(19) United States
(12) Patent Application Publication
(10) Pub. No.: US 2026/0368404 A1
(43) Pub. Date: Nov. 19, 2026

(54) SYSTEM AND METHOD FOR AUTOMATED ACOUSTIC LENS TOPOLOGY OPTIMIZATION FOR TRANSCRANIAL WAVE FOCUSING

(71) Applicant: Georgia Tech Research Corporation, Atlanta, GA (US)

(72) Inventors: Konstantinos Arvanitis, Atlanta, GA (US); Pradosh Pritam Dash, Atlanta, GA (US)

(21) Appl. No.: 19/680,599

(22) Filed: May 18, 2026

Related U.S. Application Data
(60) Provisional application No. 63/806,773, filed on May 16, 2025.

(51) Int. Cl. G06F 30/27; G01S 7/521; G10K 11/30

(52) U.S. Cl. CPC G06F 30/27; G01S 7/521; G10K 11/30

(57) ABSTRACT

A method for designing an acoustic lens for focusing acoustic waves through a heterogeneous propagation medium includes receiving a three-dimensional acoustic property map of the heterogeneous propagation medium, the acoustic property map including a spatially varying speed of sound distribution and a spatially varying density distribution, and receiving a target acoustic intensity distribution at a target plane. A thickness distribution of the acoustic lens is initialized, the thickness distribution being parameterized by an unconstrained optimization variable transformed by a softplus function bounded by a maximum thickness. The thickness distribution is iteratively updated by simulating forward propagation of an acoustic pressure field from a source plane, through the acoustic lens, and through the heterogeneous propagation medium to the target plane using a heterogeneous angular spectrum approach, computing a loss, computing a gradient by automatic differentiation, and updating the unconstrained optimization variable based on the gradient.

### CROSS-REFERENCE TO RELATED APPLICATIONS

This application claims the benefit of U.S. Provisional Application Ser. No. 63/806,773, filed on 16 May 2025, which is incorporated herein by reference in its entirety as if fully set forth below.

### GOVERNMENT LICENSE RIGHTS

This invention was made with government support under 1933158, and 1966158 awarded by the National Science Foundation. The government has certain rights in this invention.

### FIELD OF INVENTION

The present disclosure relates to acoustic wave focusing through heterogeneous media, and more particularly to systems and methods for automated topology optimization of passive acoustic lenses for transcranial ultrasound wave focusing.

### BACKGROUND

Focused ultrasound is a non-invasive modality that can deliver acoustic energy deep within the body for a range of therapeutic and diagnostic applications, including neuromodulation, tissue ablation, blood-brain barrier opening, and targeted drug delivery. Transcranial focused ultrasound, in particular, has attracted growing interest as a route to non-invasively interact with deep brain structures. Existing approaches to transcranial focusing include large multi-element phased arrays driven by per-element electronic delays, single-element transducers paired with passive acoustic lenses or holograms, and neuronavigation-guided single-element systems. Phased-array systems typically rely on patient-specific computed tomography or magnetic resonance imaging data to compute aberration corrections, and on continuous magnetic resonance guidance during treatment to monitor focal placement. Passive holographic lenses, often fabricated by three-dimensional printing of polymer materials, offer an alternative in which spatial phase modulation is encoded into the thickness profile of a static lens placed in front of a single-element transducer. Common design workflows for such lenses use iterative angular spectrum or Rayleigh-Sommerfeld methods that treat the lens as a thin element or pure phase screen, with the resulting phase distribution converted to a thickness map by scaling with the wavenumber mismatch between the lens material and the surrounding medium.

However, these approaches suffer from a number of limitations. Multi-element phased-array systems are expensive, hardware-intensive, and dependent on continuous imaging guidance, which restricts their accessibility for academic research and broader clinical translation. Passive lens designs based on the thin-element or thin-film approximation treat phase accumulation as a purely longitudinal phenomenon and neglect volumetric wave propagation, lateral energy migration, and refractive walk-off within the lens material. As operating frequencies move into the lower megahertz range, which is favored for transcranial applications because of reduced skull attenuation, the lens thickness required to impart a full cycle of phase modulation becomes comparable to or larger than the acoustic wavelength, placing the lens in an acoustically thick regime in which the thin-element approximation breaks down. The result is degraded focal fidelity, reduced peak pressure, distorted reconstructions of complex target patterns, and pixel-to-pixel energy leakage within the hologram aperture. Full-wave time-domain simulations can capture these effects more faithfully but are computationally expensive and difficult to integrate into iterative, gradient-based design loops. In addition, conventional design pipelines often address skull-induced aberrations only as a separate correction step layered onto an idealized lens design, rather than as an integral part of the lens topology optimization, and they typically do not provide a direct, differentiable path from a target acoustic intensity distribution to a manufacturable three-dimensional thickness profile that jointly accounts for heterogeneous propagation through both the lens material and the skull.

What is needed, therefore, are systems and methods that can automatically design passive acoustic lenses for transcranial wave focusing in a manner that captures volumetric wave propagation effects within an acoustically thick lens, accounts for heterogeneous acoustic properties of the propagation medium, and produces a manufacturable thickness profile directly from a target acoustic intensity distribution while remaining computationally tractable for routine, patient-specific design.

### SUMMARY

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

According to an aspect of the present disclosure, a method for designing an acoustic lens for focusing acoustic waves through a heterogeneous propagation medium is provided. The method can include receiving a three-dimensional acoustic property map of the heterogeneous propagation medium, the acoustic property map including a spatially varying speed of sound distribution and a spatially varying density distribution. The method can include receiving a target acoustic intensity distribution at a target plane. The method can include initializing a thickness distribution of the acoustic lens, the thickness distribution being parameterized by an unconstrained optimization variable transformed by a softplus function bounded by a maximum thickness. The method can include iteratively updating the thickness distribution by, for each of a plurality of iterations, simulating forward propagation of an acoustic pressure field from a source plane, through the acoustic lens defined by the thickness distribution, and through the heterogeneous propagation medium to the target plane using a heterogeneous angular spectrum approach that accounts for the spatially varying speed of sound distribution and the spatially varying density distribution. The method can include computing a simulated intensity distribution at the target plane based on the simulated forward propagation. The method can include computing a loss based on a difference between the simulated intensity distribution and the target acoustic intensity distribution. The method can include computing, by automatic differentiation, a gradient of the loss with respect to the unconstrained optimization variable. The method can include updating the unconstrained optimization variable based on the gradient and a learning rate. The method can include outputting a converged thickness distribution of the acoustic lens upon satisfaction of a convergence criterion.

According to another aspect of the present disclosure, a system for designing and producing an acoustic lens for focusing acoustic waves through a heterogeneous propagation medium is provided. The system can include a memory storing a three-dimensional acoustic property map of the heterogeneous propagation medium, the acoustic property map including a spatially varying speed of sound distribution and a spatially varying density distribution, and storing a target acoustic intensity distribution at a target plane. The system can include a processor in communication with the memory. The processor can be configured to initialize a thickness distribution of the acoustic lens, the thickness distribution being parameterized by an unconstrained optimization variable transformed by a softplus function bounded by a maximum thickness. The processor can be configured to iteratively update the thickness distribution by, for each of a plurality of iterations, simulating forward propagation of an acoustic pressure field from a source plane, through the acoustic lens defined by the thickness distribution, and through the heterogeneous propagation medium to the target plane using a heterogeneous angular spectrum approach that accounts for the spatially varying speed of sound distribution and the spatially varying density distribution. The processor can be configured to compute a simulated intensity distribution at the target plane based on the simulated forward propagation. The processor can be configured to compute a loss based on a difference between the simulated intensity distribution and the target acoustic intensity distribution. The processor can be configured to compute, by automatic differentiation, a gradient of the loss with respect to the unconstrained optimization variable. The processor can be configured to update the unconstrained optimization variable based on the gradient and a learning rate. The processor can be configured to output a converged thickness distribution of the acoustic lens upon satisfaction of a convergence criterion.

According to another aspect of the present disclosure, a non-transitory computer-readable medium storing instructions that, when executed by a processor, cause the processor to perform operations for designing an acoustic lens for focusing acoustic waves through a heterogeneous propagation medium is provided. The operations can include receiving a three-dimensional acoustic property map of the heterogeneous propagation medium, the acoustic property map including a spatially varying speed of sound distribution and a spatially varying density distribution. The operations can include receiving a target acoustic intensity distribution at a target plane. The operations can include initializing a thickness distribution of the acoustic lens, the thickness distribution being parameterized by an unconstrained optimization variable transformed by a softplus function bounded by a maximum thickness. The operations can include iteratively updating the thickness distribution by, for each of a plurality of iterations, simulating forward propagation of an acoustic pressure field from a source plane, through the acoustic lens defined by the thickness distribution, and through the heterogeneous propagation medium to the target plane using a heterogeneous angular spectrum approach that accounts for the spatially varying speed of sound distribution and the spatially varying density distribution. The operations can include computing a simulated intensity distribution at the target plane based on the simulated forward propagation. The operations can include computing a loss based on a difference between the simulated intensity distribution and the target acoustic intensity distribution. The operations can include computing, by automatic differentiation, a gradient of the loss with respect to the unconstrained optimization variable. The operations can include updating the unconstrained optimization variable based on the gradient and a learning rate. The operations can include outputting a converged thickness distribution of the acoustic lens upon satisfaction of a convergence criterion.

The foregoing general description of the illustrative embodiments and the following detailed description thereof are merely exemplary aspects of the teachings of this disclosure and are not restrictive.

### BRIEF DESCRIPTION OF FIGURES

Non-limiting and non-exhaustive examples are described with reference to the following figures.

FIG. 1 illustrates an experimental system for characterizing acoustic fields generated by an acoustic lens through a heterogeneous propagation medium, according to examples of the disclosed technology.

FIG. 2 illustrates an experimental system for validating acoustic lens designs and characterizing transcranial wave propagation, according to examples of the disclosed technology.

FIG. 3 is a flow diagram for a method for designing an acoustic lens for focusing acoustic waves through a heterogeneous propagation medium, according to examples of the disclosed technology.

FIG. 4 illustrates a schematic overview of a HASA-ADAM framework for designing an acoustic lens, according to examples of the disclosed technology.

FIG. 5 illustrates a topology optimization path for designing an acoustic lens to produce a target acoustic field, according to examples of the disclosed technology.

FIG. 6 illustrates a phase optimization path for designing an acoustic lens and converting an optimized phase distribution into a physical lens topology, according to examples of the disclosed technology.

FIG. 7 illustrates an effect of refractive walk-off on acoustic wave propagation through an acoustic lens, according to examples of the disclosed technology.

FIG. 8 illustrates a comparative array of acoustic holography results generated using different lens design approaches across multiple operating frequencies, according to examples of the disclosed technology.

FIG. 9A illustrates a normalized acoustic intensity distribution at a target plane predicted by a fluid model, according to examples of the disclosed technology.

FIG. 9B illustrates a normalized acoustic intensity distribution at a target plane predicted by a shear model, according to examples of the disclosed technology.

FIG. 9C illustrates an experimentally measured normalized acoustic intensity distribution at a target plane, according to examples of the disclosed technology.

FIG. 9D illustrates a fluid error map relative to experimental measurements of an acoustic holographic field, according to examples of the disclosed technology.

FIG. 9E illustrates a shear error map relative to experimental measurements of an acoustic holographic field, according to examples of the disclosed technology.

FIG. 10 illustrates a bar graph comparing performance of a fluid model and a shear model, according to examples of the disclosed technology.

FIG. 11 illustrates a schematic comparison of a phase optimization path and a topology optimization path for transcranial wave focusing, according to examples of the disclosed technology.

FIG. 12 illustrates lens surface maps for a transcranial acoustic holography system, according to examples of the disclosed technology.

FIG. 13 illustrates a skull slice in an XZ plane showing spatially varying acoustic properties, according to examples of the disclosed technology.

FIG. 14 illustrates simulated acoustic pressure field scan results comparing reference, aberrated, phase-corrected, and topology-corrected configurations, according to examples of the disclosed technology.

FIG. 15 illustrates experimental acoustic pressure field scan results for aberrated, phase-corrected, and topology-corrected configurations, according to examples of the disclosed technology.

FIG. 16 illustrates an effect of skull rotation angle on relative peak pressure and full width at half maximum, according to examples of the disclosed technology.

FIG. 17 illustrates an effect of skull rotation angle on focal shift, according to examples of the disclosed technology.

FIG. 18 illustrates a two-dimensional thickness map of a lens profile, according to examples of the disclosed technology.

FIG. 19 illustrates a three-dimensional rendering of a medium structure reconstructed from acoustic field data, according to examples of the disclosed technology.

FIG. 20A illustrates a simulated acoustic pressure field distribution in a sagittal plane for a focused ultrasound beam, according to examples of the disclosed technology.

FIG. 20B illustrates a simulated acoustic pressure field distribution in a transverse plane for a focused ultrasound beam, according to examples of the disclosed technology.

FIG. 20C illustrates a simulated acoustic pressure field distribution in a coronal plane for a focused ultrasound beam, according to examples of the disclosed technology.

FIG. 21A illustrates a lateral resolution profile of a focal acoustic pressure field generated by an optimized acoustic lens, according to examples of the disclosed technology.

FIG. 21B illustrates an axial resolution profile of a focal acoustic pressure field generated by an optimized acoustic lens, according to examples of the disclosed technology.

FIG. 22 illustrates a three-dimensional beam profile of an acoustic focal field generated through an optimized acoustic lens, according to examples of the disclosed technology.

FIG. 23 illustrates a grayscale thickness map of a lens profile generated by a topology optimization path, according to examples of the disclosed technology.

FIG. 24 illustrates a three-dimensional surface visualization of a medium structure used in acoustic wave propagation modeling, according to examples of the disclosed technology.

FIG. 25 illustrates a normalized pressure field in a coronal plane resulting from acoustic wave propagation, according to examples of the disclosed technology.

FIG. 26 illustrates a two-dimensional acoustic intensity map of a reconstructed pressure field in a transverse plane, according to examples of the disclosed technology.

FIG. 27 illustrates a two-dimensional thickness profile of an acoustic lens, according to examples of the disclosed technology.

FIG. 28 illustrates a three-dimensional surface rendering of a medium structure characterized along orthogonal axes, according to examples of the disclosed technology.

FIG. 29A illustrates a simulated normalized pressure distribution in a sagittal plane of an acoustic field generated by a holographic lens through a skull, according to examples of the disclosed technology.

FIG. 29B illustrates a simulated normalized pressure distribution in a transverse plane of an acoustic field generated by a holographic lens through a skull, according to examples of the disclosed technology.

FIG. 29C illustrates a simulated normalized pressure distribution in a coronal plane of an acoustic field generated by a holographic lens through a skull, according to examples of the disclosed technology.

FIG. 30A illustrates a lateral focal performance characteristic of a diffraction-limited acoustic focus generated by an optimized lens topology, according to examples of the disclosed technology.

FIG. 30B illustrates an axial focal performance characteristic of a diffraction-limited acoustic focus generated by an optimized lens topology, according to examples of the disclosed technology.

FIG. 31 illustrates a three-dimensional beam profile showing acoustic intensity isosurfaces generated by an optimized acoustic lens, according to examples of the disclosed technology.

### DETAILED DESCRIPTION

The following description sets forth exemplary aspects of the present disclosure. It should be recognized, however, that such description is not intended as a limitation on the scope of the present disclosure. Rather, the description also encompasses combinations and modifications to those exemplary aspects described herein.

The disclosed technology relates to systems and methods for designing an acoustic lens that focuses acoustic waves through a heterogeneous propagation medium. In some aspects, the disclosed technology can iteratively optimize a thickness distribution of a passive acoustic lens by coupling a heterogeneous angular spectrum approach for forward wave propagation with gradient-based optimization, such that the thickness distribution converges toward a profile that produces a target acoustic intensity distribution at a target plane when acoustic waves propagate through both the acoustic lens and the heterogeneous propagation medium. In some aspects, the disclosed technology accounts for spatially varying speed of sound and density within the heterogeneous propagation medium, captures volumetric wave propagation effects within an acoustically thick lens, and provides a differentiable design pipeline from a prescribed target acoustic intensity distribution to a manufacturable three-dimensional thickness profile of the acoustic lens.

The disclosed technology can further include fabricating the acoustic lens based on a converged thickness distribution produced by the iterative optimization, for example by three-dimensional printing of a polymer material to realize a passive acoustic lens having the converged thickness distribution. In some aspects, the disclosed technology can be applied to trans-skull focused ultrasound, in which acoustic waves emitted by a transducer pass through the acoustic lens and through a skull to form a focal region within tissue distal to the skull. In some aspects, the disclosed technology can be applied across a range of operating frequencies, target acoustic intensity distributions, propagation media, and lens materials, and can be implemented on a computing system that provides automatic differentiation and hardware acceleration.

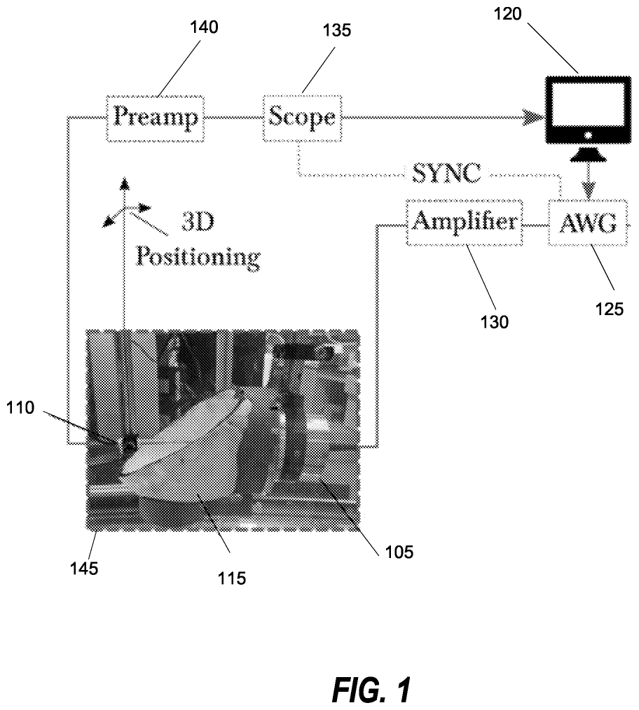

FIG. 1 illustrates an experimental system for characterizing acoustic fields generated by an acoustic lens through a heterogeneous propagation medium, according to examples of the disclosed technology. The experimental system can be used to acquire spatially resolved acoustic pressure measurements that can be compared against simulated or target acoustic field distributions produced by a thickness distribution of an acoustic lens designed in accordance with the disclosed technology. As used herein, the terms “acoustic hologram”, “acoustic hologram lens”, and “acoustic lens” can be used interchangeably to refer to the same passive lens having the thickness distribution produced by the disclosed iterative optimization.

As shown in FIG. 1, the experimental system can include a transducer 105 coupled to an acoustic lens. The transducer 105 can be acoustically coupled to a skull 115 through the acoustic lens, such that acoustic waves emitted by the transducer 105 propagate through the acoustic lens and through the skull 115. The transducer 105, the acoustic lens, and the skull 115 can be submerged in a water tank 145, which can provide a controlled acoustic propagation environment for the experimental system. In some aspects, the water tank 145 can contain degassed deionized water that serves as an acoustic coupling medium between the transducer 105, the acoustic lens, and the skull 115. For ex vivo trans-skull experiments, the skull 115 can be degassed in the degassed deionized water for approximately 12 hours prior to acoustic measurements to reduce the presence of trapped gas that can otherwise scatter or attenuate the propagating acoustic waves. In some aspects, the transducer 105 can be a 60 mm diameter piston transducer. The acoustic lens can be referred to herein as the acoustic lens having the thickness distribution produced by the disclosed iterative optimization.

The skull 115 can be supported within the water tank 145 in an orientation that aligns the skull 115 with an acoustic propagation axis of the transducer 105. In some aspects, the skull 115 can be one example of the heterogeneous propagation medium, and the heterogeneous propagation medium can additionally or alternatively include other aberrating layers such as a fat layer, a bone structure other than the skull, or a combination of soft tissue and bone. Acoustic properties of the skull 115, or of another heterogeneous propagation medium used in place of or in addition to the skull 115, can correspond to the spatially varying speed of sound distribution and the spatially varying density distribution of the three-dimensional acoustic property map used by the disclosed technology.

The experimental system can include a hydrophone 110 positioned within the water tank 145 to sample an acoustic pressure field generated by the transducer 105 after propagation of the acoustic waves through the acoustic lens and the skull 115. In some aspects, the hydrophone 110 can be a calibrated 2 mm needle hydrophone. The hydrophone 110 can be mounted on a three-axis positioning system that enables translational movement of the hydrophone 110 along three orthogonal axes. The three-axis positioning system can position the hydrophone 110 to raster scan the acoustic pressure field at a plurality of spatial locations within the water tank 145, such that the acoustic pressure field can be sampled across a region of interest at the target plane and along an axial direction relative to the transducer 105.

On an excitation side of the experimental system, an arbitrary waveform generator 125 can generate a drive signal that defines an excitation waveform applied to the transducer 105. In some aspects, the arbitrary waveform generator 125 can be implemented as a function generator, such as an HP Agilent Keysight 33511B function generator. The arbitrary waveform generator 125 can be electrically connected to an amplifier 130, which can amplify the drive signal to a level sufficient to excite the transducer 105 and produce acoustic waves of finite amplitude. In some aspects, the amplifier 130 can be a power amplifier, such as a power amplifier from E&I (Rochester, NY), configured to amplify signals output by the arbitrary waveform generator 125. An output of the amplifier 130 can be electrically connected to the transducer 105 to drive the transducer 105 with the amplified drive signal.

On an acquisition side of the experimental system, the hydrophone 110 can detect the acoustic pressure field and can output a corresponding electrical signal to a preamplifier 140. The preamplifier 140 can condition and amplify the electrical signal output by the hydrophone 110. The conditioned signal output by the preamplifier 140 can be routed to an oscilloscope 135 for digitization and recording. In some aspects, the oscilloscope 135 can be a digital oscilloscope that records the conditioned signal in the time domain to characterize the focal field of the acoustic lens.

A display/computer system 120, can be communicatively coupled to the oscilloscope 135 and to the arbitrary waveform generator 125. The display/computer system 120 can receive a digitized hydrophone signal from the oscilloscope 135 for visualization, processing, and storage of acoustic field data acquired by the hydrophone 110. The display/computer system 120 can also control the arbitrary waveform generator 125 to define excitation waveform parameters, such as waveform shape, frequency, amplitude, and duration, used to drive the transducer 105.

A synchronization signal can be provided between the oscilloscope 135 and the arbitrary waveform generator 125 to coordinate timing between signal generation and data acquisition. The synchronization signal can cause recorded waveforms captured by the oscilloscope 135 to be temporally registered to excitation events generated by the arbitrary waveform generator 125, such that acoustic pressure measurements acquired by the hydrophone 110 can be aligned in time with respect to the drive signal applied to the transducer 105.

In operation, the arbitrary waveform generator 125 can produce a drive signal that is amplified by the amplifier 130 and applied to the transducer 105, which can generate an acoustic wave. The acoustic wave can pass through the acoustic lens, which can spatially modulate the acoustic wavefront in accordance with the thickness distribution of the acoustic lens, and can subsequently propagate through the skull 115, which can introduce aberrations due to heterogeneous acoustic properties of the skull 115. The hydrophone 110, scanned via the three-axis positioning system, can sample a resulting acoustic pressure field at a plurality of spatial locations within the water tank 145. The detected signals can be conditioned by the preamplifier 140, digitized by the oscilloscope 135, and recorded by the display/computer system 120 for subsequent analysis and comparison against simulated or target acoustic field distributions.

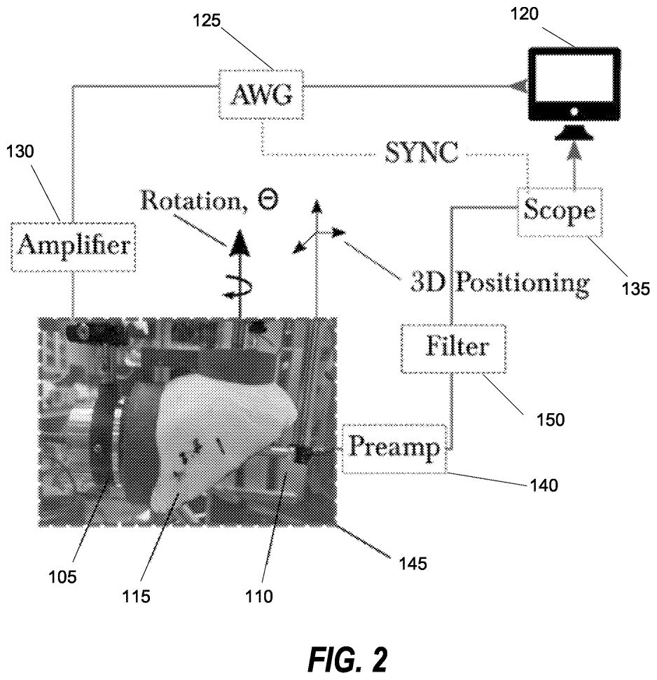

FIG. 2 illustrates an experimental system for validating acoustic lens designs and characterizing transcranial wave propagation, according to examples of the disclosed technology. The experimental system of FIG. 2 can extend the experimental system described with reference to FIG. 1 by providing controlled angular adjustment between the transducer 105, the acoustic lens, and the skull 115, and by providing additional analog signal conditioning to support both linear focal field characterization and nonlinear acoustic measurements.

As shown in FIG. 2, the transducer 105 can be coupled to the acoustic lens, which in some aspects can be a three-dimensionally printed acoustic lens, and the transducer 105 and the acoustic lens can be affixed to a rotational fixture that defines a rotational axis. The rotational fixture can permit angular adjustment of the transducer 105 and the acoustic lens relative to the skull 115 through a rotation angle θ about the rotational axis. The transducer 105, the acoustic lens, and the skull 115 can be positioned within the water tank 145 containing degassed deionized water that serves as the acoustic coupling medium between the transducer 105, the acoustic lens, and the skull 115. In some aspects, the rotational fixture can support registration validation studies in which the rotation angle θ is varied to introduce a controlled angular misregistration between the acoustic lens and the skull 115, such that focal performance can be characterized as a function of the rotation angle θ.

The hydrophone 110 can be positioned on a side of the skull 115 opposite the transducer 105 to capture an acoustic pressure field transmitted through the acoustic lens and the skull 115. The hydrophone 110 can be mounted on a three-axis positioning system that enables three-dimensional spatial scanning of a focal region, such that the hydrophone 110 can raster scan the acoustic pressure field across axial and lateral planes to map the acoustic pressure field within the water tank 145.

An electrical signal acquired by the hydrophone 110 can be routed to the preamplifier 140, which can condition and amplify the electrical signal output by the hydrophone 110. An output of the preamplifier 140 can be electrically connected to a filter 150, which can be disposed between the preamplifier 140 and the oscilloscope 135. The filter 150 can provide additional analog signal conditioning to the electrical signal output by the preamplifier 140 prior to digitization by the oscilloscope 135. In some aspects, the filter 150 can include an analog low-pass filter coupled with an additional gain stage, such as a gain stage providing approximately 40 dB of analog gain with low-pass filtering at a cutoff frequency of approximately 600 kHz. The 40 dB analog low-pass gain stage can enhance detection of low-frequency parametric signals by isolating a low-frequency parametric array component from higher-frequency primary signals present in the electrical signal output by the hydrophone 110. The filtered signal output by the filter 150 can be digitized by the oscilloscope 135, which can record time-domain waveforms for subsequent analysis.

The display/computer system 120 can be communicatively coupled to the oscilloscope 135 and to the arbitrary waveform generator 125. The display/computer system 120 can receive digitized waveform data from the oscilloscope 135 and can coordinate with the arbitrary waveform generator 125 to define excitation parameters applied to the transducer 105. A synchronization signal can be provided from the arbitrary waveform generator 125 to the oscilloscope 135 to temporally align signal generation and data acquisition.

In operation, the experimental system of FIG. 2 can support both linear acoustic measurements, such as focal field characterization of the acoustic pressure field produced by the transducer 105 and the acoustic lens after propagation through the skull 115, and nonlinear acoustic measurements, such as parametric array signal detection for registration feedback. Selection between linear and nonlinear acoustic measurements can be implemented by selecting excitation waveforms generated by the arbitrary waveform generator 125 and by selecting filter settings applied by the filter 150.

For nonlinear acoustic measurements, the arbitrary waveform generator 125 can generate a bi-frequency excitation signal that drives the transducer 105 at two primary frequencies, such that nonlinear interaction during propagation through the acoustic lens and the skull 115 generates a parametric array signal at a difference frequency equal to a difference between the two primary frequencies. In some aspects, the bi-frequency excitation signal can include primary frequencies of approximately 0.95 MHz and approximately 1.05 MHz, which can generate a difference frequency of approximately 100 kHz through nonlinear acoustic interaction. The parametric array signal at the difference frequency can be used as registration feedback for evaluating alignment between the acoustic lens and the skull 115.

In some aspects, the bi-frequency excitation signal can be applied as short tone bursts having a tone burst length of approximately 30 to 40 cycles, which can reduce standing wave artifacts during parametric array signal generation. The arbitrary waveform generator 125 can output the bi-frequency excitation signal at a pulse repetition frequency of approximately 1 to 2 Hz, which can keep cumulative exposure of the skull 115 and surrounding components within thermal and mechanical safety thresholds during parametric array signal generation. In some aspects, peak-to-peak primary pressures generated by the transducer 105 during parametric array characterization can range from approximately 0.25 MPa to approximately 1 MPa, which can provide a regime of safe exposure for validation simulations and ex vivo measurements while producing detectable parametric array signal levels at the difference frequency.

On an acquisition side of the experimental system of FIG. 2, the electrical signal output by the hydrophone 110 during parametric array measurements can include a low-frequency parametric array component at the difference frequency superimposed on higher-frequency components corresponding to the primary frequencies. The preamplifier 140 can amplify the electrical signal, and the filter 150 can apply low-pass filtering at approximately 600 kHz together with approximately 40 dB of additional analog gain to attenuate the higher-frequency primary signals while amplifying the low-frequency parametric array component. The filtered and amplified signal can then be digitized by the oscilloscope 135 and recorded by the display/computer system 120 for analysis of parametric array signal amplitude and spatial distribution. The rotation angle θ provided by the rotational fixture can be varied during parametric array measurements to characterize sensitivity of the parametric array signal to angular misregistration between the acoustic lens and the skull 115.

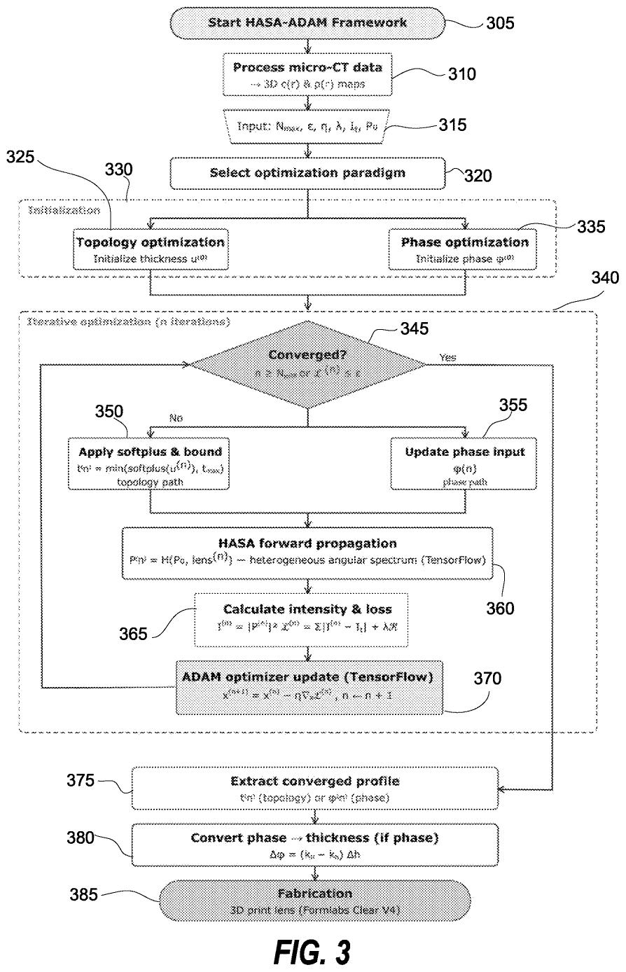

FIG. 3 is a flow diagram of a method for designing an acoustic lens for focusing acoustic waves through a heterogeneous propagation medium, according to examples of the disclosed technology. The method illustrated in FIG. 3 can be referred to herein as the method for designing an acoustic lens for focusing acoustic waves through a heterogeneous propagation medium. The method illustrated in FIG. 3 can implement a HASA-ADAM framework that couples a heterogeneous angular spectrum approach (HASA) for forward acoustic wave propagation with an Adam gradient-based optimizer to iteratively refine a thickness distribution of the acoustic lens.

The method can begin at a step 305, at which the HASA-ADAM framework is initiated. At a step 310, micro-computed tomography (micro-CT) data of a propagation medium can be processed to generate a three-dimensional acoustic property map of the heterogeneous propagation medium, including a three-dimensional speed-of-sound map c(r) and a three-dimensional density map ρ(r). The acoustic property map can include a spatially varying speed of sound distribution and a spatially varying density distribution that characterize the heterogeneous propagation medium at locations r along an acoustic propagation path. In some aspects, the heterogeneous propagation medium can include the skull 115, and the speed-of-sound map and the density map can be derived from micro-CT data of the skull 115.

At a step 315, input parameters for the HASA-ADAM framework can be received. The input parameters can include a maximum iteration count Nₘₐₓ, a convergence tolerance ε, a learning rate η, a regularization weight λ, a target intensity Iₜ corresponding to a target acoustic intensity distribution at a target plane, and an initial pressure distribution P₀ at a source plane. In some aspects, the maximum iteration count Nₘₐₓ can be approximately 500 for single-point focusing applications and can be approximately 2000 for complex two-dimensional pressure distributions. In some aspects, the convergence tolerance E can be approximately 0.001, below which a loss value can be considered converged. In some aspects, the learning rate η can be approximately 0.01. The target intensity Iₜ received at the step 315 can correspond to the target acoustic intensity distribution at the target plane used by the disclosed method.

At a step 320, an optimization paradigm can be selected from a topology optimization paradigm and a phase optimization paradigm. Based on the optimization paradigm selected at the step 320, the method can proceed to an initialization 325. The initialization 325 can include two alternative paths corresponding to the two optimization paradigms. Along a topology optimization path, the method can proceed to a step 330, at which a thickness u⁽⁰⁾ of the acoustic lens can be initialized. The thickness u⁽⁰⁾ initialized at the step 330 can correspond to an unconstrained optimization variable that parameterizes the thickness distribution of the acoustic lens. In some aspects, the thickness distribution of the acoustic lens can be initialized with a uniform initial thickness of approximately 3.6 mm. Along a phase optimization path, the method can proceed to a step 335, at which a phase φ⁽⁰⁾ can be initialized in lieu of a thickness.

Following the initialization 325, the method can enter an iterative optimization 340 loop that runs for n iterations to iteratively update the thickness distribution. The iterative optimization 340 can begin at a step 345, at which a convergence criterion can be evaluated. The convergence criterion evaluated at the step 345 can include a determination of whether the iteration count n has reached the maximum iteration count Nₘₐₓ, expressed as n≥Nₘₐₓ, or whether a loss L⁽ⁿ⁾ at iteration n has fallen to or below the convergence tolerance E, expressed as L⁽ⁿ⁾≤ε. The convergence criterion can include at least one of the loss being less than or equal to the convergence tolerance, or the iteration count reaching the maximum iteration count.

When the convergence criterion is not satisfied at the step 345, the method can proceed along one of two parallel paths corresponding to the optimization paradigm selected at the step 320. Along the topology optimization path, the method can proceed to a step 350, at which a softplus function can be applied to the unconstrained optimization variable u⁽ⁿ⁾ and the resulting thickness can be bounded by a maximum thickness tₘₐₓ according to the relationship

t⁽ⁿ⁾=min(softplus(u⁽ⁿ⁾),tₘₐₓ).

The softplus function applied at the step 350 can transform the unconstrained optimization variable into a non-negative thickness, and the bound tₘₐₓ can constrain the thickness distribution to a range of zero to a maximum thickness. In some aspects, the maximum thickness tₘₐₓ can be 5 mm or less. Along the phase optimization path, the method can proceed to a step 355, at which a phase input φ⁽ⁿ⁾ can be updated. The phase optimization path supported by the step 355 can iteratively refine a phase distribution while maintaining a fixed amplitude, and a converged phase profile output by the phase optimization path can subsequently be converted to a thickness map using a wavenumber-based relationship as described below.

An output of either the step 350 or the step 355 can be provided to a step 360, at which HASA forward propagation can be performed according to the relationship

P⁽ⁿ⁾=H(P₀,lens⁽ⁿ⁾),

where H denotes the heterogeneous angular spectrum approach forward propagator, P₀ denotes the initial pressure distribution at the source plane, and lens⁽ⁿ⁾ denotes the acoustic lens defined by the thickness distribution at iteration n. The step 360 can simulate forward propagation of an acoustic pressure field from the source plane, through the acoustic lens defined by the thickness distribution, and through the heterogeneous propagation medium to the target plane using the heterogeneous angular spectrum approach that accounts for the spatially varying speed of sound distribution and the spatially varying density distribution. In some aspects, the heterogeneous angular spectrum approach implemented at the step 360 can be implemented in a machine learning framework such as TensorFlow that provides automatic differentiation and hardware acceleration.

The method can proceed to a step 365, at which a simulated intensity distribution at the target plane and a loss value can be calculated based on the simulated forward propagation. The simulated intensity distribution at iteration n can be calculated according to the relationship

I⁽ⁿ⁾=|P⁽ⁿ⁾|²,

and the loss at iteration n can be calculated according to the relationship

L⁽ⁿ⁾=|I⁽ⁿ⁾−Iₜ|+λR,

where Iₜ denotes the target intensity, λ denotes the regularization weight, and R denotes a regularization term. The loss calculated at the step 365 can include an L1 intensity loss metric computing absolute differences between the simulated intensity distribution and the target acoustic intensity distribution, and can further include a regularization term weighted by the regularization weight λ.

At a step 370, an Adam optimizer update can be performed and the iteration counter can be incremented. The Adam optimizer update can update an optimization variable x according to the relationship

X⁽ⁿ⁺⁾=x⁽ⁿ⁾−η∇ₓL⁽ⁿ⁾,

where η denotes the learning rate and ∇ₓL⁽ⁿ⁾ denotes a gradient of the loss with respect to the optimization variable x. The optimization variable x can correspond to the unconstrained optimization variable u⁽ⁿ⁾ along the topology optimization path or to the phase φ⁽ⁿ⁾ along the phase optimization path. The gradient ∇ₓL⁽ⁿ⁾ can be computed by automatic differentiation provided by the machine learning framework used to implement the heterogeneous angular spectrum approach. The iteration counter can be incremented as n←n+1, and the method can return to the step 345 for a subsequent evaluation of the convergence criterion. In some aspects, the Adam optimizer used at the step 370 can use a learning rate of approximately 0.01 for iterative optimization of the thickness distribution.

When the convergence criterion is satisfied at the step 345, the iterative optimization 340 loop can be exited, and the method can proceed to a step 375, at which a converged profile can be extracted. The converged profile extracted at the step 375 can include a converged thickness t⁽ⁿ⁾ along the topology optimization path or a converged phase φ⁽ⁿ⁾ along the phase optimization path. The step 375 can output a converged thickness distribution of the acoustic lens upon satisfaction of the convergence criterion.

At a step 380, when the converged profile extracted at the step 375 is a converged phase profile output by the phase optimization path, the converged phase profile can be converted to a thickness map according to the wavenumber-based relationship

Δφ=(kᵤ−kₕ)Δh,

where Δφ denotes a phase difference, kᵤ denotes a wavenumber in a background medium surrounding the acoustic lens, kₕ denotes a wavenumber in a lens material of the acoustic lens, and Δh denotes a thickness increment of the acoustic lens. The step 380 can be bypassed when the converged profile extracted at the step 375 is a converged thickness distribution output by the topology optimization path.

At a step 385, the acoustic lens can be fabricated by three-dimensional printing of a polymer based on the converged thickness distribution. In some aspects, the acoustic lens can be fabricated from a clear white v4 resin photopolymer, such as Formlabs Clear V4 resin, using a stereolithography three-dimensional printer, such as a Formlabs Form 3B printer. The step 385 can produce a physical realization of the acoustic lens having the converged thickness distribution output by the HASA-ADAM framework.

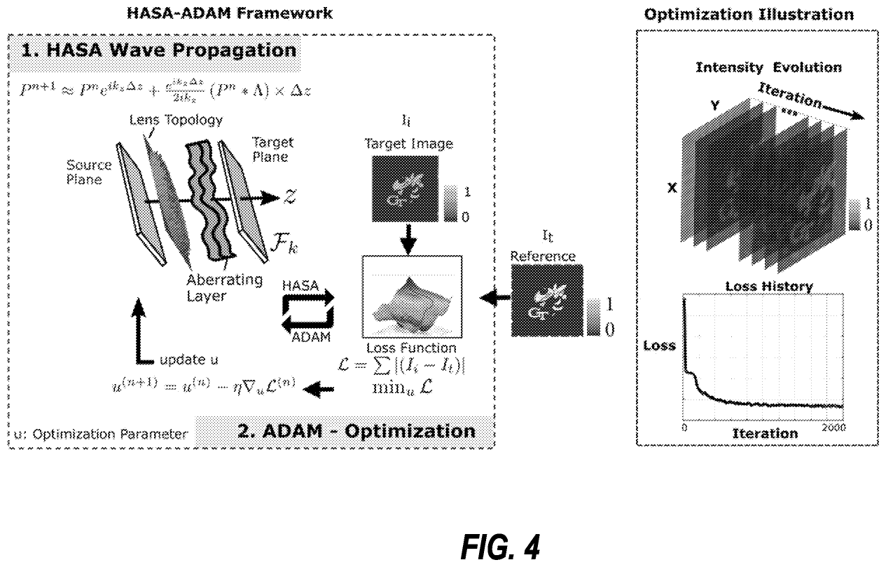

FIG. 4 illustrates a schematic overview of the HASA-ADAM framework for designing an acoustic lens, according to examples of the disclosed technology. The HASA-ADAM framework illustrated in FIG. 4 can implement the method for designing an acoustic lens for focusing acoustic waves through a heterogeneous propagation medium, and can include a HASA wave propagation stage and an ADAM-based optimization stage that are coupled in an iterative loop.

In the HASA wave propagation stage, an acoustic pressure field originating at a source plane can propagate through a lens topology and through an aberrating layer to arrive at a target plane. The lens topology can represent a spatially varying thickness distribution of a passive holographic lens, and the aberrating layer can represent a heterogeneous propagation medium such as a skull. The HASA wave propagation stage can implement a forward marching scheme along an axial z-direction in which an angular spectrum at successive planes can be updated according to a recursive relationship between adjacent axial propagation steps.

The HASA wave propagation stage can update the acoustic pressure field at successive axial propagation steps according to the relationship

$${P}^{n + 1} \approx {P}^{n} {e}^{i {k}_{z} Δ z} + \frac{{e}^{i {k}_{z} Δ z}}{2 i {k}_{z}} ( {P}^{n} * Λ ) \times Δ z ,$$

where Pⁿ denotes the angular spectrum of the acoustic pressure field at axial step n, Δz denotes an axial marching step size between successive axial propagation steps, k_{z} denotes an axial component of a wavenumber in a background medium, and * denotes a two-dimensional convolution over component wavenumbers kₓ and k_{y}. A spatial variation term Λ can be defined according to the relationship

$$Λ = {ℱ}_{k} [ {k}_{0}^{2} ( 1 - μ ) ] ,$$

where [symbol] ₖ denotes a Fourier transform over the component wavenumbers kₓ and k_{y}, k₀=ω/c₀ denotes a reference wavenumber defined with respect to an angular frequency ω and a reference speed of sound c₀, and

$$μ = {c}_{0}^{2} / {c}^{2}$$

denotes a squared refractive index ratio between the reference speed of sound c₀ and a spatially varying speed of sound c at a given axial propagation step. The spatial variation term Λ can encode a correction based on a refractive index mismatch between materials at the axial propagation step, such that the HASA wave propagation stage can account for the spatially varying speed of sound distribution and the spatially varying density distribution of the heterogeneous propagation medium.

At each of a plurality of axial propagation steps, the HASA wave propagation stage can transform the acoustic pressure field to a frequency domain by a two-dimensional fast Fourier transform, multiply the transformed acoustic pressure field by an exponential phase term e^{ik}^{_{z}}^{Δz} encoding axial propagation, and apply a correction based on the refractive index mismatch between materials at the axial propagation step through convolution with the spatial variation term Λ. In some aspects, the axial marching step size Δz can be smaller than an acoustic wavelength in the background medium to facilitate computational stability. In some aspects, the axial marching step size Δz can be approximately 250 μm, corresponding to approximately λ/6 at 1 MHz, or approximately 150 μm in other configurations.

In some aspects, the HASA wave propagation stage can further include attenuating spatial-frequency components above a cutoff and applying a tapering mask at spatial edges of the acoustic pressure field. Attenuating spatial-frequency components above the cutoff can suppress evanescent or aliased spectral content during the forward marching scheme, and applying the tapering mask at the spatial edges of the acoustic pressure field can reduce wrap-around artifacts associated with the discrete two-dimensional fast Fourier transform. In some aspects, computational grids used by the HASA wave propagation stage can be zero-padded at the spatial edges of the acoustic pressure field to further reduce circular convolution artifacts during forward propagation.

In the ADAM-based optimization stage, a simulated intensity distribution produced by the HASA wave propagation stage at the target plane can be compared against the target acoustic intensity distribution. As used herein, the target acoustic intensity distribution can also be referred to as a reference image. The target acoustic intensity distribution can define a desired holographic pattern at the target plane, such as a normalized intensity pattern with values ranging from zero to one. A loss function can quantify a discrepancy between the simulated intensity distribution and the target acoustic intensity distribution. The loss function evaluated at iteration n can be calculated according to the relationship

$${L}^{( n )} = {\sum }_{x , y} \vert {I}^{( n )} ( x , y ) - {I}_{t} ( x , y ) \vert + λ R ( {t}^{( n )} ) ,$$

where the sum can be taken over spatial coordinates x and y at the target plane, I⁽ⁿ⁾(x,y) denotes the simulated intensity distribution at iteration n, Iₜ(x,y) denotes the target acoustic intensity distribution, and λR(t⁽ⁿ⁾) denotes an optional regularization term weighted by a regularization weight A that can be applied to the thickness distribution t⁽ⁿ⁾. The first term of the loss function can implement an L1 intensity loss metric computing absolute differences between the simulated intensity distribution and the target acoustic intensity distribution. In some aspects, the regularization term can include a total variation regularizer that encourages smooth thickness variations across the lens topology.

The ADAM-based optimization stage can update the unconstrained optimization variable u that parameterizes the thickness distribution according to the gradient-based update rule

u⁽ⁿ⁺¹⁾=u⁽ⁿ⁾−η∇ᵤL⁽ⁿ⁾,

where η denotes the learning rate and ∇ᵤL⁽ⁿ⁾ denotes a gradient of the loss with respect to the unconstrained optimization variable u. The gradient ∇ᵤL⁽ⁿ⁾ can be computed by automatic differentiation. The updated unconstrained optimization variable can be fed back into the HASA wave propagation stage to complete an iterative loop between the HASA wave propagation stage and the ADAM-based optimization stage. The iterative loop can continue until a convergence criterion is satisfied or a maximum iteration count is reached, as described above.

The HASA wave propagation stage and the ADAM-based optimization stage can be implemented using a machine learning framework that provides automatic differentiation and graphics processing unit acceleration. In some aspects, the machine learning framework can be TensorFlow, and the automatic differentiation provided by the machine learning framework can compute the gradient ∇ᵤL⁽ⁿ⁾ of the loss with respect to the unconstrained optimization variable through the HASA wave propagation stage. The machine learning framework can execute the HASA wave propagation stage and the ADAM-based optimization stage on a graphics processing unit, such as a 24 GB NVIDIA RTX 3090 graphics processing unit. In some aspects, the HASA-ADAM framework can converge in approximately 20 minutes at a λ/10 discretization at 1 MHz over a 40 mm domain on a system equipped with a 24 GB NVIDIA RTX 3090 graphics processing unit.

A progression of reconstructed intensity distributions across successive iterations can illustrate the evolution of the simulated intensity distribution at the target plane as the HASA-ADAM framework proceeds. Early iterations can exhibit diffuse, low-fidelity intensity distributions, while later iterations can converge toward a sharper reconstruction of the target acoustic intensity distribution. A loss history can display the loss value as a function of iteration over a range of iterations, such as up to approximately 2000 iterations, and can exhibit a monotonic decrease and a plateau associated with convergence of the HASA-ADAM framework.

In some aspects, hyperparameters of the ADAM-based optimization stage can be selected by an empirical sweep across candidate values. A learning rate sweep across values of η∈{0.001, 0.005, 0.01, 0.05, 0.1}can be performed to identify convergence behavior, with higher learning rates producing faster loss reduction accompanied by oscillation near convergence and lower learning rates producing stable but slower convergence. A learning rate of approximately 0.01 can provide a compromise between fall rate and oscillation. A total variation regularizer weight sweep across values of λ∈{0.0, 0.01, 0.1, 1.0, 10.0}can be performed to identify a regularizer weight that smooths the lens topology for manufacturability without degrading acoustic reconstruction. In some aspects, a total variation regularizer weight of approximately 0.01 can be used. In some aspects, the convergence tolerance can be approximately 0.001, below which the loss value can be considered converged.

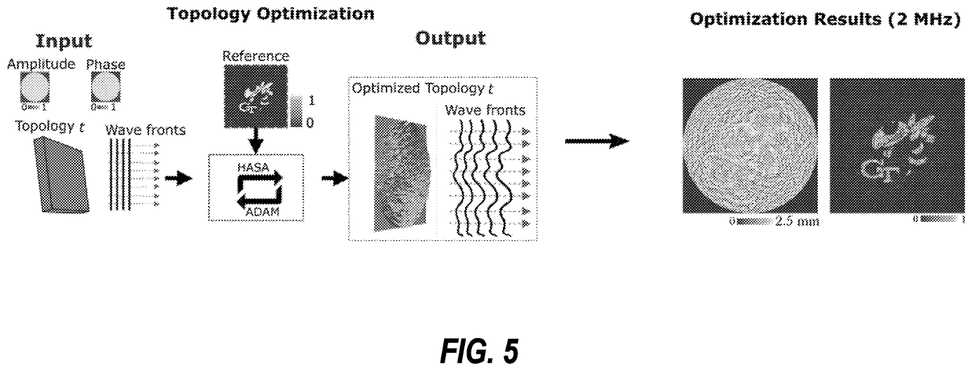

FIG. 5 illustrates a topology optimization path for designing an acoustic lens to produce a target acoustic field, according to examples of the disclosed technology. The topology optimization path illustrated in FIG. 5 can implement the HASA-ADAM framework along the topology optimization path described above, in which a thickness distribution of the acoustic lens is treated as an unconstrained optimization variable that is iteratively refined by coupling the HASA wave propagation stage with the ADAM-based optimization stage. The topology optimization path can be organized into an input stage, a topology optimization stage, and an output stage.

In the input stage, a source acoustic field at the source plane can be defined by an initial amplitude distribution and an initial phase distribution. The initial amplitude distribution can be represented as a circular aperture profile having normalized values ranging from zero to one, and the initial phase distribution can be represented as a circular aperture profile having normalized values ranging from zero to one. The input stage can further include an initial topology t of the acoustic lens, depicted as a uniform initial thickness distribution from which planar wave fronts can propagate along the axial z-direction toward the topology optimization stage. In some aspects, the initial topology t can be a uniform initial thickness of approximately 3.6 mm across the lens aperture.

In the topology optimization stage, the planar wave fronts produced by the initial topology t can be received by an iterative optimization loop comprising the HASA wave propagator coupled with the ADAM optimizer. The iterative optimization loop can exchange forward-propagated acoustic pressure fields and backpropagated gradients of the loss with respect to the unconstrained optimization variable between the HASA wave propagator and the ADAM optimizer at each iteration. The target acoustic intensity distribution representing the desired target intensity pattern at the target plane can be provided as an input to the iterative optimization loop. The target acoustic intensity distribution can be displayed with a normalized intensity scale ranging from zero to one and can serve as the target against which the simulated intensity distribution is compared during each iteration.

At each iteration n of the topology optimization stage, the thickness distribution of the acoustic lens can be computed from the unconstrained optimization variable u⁽ⁿ⁾ according to the relationship

where the softplus function can transform the unconstrained optimization variable u⁽ⁿ⁾ into a non-negative thickness, and where the maximum thickness tₘₐₓ can bound the thickness distribution to a range of zero to a maximum thickness. In some aspects, the maximum thickness tₘₐₓ can be 5 mm or less. The HASA wave propagator can simulate forward propagation of an acoustic pressure field from the source plane, through the acoustic lens defined by the thickness distribution t⁽ⁿ⁾, and through the heterogeneous propagation medium to the target plane to produce a simulated intensity distribution I⁽ⁿ⁾(x,y) at the target plane.

A loss can be computed at each iteration based on a difference between the simulated intensity distribution and the target acoustic intensity distribution according to the relationship

where Iₜ(x,y) denotes the target acoustic intensity distribution and λR(t⁽ⁿ⁾) denotes a regularization term applied to the thickness distribution t⁽ⁿ⁾ and weighted by a regularization weight λ that controls smoothness of the thickness distribution. The ADAM optimizer can update the unconstrained optimization variable based on the gradient of the loss with respect to the unconstrained optimization variable according to the relationship

where η denotes the learning rate and ∇ᵤL⁽ⁿ⁾ denotes the gradient of the loss with respect to the unconstrained optimization variable u, computed by automatic differentiation provided by the machine learning framework.

In the output stage, the topology optimization framework can produce an optimized topology t of the acoustic lens, depicted as a three-dimensional surface map representing the spatially varying thickness distribution of the acoustic lens after the iterative optimization loop has satisfied the convergence criterion. Wave fronts emerging from the optimized topology t can be non-planar curved wave fronts that propagate through the heterogeneous propagation medium to the target plane, where the wave fronts can produce a reconstructed two-dimensional acoustic intensity field that substantially matches the target acoustic intensity distribution provided to the iterative optimization loop.

In some aspects, the topology optimization path can operate at an operating frequency of approximately 2 MHz with a maximum lens thickness tₘₐₓ of approximately 2.5 mm and a grid resolution of approximately 0.125 mm. In some aspects, the topology optimization path can operate at an operating frequency of approximately 0.5 MHz with a maximum lens thickness tₘₐₓ of approximately 10.0 mm and a grid resolution of approximately 0.500 mm. Voxel sizes in lateral and axial directions, denoted dx and dz, can be maintained at approximately λ/6 relative to an acoustic wavelength at the operating frequency to reduce numerical aliasing across different operating frequencies. In some aspects, the axial marching step size Δz used by the HASA wave propagator can be approximately 150 μm, corresponding to approximately λ/6 at 1 MHz, to facilitate computational stability of the forward marching scheme.

In some aspects, computational grids used by the HASA wave propagator within the topology optimization path can be zero-padded by N/2 on all boundaries during the forward pass, where N denotes a transverse grid size, to reduce spatial aliasing and circular convolution errors associated with the discrete Fourier transform used by the HASA wave propagator.

The iterative optimization loop of the topology optimization path can continue until the convergence criterion is satisfied or a maximum iteration count is reached. In some aspects, the maximum iteration count can be approximately 500 for single-point focusing applications and can be approximately 2000 for complex two-dimensional acoustic intensity distributions at the target plane.

In some aspects, the topology optimization path can further apply an aperture mask to the thickness distribution to constrain the acoustic lens to a defined aperture shape, and can further apply a region-of-interest mask to the simulated intensity distribution to weight the loss within a defined region of the target plane. The aperture mask can be applied to the thickness distribution t⁽ⁿ⁾ at each iteration to set thickness values outside the defined aperture shape to zero or to a fixed background value, such that the optimized topology is confined to the defined aperture shape. In some aspects, the defined aperture shape can be a circular aperture shape matching a transducer geometry, and the aperture mask can be implemented as a circular aperture mask matching a standard transducer geometry. The region-of-interest mask can be applied to the simulated intensity distribution I⁽ⁿ⁾(x,y) to weight contributions of spatial coordinates within the defined region of the target plane to the loss L⁽ⁿ⁾, such that the iterative optimization loop preferentially refines the thickness distribution to match the target acoustic intensity distribution within the defined region of the target plane.

Through repeated application of the HASA wave propagator and the ADAM optimizer in the iterative optimization loop, the unconstrained optimization variable can be progressively refined such that the simulated intensity distribution at the target plane converges toward the target acoustic intensity distribution, while accounting for volumetric wave propagation effects within the acoustic lens and through the heterogeneous propagation medium.

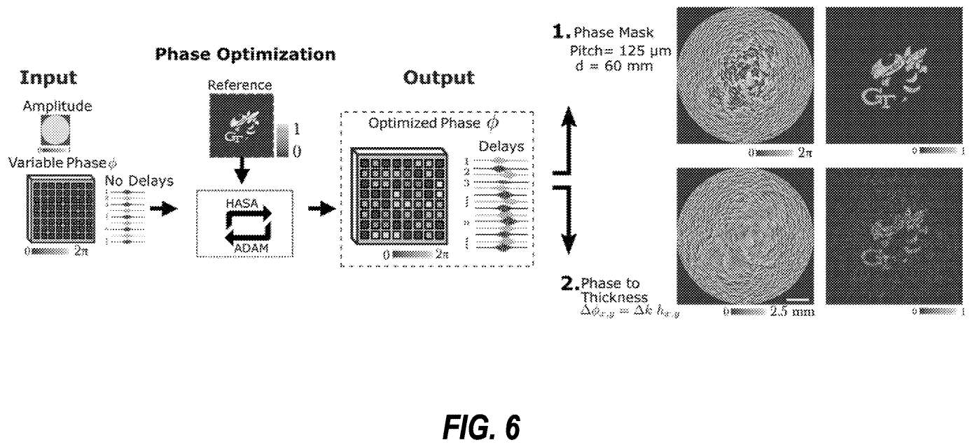

FIG. 6 illustrates a phase optimization path for designing an acoustic lens and converting an optimized phase distribution into a physical lens topology, according to examples of the disclosed technology. The phase optimization path illustrated in FIG. 6 can implement the HASA-ADAM framework along the phase optimization path described above, in which a phase distribution at a hologram plane is treated as the optimization variable rather than a thickness distribution, and a converged phase profile is subsequently converted to a manufacturable thickness map. The phase optimization path can be organized into an input stage, a phase optimization stage, and an output stage, followed by post-processing operations that translate the converged phase distribution into a physical thickness map of the acoustic lens.

In the input stage, a source acoustic field at the source plane can be defined by an amplitude distribution and a variable phase distribution. The amplitude distribution can be represented as a circular aperture profile representing a source pressure profile at a transducer, having normalized amplitude values ranging from zero to one. The variable phase distribution can be represented as a two-dimensional pixelated array in which each pixel encodes a phase value bounded between zero and 2π. An initial state of the variable phase distribution can correspond to a condition of no delays applied across a plurality of elements of the variable phase distribution, such that an initial time-domain representation of the variable phase distribution exhibits a plurality of element waveforms numbered 1, 2, 3, through n that are temporally aligned.

In the phase optimization stage, the amplitude distribution and the variable phase distribution received from the input stage can be propagated through a HASA wave propagator that simulates forward propagation of an acoustic pressure field from the source plane, through a hologram plane defined by the variable phase distribution, and through the heterogeneous propagation medium to the target plane. A simulated intensity distribution produced by the HASA wave propagator at the target plane can be compared against the target acoustic intensity distribution, such as a target intensity pattern that includes graphical features. The comparison can drive an iterative optimization loop that alternates between the HASA wave propagator and an ADAM optimizer, with forward-propagated acoustic pressure fields exchanged from the HASA wave propagator to the ADAM optimizer and backpropagated gradients of a loss with respect to the variable phase distribution exchanged from the ADAM optimizer to the HASA wave propagator at each iteration.

At each iteration n of the phase optimization stage, the loss can be computed based on a difference between the simulated intensity distribution at the target plane and the target acoustic intensity distribution according to the relationship

where the sum can be taken over spatial coordinates x and y at the target plane, I⁽ⁿ⁾(x,y) denotes the simulated intensity distribution at iteration n, Iₜ(x,y) denotes the target acoustic intensity distribution, and λR(φ⁽ⁿ⁾) denotes a regularization term applied to the variable phase distribution φ⁽ⁿ⁾ and weighted by a regularization weight λ. The ADAM optimizer can update the variable phase distribution according to the gradient-based update rule

where η denotes the learning rate and ∇_{φ}L⁽ⁿ⁾ denotes a gradient of the loss with respect to the variable phase distribution, computed by automatic differentiation provided by the machine learning framework. The phase optimization stage can iteratively refine the variable phase distribution while maintaining a fixed amplitude across the iterative optimization loop.

In the output stage, the phase optimization framework can produce an optimized phase distribution φ upon satisfaction of the convergence criterion. The optimized phase distribution can be represented as a two-dimensional pixelated array having phase values bounded between zero and 2π, accompanied by a corresponding set of time-domain delay waveforms numbered 1, 2, 3, through n that illustrate per-element delays encoded by the optimized phase distribution.

Following the phase optimization stage, the phase optimization path can perform one or more post-processing operations to translate the optimized phase distribution into a manufacturable thickness map of the acoustic lens. In a first post-processing operation, the optimized phase distribution can be retained as a phase mask characterized by a pitch and a propagation distance. In some aspects, the pitch of the phase mask can be approximately 125 μm and the propagation distance d between the phase mask and the target plane can be approximately 60 mm. The phase mask can be represented as a grayscale image having phase values ranging from zero to 2π, and a reconstructed intensity field produced by the phase mask at the target plane can be represented as a normalized intensity field having values ranging from zero to one.

In a second post-processing operation, the optimized phase distribution can be converted into a physical thickness map of the acoustic lens according to a wavenumber-based relationship

where Δφ(x,y) denotes a phase difference at lateral coordinates (x,y), k_{w} denotes a wavenumber of water surrounding the acoustic lens, kₕ denotes a wavenumber of a lens material of the acoustic lens, and Δh(x,y) denotes a thickness of the acoustic lens at the lateral coordinates (x,y). The physical thickness map produced by the second post-processing operation can be represented as a grayscale image having thickness values ranging from zero to approximately 2.5 mm, and the physical thickness map can be transmitted to a three-dimensional printer to fabricate the acoustic lens from a polymer material having the wavenumber kₕ.

A reconstructed intensity field produced by the physical thickness map at the target plane can exhibit additional background scattering and reduced contrast relative to a reconstructed intensity field produced by the phase mask at the target plane. The additional background scattering and the reduced contrast can arise because conversion of the optimized phase distribution into the physical thickness map can introduce wave propagation effects within the lens material that are not captured by a thin-element approximation underlying the phase optimization stage. In some aspects, the topology optimization path described with reference to FIG. 5 can be used in place of the phase optimization path to account for the wave propagation effects within the lens material directly during the iterative optimization loop.

In some aspects, the phase optimization path can operate at a plurality of operating frequencies to address different transcranial penetration and resolution requirements. For example, the phase optimization path can operate at an operating frequency of approximately 0.5 MHz, at an operating frequency of approximately 1.0 MHz, or at an operating frequency of approximately 2.0 MHz. Lower operating frequencies, such as approximately 0.5 MHz, can provide reduced skull attenuation and enhanced transcranial penetration, while higher operating frequencies, such as approximately 2.0 MHz, can provide finer spatial resolution at the target plane. A grid resolution, a maximum lens thickness used during the post-processing operations, and an axial marching step size used by the HASA wave propagator can be selected based on the operating frequency such that voxel sizes in lateral and axial directions are maintained at approximately λ/6 relative to an acoustic wavelength at the operating frequency.

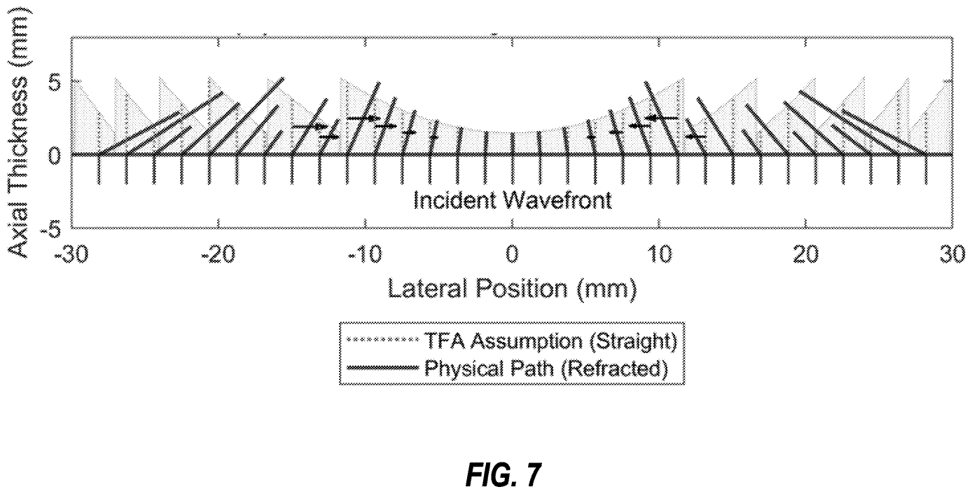

FIG. 7 illustrates an effect of refractive walk-off on acoustic wave propagation through an acoustic lens, according to examples of the disclosed technology. FIG. 7 depicts a cross-sectional view of an acoustically thick lens having a plurality of sawtooth-shaped lens features arranged along a lateral position axis, in which axial thickness varies with lateral position. An incident wavefront enters the lens features from below and propagates in an axial direction toward a target plane.

Within each sawtooth-shaped lens feature, dotted lines can represent a thin-film approximation (TFA) in which acoustic rays are assumed to travel straight along the longitudinal axis through the lens material without lateral deviation. Solid lines within the same lens features can represent physical refracted paths governed by Snell's law, along which acoustic rays travel through the lens material at angles deviating from the longitudinal axis. Arrows extending laterally from selected lens features can indicate a direction of lateral energy migration that results from refraction at lens interfaces. As lateral position moves away from a central axis of the acoustic lens, the physical refracted paths can deviate progressively from the dotted longitudinal paths, with a magnitude of lateral displacement increasing in regions of the acoustic lens that exhibit steeper topographical gradients.

A regime in which the thin-film approximation breaks down can be characterized by a geometric aspect ratio AR of holographic pixels of the acoustic lens, defined according to the relationship

where L_{2π} denotes a material thickness of the acoustic lens required for a full 2π phase delay and Λ denotes a lateral pixel pitch of the acoustic lens. The material thickness L_{2π} can be expressed in terms of an acoustic wavelength λ in a background medium, a reference speed of sound c₀ in the background medium, and a speed of sound cₗₑₙₛ in a lens material of the acoustic lens according to the relationship

In some aspects, when the geometric aspect ratio AR exceeds unity, phase-modulating features of the acoustic lens can resemble high-aspect-ratio acoustic columns rather than a thin film, and a scalar thin-element approximation can fail to capture lateral beam displacement within the lens material.

The lateral pixel pitch Λ can be constrained by a Nyquist sampling condition that suppresses grating lobes during wavefront steering. For a maximum steering angle defined by a numerical aperture NA of the acoustic lens, the lateral pixel pitch Λ can satisfy the relationship

A sampling and diffraction relationship can further constrain a lateral voxel size dx used by the heterogeneous angular spectrum approach in relation to the acoustic wavelength and a diffraction-limited resolution at the target plane. The sampling and diffraction relationship can be expressed as

where c denotes a speed of sound in the background medium, f denotes an operating frequency, δ denotes a diffraction-limited lateral resolution at the target plane, z denotes a focal depth at which the target plane is positioned, and D denotes an aperture diameter of the acoustic lens. The leftmost portion of the relationship can correspond to a spatial sampling limit imposed by the Nyquist criterion, the central portion can correspond to the acoustic wavelength, and the rightmost portion can correspond to a diffraction-limited resolution determined by an aperture geometry.

Refraction of an acoustic ray traversing an interface between the lens material and the background medium can be governed by a steering angle relation derived from Snell's law. For an acoustic ray incident on a surface of the acoustic lens having a surface normal angle θ relative to a longitudinal axis, a steering angle α at which the acoustic ray emerges from the acoustic lens into a water background medium having a speed of sound c_{w} can satisfy the relationship

A refractive limit on the surface normal angle θ beyond which total internal reflection can occur in the lens material can be expressed as

In some aspects, for a lens material having a speed of sound of approximately 2500 m/s and a water background medium having a speed of sound of approximately 1480 m/s, the refractive limit θₘₐₓ can be approximately 54.6 degrees. Surface normal angles exceeding the refractive limit can produce Fresnel amplitude apodization at peripheral regions of the acoustic lens and can drive acoustic energy into evanescent components that do not propagate to the target plane.

As lateral energy migrates within the lens material along the physical refracted paths, acoustic energy intended for a given lateral coordinate of the acoustic lens can be displaced into one or more neighboring pixels of a hologram aperture. The resulting lateral energy migration can produce volumetric crosstalk between neighboring pixels of the acoustic lens that a thin-element approximation can fail to model, because the thin-element approximation can treat phase accumulation as a purely longitudinal phenomenon and can neglect lateral redistribution of acoustic energy within the lens material. The volumetric crosstalk can manifest as a radial contraction of acoustic exit coordinates relative to an idealized pixel grid assumed by the thin-element approximation, and can reduce contrast and fidelity of a reconstructed acoustic intensity field at the target plane.

In some aspects, the topology optimization path described with reference to FIG. 5 can directly optimize the thickness distribution of the acoustic lens using the heterogeneous angular spectrum approach, such that the iterative optimization loop can pre-compensate for the volumetric diffraction effects associated with refractive walk-off during the design of the acoustic lens. Because the heterogeneous angular spectrum approach can simulate forward propagation of the acoustic pressure field through the acoustic lens defined by the thickness distribution and through the heterogeneous propagation medium while accounting for the spatially varying speed of sound distribution and the spatially varying density distribution, the gradient of the loss computed by automatic differentiation can incorporate contributions from lateral energy migration within the lens material. The converged thickness distribution output by the iterative optimization can therefore deviate from a thickness map obtained by direct phase-to-thickness conversion, and can yield a reconstructed acoustic intensity field at the target plane that retains fidelity to a target acoustic intensity distribution even when the acoustic lens operates in an acoustically thick regime characterized by AR greater than unity.

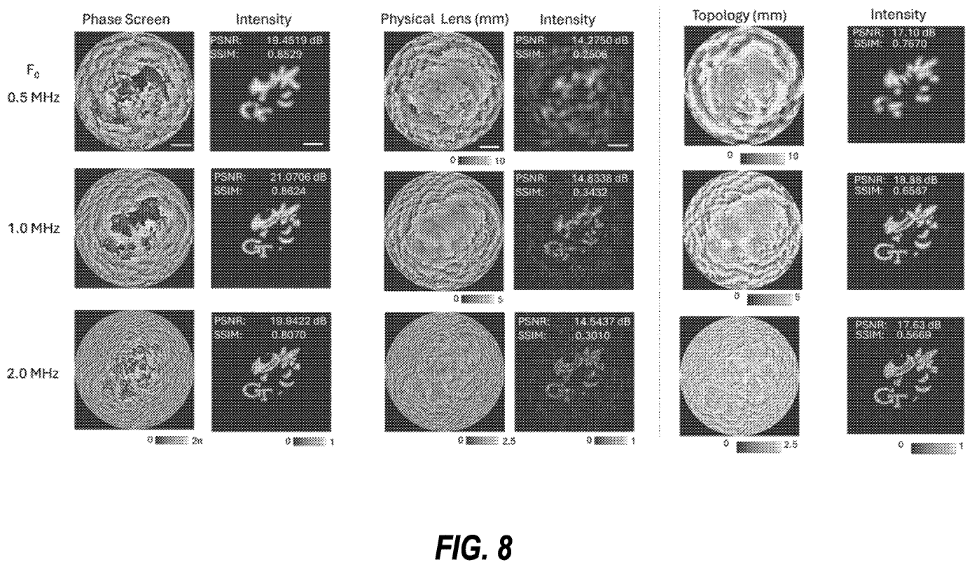

FIG. 8 illustrates a comparative array of acoustic holography results generated using different lens design approaches across multiple operating frequencies, according to examples of the disclosed technology. FIG. 8 depicts reconstructions of a target intensity pattern produced at operating frequencies of approximately 0.5 MHz, approximately 1.0 MHz, and approximately 2.0 MHz, with each operating frequency associated with a phase screen, a physical lens topology obtained by phase-to-thickness conversion, and a topology-optimized lens obtained by the topology optimization path described with reference to FIG. 5.

For each operating frequency, the phase screen can be represented as a circular spatial map having phase values ranging from zero to 2π, and the phase screen can be accompanied by a corresponding reconstructed intensity field at the target plane. The physical lens topology can be represented as a circular thickness map having thickness values expressed in millimeters, and the physical lens topology can be accompanied by a corresponding reconstructed intensity field at the target plane produced by the physical lens topology. The topology-optimized lens can be represented as a circular thickness map having thickness values expressed in millimeters, and the topology-optimized lens can be accompanied by a corresponding reconstructed intensity field at the target plane produced by the topology-optimized lens. The reconstructed intensity fields can be displayed with a normalized intensity scale ranging from zero to one and can be annotated with a peak signal-to-noise ratio (PSNR) metric and a structural similarity index (SSIM) metric quantifying fidelity of the reconstructed intensity field relative to a target intensity pattern.

In some aspects, a maximum thickness used to bound the thickness distribution of the physical lens topology and the topology-optimized lens can be scaled with the operating frequency. At an operating frequency of approximately 0.5 MHz, the maximum thickness can be approximately 10 mm. At an operating frequency of approximately 1.0 MHz, the maximum thickness can be approximately 5.0 mm. At an operating frequency of approximately 2.0 MHz, the maximum thickness can be approximately 2.5 mm. The maximum thickness used at each operating frequency can correspond to the upper bound tₘₐₓ applied to the thickness distribution by the softplus transformation along the topology optimization path.

In some aspects, a grid resolution used by the heterogeneous angular spectrum approach can also be scaled with the operating frequency. At an operating frequency of approximately 0.5 MHz, the grid resolution can be approximately 0.500 mm. At an operating frequency of approximately 1.0 MHz, the grid resolution can be approximately 0.250 mm. At an operating frequency of approximately 2.0 MHz, the grid resolution can be approximately 0.125 mm. Voxel sizes in lateral and axial directions, denoted dx and dz, can be adapted to approximately λ/6 relative to an acoustic wavelength λ at the operating frequency to reduce numerical aliasing across the operating frequencies of approximately 0.5 MHz, approximately 1.0 MHz, and approximately 2.0 MHz.

The reconstructed intensity fields produced by the phase screens at the operating frequencies of approximately 0.5 MHz, approximately 1.0 MHz, and approximately 2.0 MHz can illustrate idealized reconstructions of the target intensity pattern obtained under a thin-element approximation, with the reconstructed intensity field at approximately 0.5 MHz exhibiting reduced fidelity to the target intensity pattern relative to the reconstructed intensity fields at approximately 1.0 MHz and approximately 2.0 MHz. The reconstructed intensity fields produced by the physical lens topologies at each operating frequency can exhibit degraded fidelity relative to the reconstructed intensity fields produced by the phase screens, with lower PSNR and SSIM values, reflecting volumetric wave propagation effects within the lens material that are not captured by the thin-element approximation used to convert the phase screen into the physical lens topology. The reconstructed intensity fields produced by the topology-optimized lenses at each operating frequency can exhibit improved fidelity relative to the reconstructed intensity fields produced by the physical lens topologies, with higher PSNR and SSIM values, reflecting compensation of the volumetric wave propagation effects through direct topology optimization using the heterogeneous angular spectrum approach.

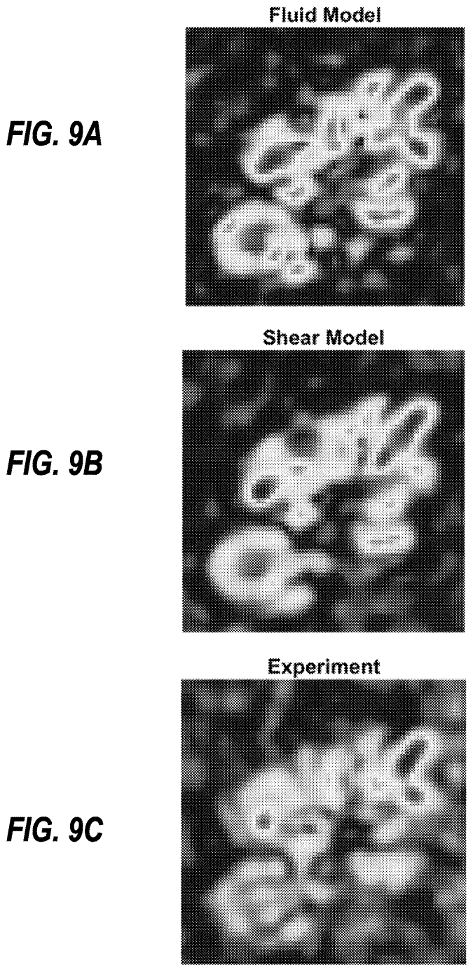

FIGS. 9A-9C illustrate a comparison of normalized acoustic intensity distributions at a target plane for a complex holographic target, according to examples of the disclosed technology. FIG. 9A illustrates a normalized acoustic intensity distribution at the target plane predicted by a fluid model, FIG. 9B illustrates a normalized acoustic intensity distribution at the target plane predicted by a shear model, and FIG. 9C illustrates an experimentally measured normalized acoustic intensity distribution at the target plane acquired via a hydrophone raster scan.

The fluid model of FIG. 9A can correspond to a compressional-only simulation of acoustic wave propagation through the heterogeneous propagation medium, in which shear wave modes within the heterogeneous propagation medium are neglected and acoustic propagation is modeled in terms of longitudinal pressure waves alone. The reconstructed acoustic intensity distribution produced by the fluid model can exhibit relatively sharp edge definition and high contrast against a darker background.

The shear model of FIG. 9B can correspond to a simulation of acoustic wave propagation through the heterogeneous propagation medium that incorporates elastodynamic mode conversion between longitudinal pressure waves and shear waves at interfaces of the heterogeneous propagation medium. The reconstructed acoustic intensity distribution produced by the shear model can exhibit broader features, diffuse edges, and a brighter background haze surrounding the reconstructed target pattern relative to the reconstructed acoustic intensity distribution produced by the fluid model.

The experimentally measured acoustic intensity distribution of FIG. 9C can be acquired by raster scanning a hydrophone across the target plane to sample the acoustic pressure field at a plurality of spatial locations, as described above with reference to the experimental systems of FIG. 1 and FIG. 2. The experimentally measured acoustic intensity distribution can exhibit spatial broadening and off-axis signal leakage that visually corresponds more closely to the broader features and brighter background haze predicted by the shear model of FIG. 9B than to the reconstructed acoustic intensity distribution predicted by the fluid model of FIG. 9A. The closer visual correspondence between the shear model and the experimental measurement can indicate that incorporation of shear wave mode conversion into the simulation of acoustic wave propagation through the heterogeneous propagation medium can improve agreement between simulated and measured acoustic intensity distributions for a complex holographic target.

In some aspects, a forward model of a physical acquisition chain can be applied to a simulated acoustic pressure field produced by the fluid model or the shear model to reproduce blurring and pixelation introduced by the hydrophone raster scan used to acquire the experimentally measured acoustic intensity distribution of FIG. 9C. The forward model of the physical acquisition chain can convolve a high-resolution simulated acoustic pressure field with a disk-shaped spatial kernel representing an active area of a needle hydrophone, and can downsample the convolved acoustic pressure field to an experimental scan grid. In some aspects, the disk-shaped spatial kernel can have a diameter D of approximately 2.0 mm, corresponding to the active area of a 2 mm needle hydrophone, and the experimental scan grid can have a spatial sampling interval of approximately 500 μm.

The forward model of the physical acquisition chain can be expressed by a convolution operation according to the relationship

where Pₛᵢₘ(x,y) denotes the high-resolution simulated acoustic pressure field at lateral coordinates (x,y) at the target plane, H_{disk}(D) denotes the disk-shaped spatial kernel of diameter D representing the active area of the needle hydrophone, * denotes a two-dimensional convolution over the lateral coordinates, and P_{avg}(x,y) denotes a spatially averaged acoustic pressure field that approximates an effective averaging of the acoustic pressure field over the active area of the needle hydrophone.

The spatially averaged acoustic pressure field can be downsampled to the experimental scan grid according to the relationship

where P_{fwd}(i,j) denotes a forward-modeled acoustic pressure field at discrete grid indices (i,j) of the experimental scan grid, (xᵢ,yⱼ) denotes lateral coordinates of the experimental scan grid at grid indices (i,j), and Gridₑₓₚ denotes the experimental scan grid having the spatial sampling interval of approximately 500 μm. The forward-modeled acoustic pressure field P_{fwd}(i,j) can be compared on a common spatial grid against the experimentally measured acoustic intensity distribution of FIG. 9C to evaluate agreement between the fluid model of FIG. 9A or the shear model of FIG. 9B and the experimentally measured acoustic intensity distribution acquired by the hydrophone raster scan.

FIGS. 9D-9E illustrate error maps comparing simulated acoustic intensity distributions produced by the fluid model and the shear model against the experimentally measured acoustic intensity distribution of FIG. 9C, according to examples of the disclosed technology. FIG. 9D illustrates a fluid error map representing a spatial distribution of absolute error between the fluid model of FIG. 9A and the experimentally measured acoustic intensity distribution, and FIG. 9E illustrates a shear error map representing a spatial distribution of absolute error between the shear model of FIG. 9B and the experimentally measured acoustic intensity distribution.

In some aspects, the fluid error map and the shear error map can each be computed as a pixel-wise absolute difference between a forward-modeled acoustic intensity distribution and the experimentally measured acoustic intensity distribution on a common spatial grid. The forward-modeled acoustic intensity distribution can be obtained by applying the forward model of the physical acquisition chain described above with reference to FIGS. 9A-9C to a high-resolution simulated acoustic pressure field produced by the fluid model or the shear model, such that the fluid error map and the shear error map can be evaluated on the experimental scan grid against the experimentally measured acoustic intensity distribution.

The fluid error map of FIG. 9D and the shear error map of FIG. 9E can each be displayed as a grayscale image accompanied by a normalized error scale. In some aspects, the normalized error scale can range from approximately 0 to approximately 0.6, with brighter regions of the error map corresponding to higher error magnitudes and darker regions of the error map corresponding to lower error magnitudes. The fluid error map of FIG. 9D and the shear error map of FIG. 9E can each exhibit residual structural features distributed across a region of the target plane corresponding to the complex holographic target.

A mean squared error (MSE) metric can be associated with each of the fluid error map and the shear error map to quantify agreement between the corresponding simulation model and the experimentally measured acoustic intensity distribution. In some aspects, the fluid error map of FIG. 9D can have an MSE of approximately 0.0230, and the shear error map of FIG. 9E can have an MSE of approximately 0.0163.

The shear error map of FIG. 9E can exhibit reduced residual artifacts and reduced error magnitudes relative to the fluid error map of FIG. 9D across the region of the target plane. The reduction in residual artifacts and the lower MSE associated with the shear error map relative to the fluid error map can indicate an improvement in reconstruction fidelity when elastodynamic shear mode conversion between longitudinal pressure waves and shear waves at interfaces of the heterogeneous propagation medium is incorporated into the simulation of acoustic wave propagation through the heterogeneous propagation medium.

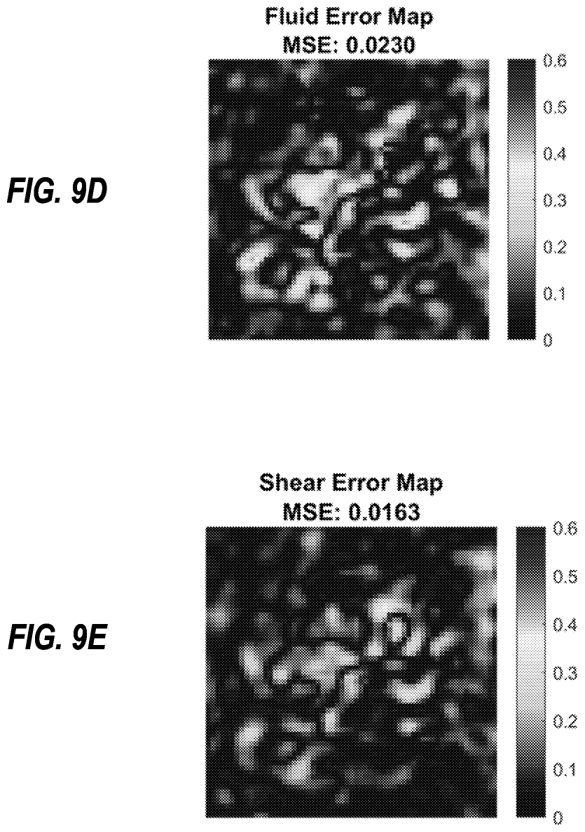

FIG. 10 illustrates a bar graph comparing performance of the fluid model and the shear model in terms of the MSE metric and a correlation coefficient metric, according to examples of the disclosed technology. The bar graph of FIG. 10 can quantify agreement between simulated acoustic intensity distributions produced by the fluid model and the shear model and the experimentally measured acoustic intensity distribution acquired by the hydrophone raster scan.

In some aspects, the bar graph of FIG. 10 can include a left vertical axis corresponding to the MSE metric and a right vertical axis corresponding to the correlation coefficient metric, with grouped bars for the fluid model and the shear model displayed under an MSE category and a correlation coefficient category. The MSE metric can be computed as a pixel-wise mean squared difference between a forward-modeled acoustic intensity distribution and the experimentally measured acoustic intensity distribution on a common spatial grid, and the correlation coefficient metric can be computed as a spatial correlation between the forward-modeled acoustic intensity distribution and the experimentally measured acoustic intensity distribution.

In some aspects, the fluid model can yield an MSE of approximately 0.023 and the shear model can yield an MSE of approximately 0.016, corresponding to an error reduction of approximately 29.1% relative to the fluid model. In some aspects, the fluid model can yield a correlation coefficient of approximately 0.63 and the shear model can yield a correlation coefficient of approximately 0.68. In other aspects, the fluid model can yield a correlation coefficient of approximately 0.864 and the shear model can yield a correlation coefficient of approximately 0.942, depending on a region of interest and a normalization applied to the forward-modeled acoustic intensity distribution and the experimentally measured acoustic intensity distribution. The reduced MSE and the increased correlation coefficient associated with the shear model relative to the fluid model can indicate that incorporation of elastodynamic shear mode conversion into the simulation of acoustic wave propagation through the heterogeneous propagation medium can improve agreement between simulated and measured acoustic intensity distributions.

In some aspects, the heterogeneous angular spectrum approach implemented by the HASA-ADAM framework can be supplemented or replaced by an elastic wave propagation model that incorporates longitudinal-to-shear mode conversion at lens interfaces and at interfaces of the heterogeneous propagation medium. The elastic wave propagation model can account for phase aberration and refractive steering arising from conversion of longitudinal pressure waves into shear waves at the lens interfaces, such that the iterative optimization loop can pre-compensate for the phase aberration and the refractive steering during design of the acoustic lens.

In some aspects, the elastic wave propagation model can be implemented using a pseudospectral time-domain elastic solver, such as a pstdElastic3D solver. The pseudospectral time-domain elastic solver can assign acoustic properties to voxels of the heterogeneous propagation medium based on a density threshold derived from the three-dimensional acoustic property map. In some aspects, voxels of the heterogeneous propagation medium having a density above a density threshold of approximately 1100 kg/m³ can be identified as skull voxels and can be assigned a shear wave speed of approximately 1400 m/s and a shear attenuation of approximately 20 dB/cm, while voxels of the heterogeneous propagation medium having a density at or below the density threshold can be modeled in terms of longitudinal pressure waves alone. In some aspects, the pseudospectral time-domain elastic solver can be configured with a Courant-Friedrichs-Lewy (CFL) number of approximately 0.1 to facilitate numerical stability of the elastic wave propagation model.

A simulated acoustic intensity distribution produced by the elastic wave propagation model can be compared against the experimentally measured acoustic intensity distribution in accordance with the MSE metric and the correlation coefficient metric described with reference to FIG. 10, and the simulated acoustic intensity distribution produced by the elastic wave propagation model can be substituted for the simulated intensity distribution computed by the heterogeneous angular spectrum approach during the iterative optimization loop to refine the thickness distribution of the acoustic lens in a manner that accounts for longitudinal-to-shear mode conversion at the lens interfaces and at the interfaces of the heterogeneous propagation medium.

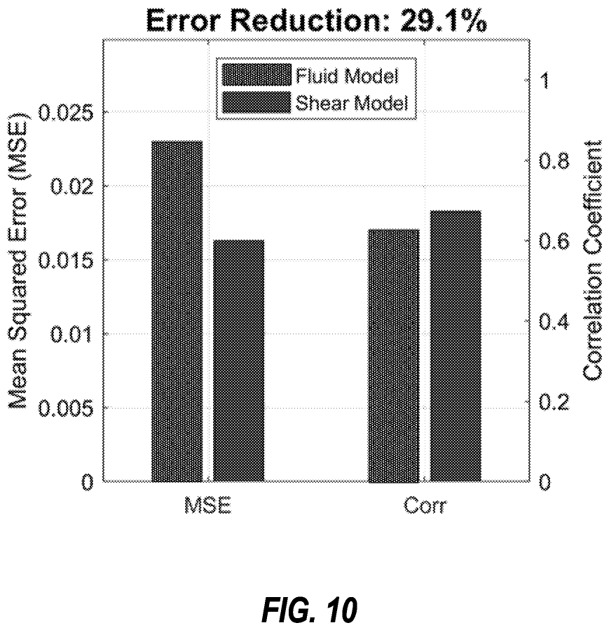

FIG. 11 illustrates a schematic comparison of a phase optimization path and a topology optimization path for transcranial wave focusing, according to examples of the disclosed technology. The schematic comparison of FIG. 11 can contrast a region across which an optimization variable is defined under the phase optimization path with a region across which an optimization variable is defined under the topology optimization path, and can illustrate how acoustic waves emitted by a transducer propagate through an acoustic lens and through a skull to a focusing region in each path.

In an upper portion of FIG. 11, the phase optimization path is illustrated. The phase optimization path can include a transducer positioned at a base of the schematic and an acoustic lens having a sawtooth-like thickness profile arranged above the transducer along an axial z-direction. An optimization plane can be defined above the acoustic lens and can be oriented transverse to the axial z-direction. The optimization plane can correspond to a two-dimensional surface across which a phase distribution of the acoustic lens is computed during the phase optimization path. A skull can be positioned above the optimization plane along the axial z-direction, and acoustic waves emitted by the transducer can propagate through the acoustic lens, across the optimization plane, and through the skull to converge at a focusing region located distal to the skull along the axial z-direction. The phase optimization path can reference the optimization plane as the two-dimensional surface for computing the phase distribution, such that volumetric wave propagation within the acoustic lens is approximated by a phase accumulation accumulated across the two-dimensional surface.

In a lower portion of FIG. 11, the topology optimization path is illustrated. The topology optimization path can include a transducer positioned at a base of the schematic and an acoustic lens arranged above the transducer along the axial z-direction. In contrast to the phase optimization path, the acoustic lens of the topology optimization path can be associated with an optimization volume rather than a single optimization plane. The optimization volume can be defined as a region having a finite axial extent along the axial z-direction and can contain a three-dimensional topographical profile of the acoustic lens that varies along the axial z-direction and along lateral directions transverse to the axial z-direction. The optimization volume can be discretized along the axial z-direction by an axial step size ΔZ. In some aspects, the axial step size ΔZ can be approximately 250 μm. A skull can be positioned above the optimization volume along the axial z-direction, and acoustic waves emitted by the transducer can propagate through the acoustic lens defined by the three-dimensional topographical profile within the optimization volume and through the skull to converge at a focusing region located distal to the skull along the axial z-direction.

In both the phase optimization path and the topology optimization path illustrated in FIG. 11, acoustic waves emitted by the transducer can propagate through the acoustic lens and through the skull to converge at the focusing region. The phase optimization path can compute a phase distribution at the optimization plane and can subsequently convert the phase distribution to a thickness map of the acoustic lens according to a wavenumber-based relationship, as described above with reference to FIG. 6. The topology optimization path can directly compute the three-dimensional topographical profile of the acoustic lens within the optimization volume using the heterogeneous angular spectrum approach, as described above with reference to FIG. 5, such that the topology optimization path accounts for volumetric wave propagation within the acoustic lens during iterative optimization of the thickness distribution.

In some aspects, the heterogeneous angular spectrum approach used by the topology optimization path can march an acoustic pressure field through the optimization volume using an axial marching step size of approximately 150 μm, corresponding to approximately λ/6 at an operating frequency of approximately 1 MHz, to facilitate computational stability of the forward marching scheme through the optimization volume. In some aspects, the axial marching step size used by the heterogeneous angular spectrum approach can be approximately 250 μm, corresponding to the axial step size ΔZ of the optimization volume illustrated in FIG. 11.

In some aspects, computational grids used by the heterogeneous angular spectrum approach within the topology optimization path can be zero-padded by approximately N/2 on all boundaries during forward propagation through the optimization volume, where N denotes a transverse grid size. The spatial padding applied to the computational grids can reduce spatial aliasing and circular convolution artifacts associated with a discrete Fourier transform used by the heterogeneous angular spectrum approach across the finite axial extent of the optimization volume.

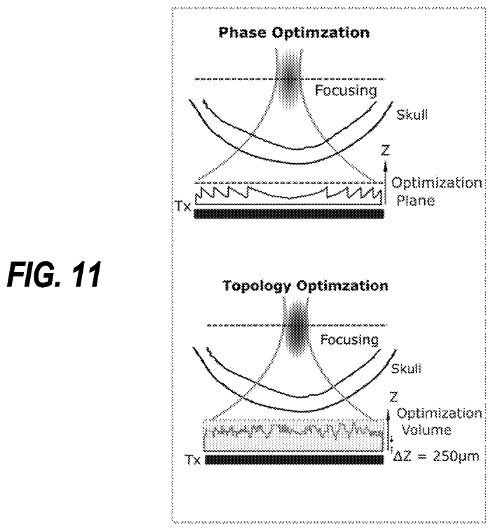

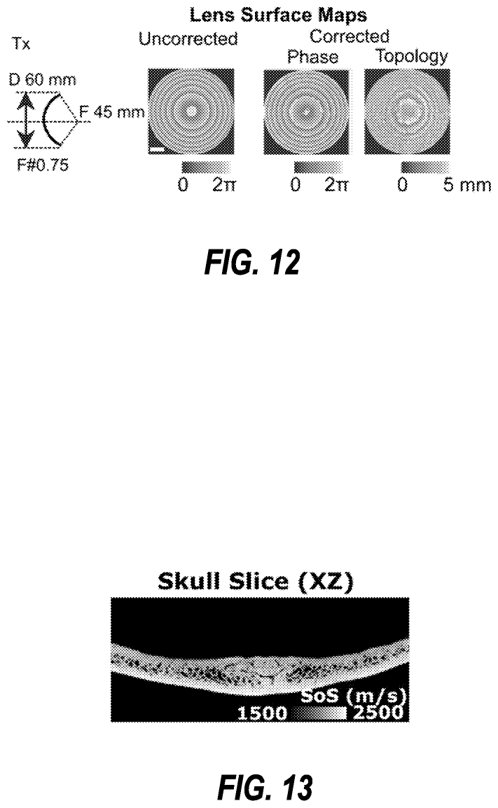

FIG. 12 illustrates lens surface maps for a transcranial acoustic holography system, and FIG. 13 illustrates a skull slice in an XZ plane showing spatially varying acoustic properties, according to examples of the disclosed technology. FIG. 12 and FIG. 13 can together illustrate inputs and outputs of the HASA-ADAM framework applied to transcranial wave focusing, including a transducer geometry, a free-field phase distribution, a skull-corrected phase distribution, a skull-corrected topology distribution, and a cross-sectional acoustic property map of the heterogeneous propagation medium.

As shown in FIG. 12, the transcranial acoustic holography system can include a schematic of a transducer characterized by an aperture diameter, a focal length, and an F-number. In some aspects, the transducer can have an aperture diameter of approximately 60 mm, a focal length of approximately 45 mm, and an F-number of approximately 0.75, corresponding to a hologram aperture sized for transcranial applications targeting a focal region within tissue distal to a skull. In some aspects, the transducer can alternatively be configured with an F-number of approximately 1.0, corresponding to a focal length of approximately 60 mm, to provide focal targets at deeper axial positions distal to the skull. The aperture diameter, the focal length, and the F-number of the transducer can establish a hologram aperture diameter D and a focal depth z used by the heterogeneous angular spectrum approach to simulate forward propagation through the acoustic lens and through the heterogeneous propagation medium to the target plane.

FIG. 12 can further include three lens surface maps that illustrate alternative outputs of the HASA-ADAM framework for a common transcranial focusing target. A first lens surface map can correspond to an uncorrected phase map, which can represent a phase distribution computed for focusing in a free field without compensation for skull aberration. The uncorrected phase map can be displayed as a series of concentric ring patterns having phase values ranging from zero to 2π. A second lens surface map can correspond to a corrected phase map, which can represent a phase distribution computed by the phase optimization path of the HASA-ADAM framework with the spatially varying speed of sound distribution and the spatially varying density distribution of the skull incorporated into the heterogeneous angular spectrum approach. The corrected phase map can be displayed as a concentric ring pattern with distortions in ring geometry relative to the uncorrected phase map, having phase values ranging from zero to 2π. A third lens surface map can correspond to a corrected topology map, which can represent a thickness distribution output by the topology optimization path of the HASA-ADAM framework. The corrected topology map can be displayed as a thickness distribution having thickness values ranging from zero to approximately 5 mm, and can exhibit an irregular surface profile with concentric features and localized variations that compensate skull-induced aberrations through direct topology optimization.

FIG. 13 illustrates a skull slice in an XZ plane showing a cross-sectional view of cranial bone with spatially varying acoustic properties. The skull slice can illustrate a heterogeneous internal structure of the cranial bone, including porous trabecular regions and denser cortical layers. The skull slice can be displayed with a grayscale gradient that encodes speed of sound values in meters per second, ranging from approximately 1500 m/s to approximately 2500 m/s. The speed of sound values illustrated by the skull slice can correspond to the spatially varying speed of sound distribution of the three-dimensional acoustic property map used by the heterogeneous angular spectrum approach during the iterative optimization.

In some aspects, the heterogeneous propagation medium can comprise a skull, and receiving the three-dimensional acoustic property map can comprise deriving the spatially varying speed of sound distribution and the spatially varying density distribution from micro-computed tomography (micro-CT) data of the skull. The micro-CT data of the skull can be processed to generate a three-dimensional speed of sound map c(r) and a three-dimensional density map ρ(r) at voxel locations r spanning a propagation domain that contains the acoustic lens, the skull, and the target plane. In some aspects, the micro-CT data can be acquired at an original spatial resolution of approximately 95 μm and binned to a working spatial resolution of approximately 150 μm, which can provide approximately 10 points per acoustic wavelength at an operating frequency of approximately 1 MHz in a background medium having an equilibrium speed of sound of approximately 1480 m/s.

In some aspects, the three-dimensional acoustic property map can be derived from the micro-CT data of the skull using a porosity-dependent mixture model. The porosity-dependent mixture model can normalize CT voxel intensities against a water baseline and an air baseline to obtain Hounsfield units H for each voxel of the skull, and can compute a volumetric porosity fraction of the cranial bone according to the relationship

A density ρ and a longitudinal speed of sound c can be assigned to each voxel of the skull by linearly interpolating between a water baseline having c=1480 m/s and ρ=1000 kg/m³ and an upper limit of dense cortical bone having cₘₐₓ=2500 m/s and ρₘₐₓ=2200 kg/m³, proportional to a solid bone fraction (1−Ψ). The voxel-wise density and longitudinal speed of sound assigned by the porosity-dependent mixture model can populate the spatially varying density distribution and the spatially varying speed of sound distribution of the three-dimensional acoustic property map, such that the heterogeneous angular spectrum approach can account for spatially varying acoustic properties across the porous trabecular regions and the denser cortical layers of the skull illustrated in FIG. 13.

In some aspects, the three-dimensional acoustic property map can be derived from magnetic resonance imaging (MRI) scan data of a patient in addition to or in place of the micro-CT data of the skull. MRI-derived property maps can be used to generate the spatially varying speed of sound distribution and the spatially varying density distribution of the three-dimensional acoustic property map for patient-specific design of the acoustic lens, for example when MRI scan data is available in lieu of micro-CT data.

In some aspects, the heterogeneous propagation medium can include aberrating layers other than skull bone. For example, the heterogeneous propagation medium can include a fat layer, a bone structure other than the skull, or a combination of soft tissue and bone, such that the disclosed technology can be applied to industrial applications including non-destructive testing as well as to transcranial focused ultrasound applications. In some aspects, the disclosed technology can also be applied to diagnostic ultrasound imaging through thick bone structures to enhance image quality. For industrial applications, the spatially varying speed of sound distribution and the spatially varying density distribution of the three-dimensional acoustic property map can be derived from computed tomography, micro-computed tomography, or alternative volumetric imaging modalities suitable for the heterogeneous propagation medium being characterized.

In some aspects, the three-dimensional acoustic property map can be supplied to a validation simulation of the heterogeneous angular spectrum approach. For example, a k-wave validation simulation can be configured with skull material properties including a maximum cortical bone speed of approximately 2500 m/s and a maximum cortical bone density of approximately 2000 kg/m³, and can use the porosity-dependent mixture model to assign voxel-wise acoustic properties to the heterogeneous propagation medium. A simulated acoustic intensity distribution produced by the validation simulation can be compared against a simulated acoustic intensity distribution produced by the heterogeneous angular spectrum approach to evaluate agreement between the heterogeneous angular spectrum approach and the validation simulation across the spatially varying speed of sound distribution and the spatially varying density distribution of the heterogeneous propagation medium.

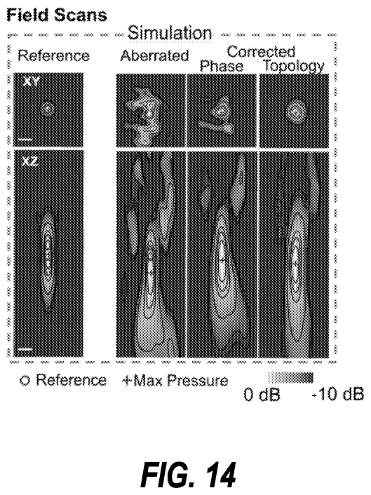

FIG. 14 illustrates simulated acoustic pressure field scan results comparing a reference configuration, an aberrated configuration, a phase-corrected configuration, and a topology-corrected configuration, according to examples of the disclosed technology. The simulated acoustic pressure field scan results illustrated in FIG. 14 can be displayed in a transverse plane at the target plane and in a sagittal plane along the acoustic propagation direction, such that focal performance of each configuration can be evaluated in both lateral and axial dimensions.

In the reference configuration, the simulated acoustic pressure field in the transverse plane can exhibit a tightly confined focal spot at a reference location indicated by a reference marker, and the simulated acoustic pressure field in the sagittal plane can exhibit an elongated focal region aligned with the acoustic propagation direction. The reference configuration can correspond to a simulation in which acoustic waves propagate to the target plane without an intervening heterogeneous propagation medium, such that the reference configuration defines a target focal distribution against which other configurations can be compared.

In the aberrated configuration, the simulated acoustic pressure field in the transverse plane can exhibit a distorted and scattered pressure distribution at the target plane, and the simulated acoustic pressure field in the sagittal plane can exhibit a broadened and irregular pressure distribution along the acoustic propagation direction. A maximum pressure location of the aberrated configuration can be displaced from the reference location, illustrating that propagation of acoustic waves through the heterogeneous propagation medium without compensation for skull-induced aberrations can shift and degrade the focal region relative to the reference configuration.

In the phase-corrected configuration, the simulated acoustic pressure field can correspond to a configuration in which an acoustic lens having a thickness distribution obtained by converting a converged phase profile of the phase optimization path described above with reference to FIG. 6 to a thickness map is positioned between a transducer and the heterogeneous propagation medium. The simulated acoustic pressure field in the transverse plane can exhibit a partially restored focal pattern at the target plane with reduced but residual aberration artifacts relative to the aberrated configuration, and the simulated acoustic pressure field in the sagittal plane can exhibit a focal region more closely aligned with the acoustic propagation direction relative to the aberrated configuration. A maximum pressure location of the phase-corrected configuration can be positioned near but offset from the reference location.

In the topology-corrected configuration, the simulated acoustic pressure field can correspond to a configuration in which an acoustic lens having a converged thickness distribution output by the topology optimization path described above with reference to FIG. 5 is positioned between the transducer and the heterogeneous propagation medium. The simulated acoustic pressure field in the transverse plane can exhibit a focal pattern at the target plane that substantially matches the reference distribution, with concentric contours surrounding a central peak, and the simulated acoustic pressure field in the sagittal plane can exhibit a well-confined elongated focal region along the acoustic propagation direction. A maximum pressure location of the topology-corrected configuration can be substantially coincident with the reference location, illustrating that direct topology optimization can compensate skull-induced aberrations such that the focal distribution at the target plane substantially matches the reference distribution.

In some aspects, the simulated acoustic pressure fields illustrated in FIG. 14 can be displayed using a normalized intensity scale spanning from approximately 0 dB to approximately −10 dB, with a grayscale gradient encoding the normalized intensity values. The transverse plane and the sagittal plane can each be accompanied by a scale bar that indicates spatial dimensions of the simulated acoustic pressure field at the target plane and along the acoustic propagation direction.

In some aspects, the simulated acoustic pressure field scan results illustrated in FIG. 14 can be generated using a full-wave time-domain solver that simulates acoustic wave propagation through the heterogeneous propagation medium. For example, the full-wave time-domain solver can be implemented using the k-Wave toolbox. In some aspects, the full-wave time-domain solver can be configured with a spatial grid size of approximately dx=dy=250 μm and a Courant-Friedrichs-Lewy (CFL) number below approximately 0.3 for fluid simulations of acoustic wave propagation through the heterogeneous propagation medium.

In some aspects, attenuation within the full-wave time-domain solver for the fluid simulations can follow a power law expressed by the relationship

where α denotes an attenuation coefficient, α₀ denotes a reference attenuation coefficient, f denotes an operating frequency, and β denotes a power law exponent. In some aspects, the power law exponent β can be approximately 1.2 for the fluid simulations of acoustic wave propagation through the heterogeneous propagation medium.

A comparison of the reference configuration, the aberrated configuration, the phase-corrected configuration, and the topology-corrected configuration illustrated in FIG. 14 can illustrate that the topology-corrected configuration produced by the topology optimization path of the HASA-ADAM framework can restore focal pressure to the reference location with a focal distribution that more closely matches the reference distribution than the phase-corrected configuration, while the aberrated configuration without compensation for skull-induced aberrations can exhibit a focal distribution that is distorted and displaced from the reference location.

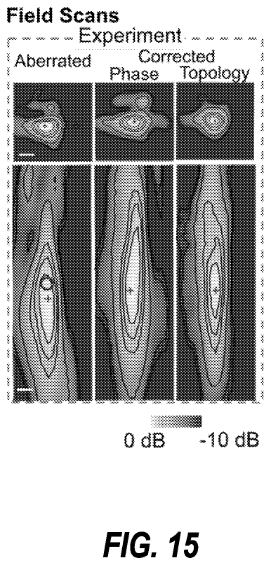

FIG. 15 illustrates experimental acoustic pressure field scan results for an aberrated configuration, a corrected phase configuration, and a corrected topology configuration, according to examples of the disclosed technology. The experimental acoustic pressure field scan results illustrated in FIG. 15 can be acquired using the experimental system described above with reference to FIG. 1 and FIG. 2, in which the hydrophone 110 raster scans the acoustic pressure field transmitted through the acoustic lens and the skull 115 across a transverse plane at the target plane and a sagittal plane along the acoustic propagation direction.

The experimental acoustic pressure field scan results illustrated in FIG. 15 can be displayed in a transverse plane at the target plane and in a sagittal plane along the acoustic propagation direction, such that focal performance of each configuration can be evaluated in both lateral and axial dimensions. In some aspects, the experimental acoustic pressure field scan results can be displayed using a normalized intensity scale spanning from approximately 0 dB to approximately −10 dB, with a grayscale gradient encoding the normalized intensity values. A scale bar can be provided in the transverse plane and in the sagittal plane to indicate spatial dimensions of the experimental acoustic pressure field at the target plane and along the acoustic propagation direction.

In the aberrated configuration, the experimentally measured acoustic pressure field in the transverse plane can exhibit a distorted pressure distribution with off-axis lobes at the target plane, and the experimentally measured acoustic pressure field in the sagittal plane can exhibit a broadened and shifted focal region along the acoustic propagation direction. A reference location can be indicated by a reference marker in the sagittal plane, and a maximum pressure location of the aberrated configuration can be indicated by a focal peak marker that is displaced from the reference location, illustrating that propagation of acoustic waves through the skull 115 without compensation for skull-induced aberrations can shift and degrade the experimentally measured focal region relative to the reference location.

In the corrected phase configuration, the acoustic lens positioned between the transducer 105 and the skull 115 can have a thickness distribution obtained by converting a converged phase profile of the phase optimization path described above with reference to FIG. 6 to a thickness map. The experimentally measured acoustic pressure field in the transverse plane can exhibit an improved focal pattern with reduced but residual irregularity relative to the aberrated configuration, and the experimentally measured acoustic pressure field in the sagittal plane can exhibit a focal region that is more confined and more closely aligned with the acoustic propagation direction relative to the aberrated configuration. A maximum pressure location of the corrected phase configuration in the sagittal plane can be positioned near but offset from the reference location.

In the corrected topology configuration, the acoustic lens positioned between the transducer 105 and the skull 115 can have a converged thickness distribution output by the topology optimization path described above with reference to FIG. 5. The experimentally measured acoustic pressure field in the transverse plane can exhibit a more confined and more symmetric focal spot relative to the aberrated configuration and the corrected phase configuration, and the experimentally measured acoustic pressure field in the sagittal plane can exhibit a more confined and more aligned focal region with a maximum pressure location indicated by a focal peak marker substantially coincident with the reference location. The corrected topology configuration can thereby illustrate that direct topology optimization through the heterogeneous angular spectrum approach can compensate skull-induced aberrations during experimental trans-skull field scans such that the experimentally measured focal distribution at the target plane substantially matches the focal distribution at the reference location.

In some aspects, the acoustic lens used in the corrected phase configuration and the corrected topology configuration can be fabricated by three-dimensional printing of a polymer from the converged thickness distribution, as described above with reference to the step 385. The acoustic lens can be fabricated with manufacturing tolerances of approximately ±0.05 mm to approximately ±0.1 mm, corresponding to approximately 5% of a lens thickness, which can be typical of stereolithography three-dimensional printing of polymer materials. The manufacturing tolerances of the stereolithography three-dimensional printing process can contribute to experimental discrepancies between the experimentally measured acoustic pressure field illustrated in FIG. 15 and a simulated acoustic pressure field predicted for the same acoustic lens, such as the simulated acoustic pressure field described above with reference to FIG. 14.

In some aspects, the polymer used to fabricate the acoustic lens can have a longitudinal group velocity of approximately 2591 m/s and an attenuation of approximately 2.922 dB·MHz^{-1.044}·cm⁻¹ at operating frequencies used during the experimental trans-skull field scans. In some aspects, the polymer can have a density of approximately 1178 kg/m³. The longitudinal group velocity and the attenuation of the polymer can be used as the speed of sound and the attenuation of the lens material in the heterogeneous angular spectrum approach implemented at the step 360, and the density of the polymer can be used as the density of the lens material in the heterogeneous angular spectrum approach implemented at the step 360, such that the iterative optimization 340 can account for acoustic properties of the lens material during forward propagation of the acoustic pressure field through the acoustic lens. Deviation between the longitudinal group velocity and the attenuation assumed during the iterative optimization 340 and corresponding acoustic properties of a fabricated polymer lens can further contribute to experimental discrepancies between the experimentally measured acoustic pressure field illustrated in FIG. 15 and a corresponding simulated acoustic pressure field.

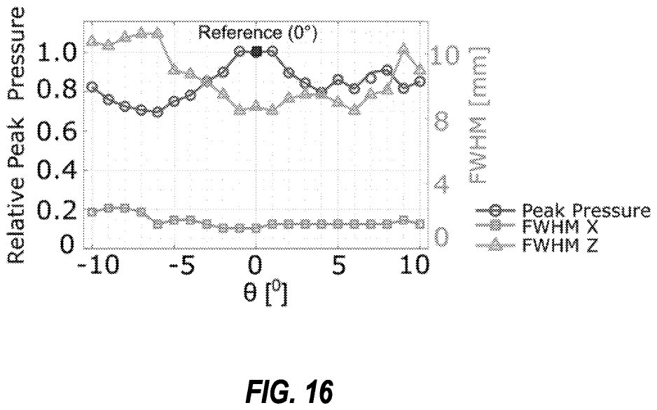

FIG. 16 illustrates an effect of skull rotation angle θ on relative peak pressure and on full width at half maximum (FWHM) of a focal acoustic pressure field generated by an acoustic lens having a converged thickness distribution output by the topology optimization path described above with reference to FIG. 5. The effect illustrated in FIG. 16 can characterize sensitivity of focal performance to angular misregistration between the acoustic lens and the skull 115, as the skull 115 is rotated about a rotational axis defined by a rotational fixture of the experimental system described above with reference to FIG. 2.

In some aspects, the framework described above can simulate registration errors by rotating the heterogeneous propagation medium relative to a transducer-lens assembly comprising the transducer 105 and the acoustic lens, such that the heterogeneous angular spectrum approach is evaluated with the three-dimensional acoustic property map of the heterogeneous propagation medium rotated through the rotation angle θ about the rotational axis. The rotation angle θ can be varied across a range of negative and positive rotation angles to introduce a controlled angular misregistration between the transducer-lens assembly and the heterogeneous propagation medium, such that focal performance can be characterized as a function of the rotation angle θ.

In some aspects, the rotation angle θ illustrated in FIG. 16 can range from approximately −10 degrees to approximately +10 degrees. The relative peak pressure can be plotted on a normalized scale ranging from approximately 0 to approximately 1.0, and the FWHM can be plotted in millimeters along a lateral X direction and along an axial Z direction, with a range of approximately 0 mm to approximately 10 mm. A reference condition at a rotation angle of approximately 0 degrees can correspond to a configuration in which the acoustic lens and the heterogeneous propagation medium are aligned without angular misregistration.

The relative peak pressure can exhibit a maximum value at the rotation angle of approximately 0 degrees, corresponding to the reference condition in which the acoustic lens and the heterogeneous propagation medium are aligned. As the rotation angle θ deviates in either a positive direction or a negative direction from approximately 0 degrees, the relative peak pressure can decrease, reaching reduced values of approximately 0.7 near a rotation angle of approximately −7 degrees and recovering to approximately 0.85 at extremes of the rotation range. The decrease in relative peak pressure with increasing magnitude of the rotation angle θ can reflect a degradation of focal pressure due to angular misregistration between the acoustic lens and the heterogeneous propagation medium.

The FWHM in the lateral X direction can remain relatively flat and low across the range of rotation angles, with values near approximately 1 mm to approximately 2 mm, indicating limited variation in lateral beam width with skull rotation. The FWHM in the axial Z direction can exhibit higher values, generally between approximately 8 mm and approximately 10 mm, with elevated values near negative rotation extremes and at rotation angles of approximately +9 degrees, and lower values near the rotation angle of approximately 0 degrees. The axial FWHM can therefore vary more substantially with skull rotation than the lateral FWHM, indicating that angular misregistration between the acoustic lens and the heterogeneous propagation medium can affect axial confinement of the focal region more strongly than lateral confinement.

In some aspects, the effect of skull rotation angle θ illustrated in FIG. 16 can be used to evaluate sensitivity of focal performance of the acoustic lens to registration errors that can arise during clinical or experimental positioning of the transducer-lens assembly relative to the skull 115. By simulating registration errors through controlled rotation of the heterogeneous propagation medium relative to the transducer-lens assembly, a tolerance range of rotation angles within which the relative peak pressure, the lateral FWHM, and the axial FWHM remain within an acceptable focal performance window can be characterized prior to fabrication of the acoustic lens by three-dimensional printing of a polymer based on the converged thickness distribution.

In some aspects, the rotation angle θ used to characterize sensitivity of focal performance can be applied within the heterogeneous angular spectrum approach by transforming the three-dimensional acoustic property map of the heterogeneous propagation medium through a rotation operator that rotates the spatially varying speed of sound distribution and the spatially varying density distribution about the rotational axis. The rotated three-dimensional acoustic property map can then be used by the heterogeneous angular spectrum approach to simulate forward propagation of the acoustic pressure field through the acoustic lens defined by the converged thickness distribution and through the rotated heterogeneous propagation medium to the target plane, such that the relative peak pressure, the lateral FWHM, and the axial FWHM can be computed from the simulated acoustic pressure field at the target plane.

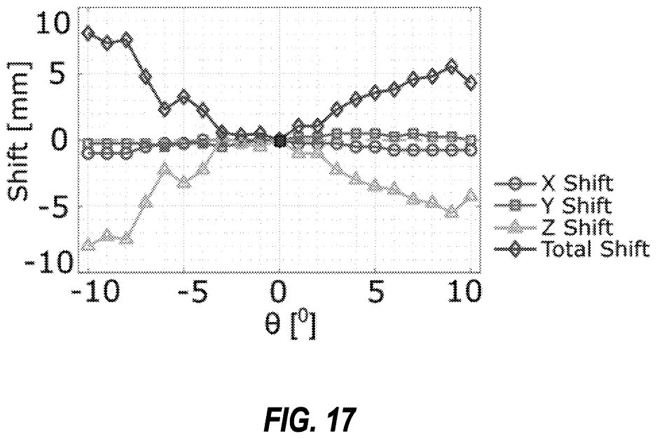

FIG. 17 illustrates an effect of skull rotation angle θ on focal shift of a focal acoustic pressure field generated by an acoustic lens having a converged thickness distribution output by the topology optimization path described above with reference to FIG. 5. FIG. 17 can complement the focal performance characterization described above with reference to FIG. 16 by quantifying spatial displacement of a focal peak relative to a reference focal location as the skull 115 is rotated about a rotational axis defined by a rotational fixture of the experimental system described above with reference to FIG. 2.

In some aspects, the rotation angle θ illustrated in FIG. 17 can range from approximately −10 degrees to approximately +10 degrees. The focal shift can be plotted in millimeters along a lateral X direction, a lateral Y direction, and an axial Z direction, and a total shift representing a combined magnitude of focal displacement along the lateral X direction, the lateral Y direction, and the axial Z direction can also be plotted. The focal shift along each direction can be computed as a difference between a coordinate of a maximum pressure location of the simulated acoustic pressure field at the target plane and a corresponding coordinate of the reference focal location at the rotation angle of approximately 0 degrees.

The focal shift along the lateral X direction can remain relatively flat and close to zero across the range of rotation angles, indicating limited lateral displacement of the focal peak along the lateral X direction with skull rotation. The focal shift along the lateral Y direction can similarly remain close to zero across the range of rotation angles, indicating limited lateral displacement of the focal peak along the lateral Y direction with skull rotation. The focal shift along the axial Z direction can exhibit a substantial linear-like decrease with the rotation angle θ, ranging from approximately −8 mm at a rotation angle of approximately −10 degrees, passing through approximately zero at a rotation angle of approximately 0 degrees, and continuing to approximately −5 mm at a rotation angle of approximately +10 degrees. The total shift can follow a generally V-shaped profile with a minimum near the rotation angle of approximately 0 degrees and increasing magnitudes at negative and positive rotation extremes, reaching approximately 9 mm at a rotation angle of approximately −10 degrees and approximately 5 mm at a rotation angle of approximately +10 degrees.

In some aspects, rotation of the skull 115 about the rotational axis can induce a coupled lateral translation of an acoustic propagation path through the skull 115 relative to the transducer-lens assembly comprising the transducer 105 and the acoustic lens. The coupled lateral translation can modify an effective aberration path through the spatially varying speed of sound distribution and the spatially varying density distribution of the heterogeneous propagation medium, such that the focal peak of the simulated acoustic pressure field can be displaced along the axial Z direction even when the lateral X direction and the lateral Y direction exhibit comparatively small focal displacements. The asymmetry of the focal shift along the axial Z direction with respect to positive and negative rotation angles can reflect asymmetry of the spatially varying acoustic properties of the skull 115 along the acoustic propagation path through the heterogeneous propagation medium.

In some aspects, the focal shift along the lateral X direction, the lateral Y direction, the axial Z direction, and the total shift illustrated in FIG. 17 can be computed by applying the rotation operator described above with reference to FIG. 16 to the three-dimensional acoustic property map of the heterogeneous propagation medium, simulating forward propagation of the acoustic pressure field through the acoustic lens defined by the converged thickness distribution and through the rotated heterogeneous propagation medium to the target plane using the heterogeneous angular spectrum approach, and identifying coordinates of a maximum pressure location of the simulated acoustic pressure field at each rotation angle θ.

In some aspects, the framework described above can be used to evaluate sensitivity of trans-skull focal performance of the acoustic lens to angular misregistration between the transducer-lens assembly and the skull 115. By simulating registration errors through controlled rotation of the heterogeneous propagation medium relative to the transducer-lens assembly and quantifying the focal shift along the lateral X direction, the lateral Y direction, the axial Z direction, and the total shift, a tolerance range of rotation angles within which the focal shift remains within an acceptable focal placement window can be characterized prior to fabrication of the acoustic lens by three-dimensional printing of a polymer based on the converged thickness distribution. In some aspects, the sensitivity of trans-skull focal performance characterized using the framework can inform design of registration procedures for clinical or experimental positioning of the transducer-lens assembly relative to the skull 115, such that angular misregistration can be constrained to a range within which focal shift along the axial Z direction and the total shift remain below predetermined thresholds.

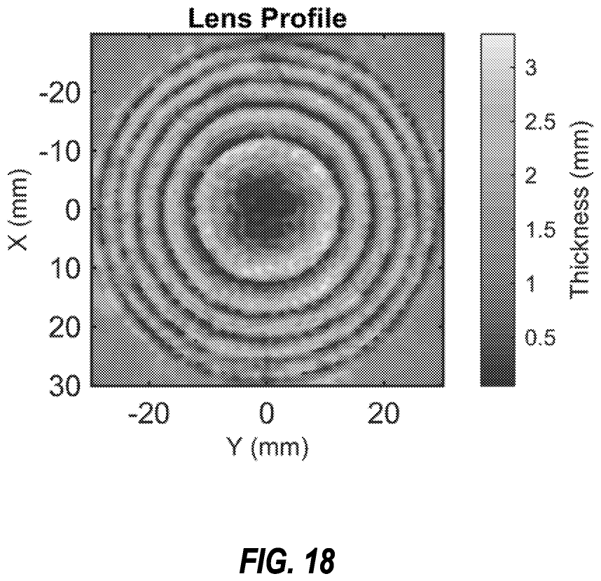

FIG. 18 illustrates a two-dimensional thickness map of a lens profile, according to examples of the disclosed technology. The two-dimensional thickness map of FIG. 18 can correspond to a converged thickness distribution output by the topology optimization path described above with reference to FIG. 5, and can be displayed as a grayscale image in which thickness values across a lateral X-Y plane of the acoustic lens are encoded by grayscale intensity.

In some aspects, the two-dimensional thickness map illustrated in FIG. 18 can span a lateral Y coordinate ranging from approximately −20 mm to approximately +20 mm and a lateral X coordinate ranging from approximately −20 mm to approximately +30 mm. Thickness values across the two-dimensional thickness map can range from approximately 0.5 mm to greater than approximately 3 mm, with darker grayscale intensities corresponding to lower thickness values and lighter grayscale intensities corresponding to higher thickness values.

The two-dimensional thickness map of FIG. 18 can exhibit a substantially concentric pattern centered near an origin of the lateral X-Y plane, comprising a series of alternating bright and dark rings that radiate outward from a central region of the acoustic lens. A dark central region of lower thickness can be surrounded by a bright annular region of higher thickness, which in turn can be encircled by additional alternating dark and bright concentric bands extending toward a periphery of a lens aperture. Spacing between successive rings of the concentric pattern can decrease progressively with increasing radial distance from a central axis of the acoustic lens, such that the two-dimensional thickness map exhibits a Fresnel-like topology characteristic of a thickness distribution that focuses acoustic waves through the heterogeneous propagation medium.

The converged thickness distribution illustrated in FIG. 18 can be output by the HASA-ADAM framework upon satisfaction of the convergence criterion and can be used as a basis for fabricating the acoustic lens. In some aspects, the converged thickness distribution can be transmitted to a three-dimensional printer to fabricate the acoustic lens from a polymer material having the thickness distribution illustrated by the two-dimensional thickness map. In some aspects, the acoustic lens can be fabricated by three-dimensional printing of a clear white v4 resin photopolymer, such as Formlabs Clear V4 resin, using a stereolithography three-dimensional printer, such as a Formlabs Form 3B printer.

In some aspects, the HASA-ADAM framework can be material-agnostic, such that the iterative optimization that produces the converged thickness distribution can be adapted to lens materials other than the clear white v4 resin photopolymer. For a selected lens material, a speed of sound of the selected lens material can be supplied to the heterogeneous angular spectrum approach in place of a speed of sound of the clear white v4 resin photopolymer, such that the wavenumber kₕ in the lens material used during forward propagation through the acoustic lens corresponds to acoustic properties of the selected lens material. The iterative optimization can then produce a converged thickness distribution adapted to the selected lens material, and the acoustic lens can be fabricated from the selected lens material based on the converged thickness distribution. In some aspects, the selected lens material can include a photopolymer other than the clear white v4 resin photopolymer, a thermoplastic, an elastomer, a ceramic, or a metal, provided that a speed of sound of the selected lens material is supplied to the heterogeneous angular spectrum approach during the iterative optimization.

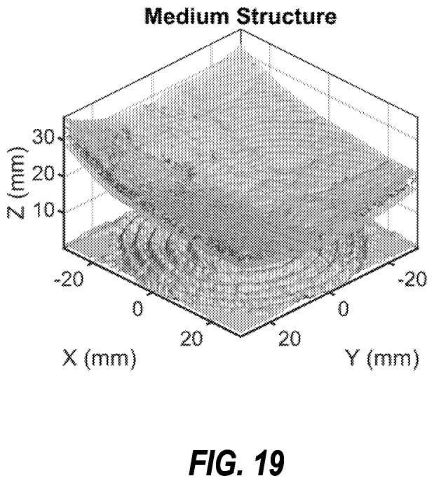

FIG. 19 illustrates a three-dimensional rendering of a medium structure reconstructed from acoustic field data, according to examples of the disclosed technology. The three-dimensional rendering of FIG. 19 can correspond to a volumetric representation of the heterogeneous propagation medium used by the heterogeneous angular spectrum approach during iterative optimization of the thickness distribution of the acoustic lens, and can be displayed in a Cartesian coordinate system having a lateral X axis, a lateral Y axis, and an axial Z axis.

In some aspects, the lateral X axis and the lateral Y axis of the three-dimensional rendering illustrated in FIG. 19 can each span a range from approximately −20 mm to approximately +20 mm, and the axial Z axis can span a range from approximately 0 mm to approximately 30 mm. The three-dimensional rendering can include an upper curved surface positioned in an elevated region of the axial Z axis and a lower curved surface positioned beneath the upper curved surface near a base of the axial Z axis, with a gap separating the upper curved surface from the lower curved surface along the axial Z axis. The upper curved surface and the lower curved surface can represent heterogeneous regions of the heterogeneous propagation medium, such as opposing portions of a skull through which acoustic waves propagate from a source plane to a target plane.

In some aspects, the upper curved surface can exhibit a concave profile that dips toward a central region of the lateral X-Y plane and rises toward peripheral edges of the lateral X-Y plane, and the lower curved surface can exhibit a curved geometry with layered or striated patterns extending across the lower curved surface. The upper curved surface and the lower curved surface can each exhibit textured, granular characteristics indicative of spatially varying acoustic properties throughout a volumetric region defined between the upper curved surface and the lower curved surface. The textured, granular characteristics can correspond to voxel-wise variations in the spatially varying speed of sound distribution and the spatially varying density distribution of the three-dimensional acoustic property map derived from micro-CT data of the heterogeneous propagation medium.

In some aspects, the three-dimensional rendering of FIG. 19 can represent a patient-specific anatomy of a skull reconstructed from micro-CT data or from MRI scan data, with the upper curved surface and the lower curved surface corresponding to outer and inner cortical layers of the skull and the volumetric region between the upper curved surface and the lower curved surface corresponding to a propagation domain that contains the acoustic lens, the skull, and the target plane. The voxel-wise speed of sound and density values assigned to the volumetric region by a porosity-dependent mixture model can populate the spatially varying speed of sound distribution and the spatially varying density distribution used by the heterogeneous angular spectrum approach during the iterative optimization.

In some aspects, the topology optimization path described above with reference to FIG. 5 can operate on the three-dimensional rendering of FIG. 19 by treating the volumetric region between the upper curved surface and the lower curved surface as the heterogeneous propagation medium through which the acoustic pressure field is forward-propagated from the source plane to the target plane at each iteration. The heterogeneous angular spectrum approach can march the acoustic pressure field along the axial Z axis through the volumetric region using an axial marching step size, such as an axial marching step size of approximately 150 μm or approximately 250 μm, with the spatially varying speed of sound distribution and the spatially varying density distribution sampled at each axial propagation step to account for local acoustic property variations across the upper curved surface, the lower curved surface, and intervening porous regions.

In some aspects, the volumetric optimization performed by the topology optimization path can produce a converged thickness distribution of the acoustic lens that is tailored to the patient-specific anatomy represented by the three-dimensional rendering of FIG. 19. Because the heterogeneous angular spectrum approach can ingest the three-dimensional acoustic property map as a direct input and can compute the gradient of the loss with respect to the unconstrained optimization variable through the volumetric propagation domain by automatic differentiation, the converged thickness distribution can be adapted to focal targets within tissue distal to the patient-specific anatomy without modifying the iterative optimization 340. In some aspects, the converged thickness distribution produced for the patient-specific anatomy can be transmitted to a three-dimensional printer to fabricate the acoustic lens from a polymer material, such that the acoustic lens is configured to focus acoustic waves through the heterogeneous propagation medium illustrated in FIG. 19 to the target plane.

In some aspects, the three-dimensional rendering of FIG. 19 can be reconstructed from acoustic field data acquired by raster scanning a hydrophone across a plurality of axial and lateral planes within a water tank, as described above with reference to the experimental systems of FIG. 1 and FIG. 2. The acoustic field data acquired by the hydrophone raster scan can be used to validate the spatially varying speed of sound distribution and the spatially varying density distribution derived from the micro-CT data of the heterogeneous propagation medium, such that the three-dimensional acoustic property map used by the heterogeneous angular spectrum approach during the iterative optimization corresponds to a heterogeneous propagation medium reconstructed from both volumetric imaging data and acoustic field measurements.

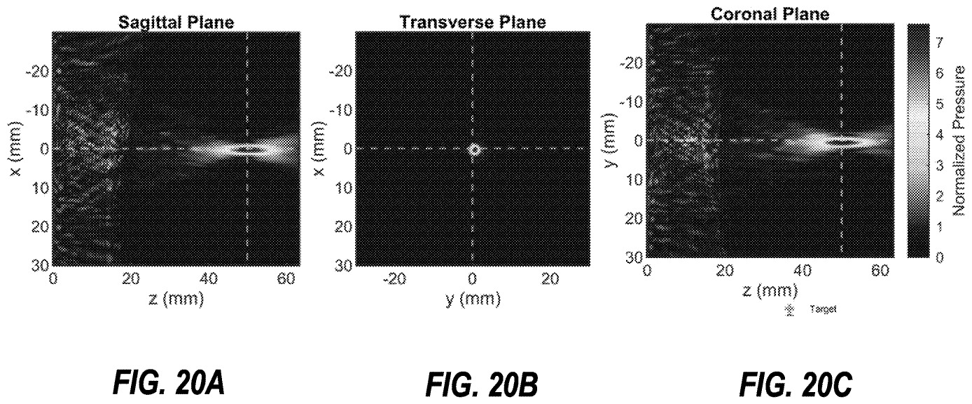

FIGS. 20A-20C illustrate simulated acoustic pressure field distributions for a focused ultrasound beam shown across three orthogonal planes, according to examples of the disclosed technology. FIG. 20A illustrates a simulated acoustic pressure field distribution in a sagittal plane, FIG. 20B illustrates a simulated acoustic pressure field distribution in a transverse plane, and FIG. 20C illustrates a simulated acoustic pressure field distribution in a coronal plane. The simulated acoustic pressure field distributions illustrated in FIGS. 20A-20C can correspond to an elongated focal beam produced by an acoustic lens having a converged thickness distribution output by the topology optimization path described above with reference to FIG. 5, with the converged thickness distribution adapted for transcranial focusing through the heterogeneous propagation medium illustrated in FIG. 19.

In some aspects, each of FIGS. 20A-20C can be displayed as a grayscale intensity map accompanied by a normalized pressure scale ranging from approximately 0 to approximately 7, with brighter regions of the grayscale intensity map corresponding to higher normalized pressure values and darker regions corresponding to lower normalized pressure values.

The sagittal plane illustrated in FIG. 20A can present the simulated acoustic pressure field distribution in an x-z coordinate system, with an axial Z axis extending from approximately 0 mm to approximately 60 mm and a lateral X axis spanning from approximately −20 mm to approximately +30 mm. A concentrated focal region can appear at approximately Z=50 mm, indicated by a bright high-intensity zone, with dashed crosshair lines marking a focal location. A diffuse scattering pattern can be visible in a near-field region between approximately Z=0 mm and approximately Z=20 mm, representing an acoustic interaction between the acoustic pressure field and a skull layer of the heterogeneous propagation medium positioned along the acoustic propagation path.

The transverse plane illustrated in FIG. 20B can present the simulated acoustic pressure field distribution in an x-y coordinate system, with a lateral X axis and a lateral Y axis each spanning from approximately −20 mm to approximately +30 mm. A tightly confined circular focal spot can be centered at an origin of the lateral X-Y plane, with dashed crosshair lines intersecting at the focal spot, illustrating lateral confinement of the simulated acoustic pressure field at the target plane.

The coronal plane illustrated in FIG. 20C can present the simulated acoustic pressure field distribution in a y-z coordinate system, with an axial Z axis extending from approximately 0 mm to approximately 60 mm and a lateral Y axis spanning from approximately −20 mm to approximately +30 mm. A focal region can be visible at approximately Z=50 mm, with a target marker positioned along the axial Z axis indicating an intended focal location and with dashed crosshair lines indicating focal coordinates. A diffuse scattering pattern can appear in a near-field region between approximately Z=0 mm and approximately Z=20 mm, corresponding to acoustic interaction with the skull layer along the acoustic propagation path.

Together, the sagittal plane of FIG. 20A, the transverse plane of FIG. 20B, and the coronal plane of FIG. 20C can illustrate an elongated focal volume that exhibits tight lateral confinement within the lateral X-Y plane and an extended depth of field along the axial Z axis. The elongated focal volume can be tailored to a deep-brain anatomical structure that is elongated along the acoustic propagation path, such as a hypothalamus, a dentate-rubro-thalamic tract, or an anterior limb of an internal capsule, which can span an axial extent of approximately 10 mm to approximately 20 mm.

In some aspects, the elongated focal volume illustrated in FIGS. 20A-20C can be produced by a volumetric optimization mode of the HASA-ADAM framework. The volumetric optimization mode can extend the topology optimization path described above with reference to FIG. 5 from a single target plane to a three-dimensional region of interest, such that the iterative optimization 340 minimizes a volumetric loss defined over the three-dimensional region of interest rather than a planar loss defined at a single target plane.

In some aspects, the volumetric optimization mode can compute forward propagation of the acoustic pressure field through an entirety of the three-dimensional region of interest at each iteration of the iterative optimization 340. The volumetric optimization mode can implement a recurrent computational graph that records a complex pressure field history at a plurality of axial slices within the three-dimensional region of interest, such that an acoustic pressure field Uₖ at each axial slice zₖ within the three-dimensional region of interest is retained during the forward propagation. In some aspects, the recurrent computational graph can be implemented using a tensor array data structure provided by the machine learning framework, such as a tf.TensorArray data structure provided by TensorFlow, that records the complex pressure field history during the forward propagation and enables the gradient of the volumetric loss with respect to the unconstrained optimization variable to be computed by automatic differentiation through the plurality of axial slices.

In some aspects, the volumetric loss can be computed as a difference between a simulated three-dimensional pressure distribution recorded across the plurality of axial slices and a target three-dimensional pressure distribution defined across the three-dimensional region of interest. The target three-dimensional pressure distribution can be selected to encode an arbitrary three-dimensional pressure distribution to be synthesized at the three-dimensional region of interest, such that the volumetric optimization mode can synthesize arbitrary three-dimensional pressure distributions matched to anatomical constraints of the heterogeneous propagation medium.

In some aspects, the target three-dimensional pressure distribution can be defined as an anisotropic three-dimensional Gaussian distribution having a lateral standard deviation smaller than an axial standard deviation, such that the volumetric optimization mode produces an elongated cigar-shaped focal volume corresponding to the simulated acoustic pressure field distributions illustrated in FIGS. 20A-20C. The anisotropic three-dimensional Gaussian distribution can be tailored to elongated anatomical structures within tissue distal to the skull layer of the heterogeneous propagation medium, such as the hypothalamus, the dentate-rubro-thalamic tract, or the anterior limb of the internal capsule, such that the elongated cigar-shaped focal volume can sonicate the elongated anatomical structure in a single exposure without mechanical raster scanning of a focal spot across the elongated anatomical structure.

In some aspects, the volumetric optimization mode can constrain energy deposition along an entirety of an acoustic propagation path through the three-dimensional region of interest, such that pre-focal and post-focal energy accumulation outside the target three-dimensional pressure distribution can be suppressed during the iterative optimization 340. By computing the volumetric loss across the plurality of axial slices, the volumetric optimization mode can refine the thickness distribution of the acoustic lens to produce the elongated focal volume illustrated in FIGS. 20A-20C while reducing energy spreading outside a designated ellipsoidal volume corresponding to the anisotropic three-dimensional Gaussian distribution.

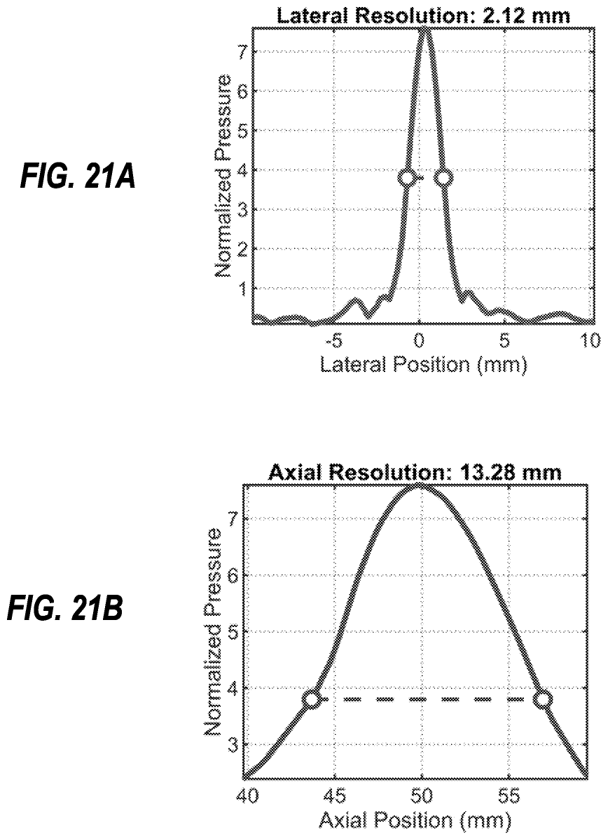

FIGS. 21A-21B illustrate lateral and axial resolution characteristics of a focal acoustic pressure field generated by an acoustic lens having a converged thickness distribution output by the topology optimization path described above with reference to FIG. 5. The lateral and axial resolution characteristics illustrated in FIGS. 21A-21B can correspond to the elongated focal volume described above with reference to FIGS. 20A-20C, such that the focal aspect ratio between the lateral resolution and the axial resolution characterizes an anisotropic cigar-shaped focus produced by the acoustic lens.

FIG. 21A illustrates a lateral resolution profile of the focal acoustic pressure field. The lateral resolution profile can be displayed as a plot of normalized pressure as a function of lateral position in millimeters. In some aspects, the lateral position can range from approximately −10 mm to approximately +10 mm, and the lateral resolution profile can exhibit a sharply peaked curve centered approximately at a lateral position of approximately 0 mm. In some aspects, a peak normalized pressure of the lateral resolution profile can reach approximately 7.5. Half-maximum markers can be positioned on opposite sides of the peak at a half-maximum pressure level to indicate a FWHM of the lateral resolution profile, and a lateral resolution determined from a spacing between the half-maximum markers can be approximately 2.12 mm. In some aspects, the lateral resolution profile can exhibit low-amplitude sidelobes extending laterally from the peak across the lateral position range.

FIG. 21B illustrates an axial resolution profile of the focal acoustic pressure field. The axial resolution profile can be displayed as a plot of normalized pressure as a function of axial position in millimeters. In some aspects, the axial position can range across a region surrounding a focal depth of approximately 50 mm, and the axial resolution profile can exhibit a broader peaked curve centered at an axial position of approximately 50 mm. In some aspects, a peak normalized pressure of the axial resolution profile can reach approximately 7.5. Half-maximum markers connected by a dashed horizontal line can be positioned on opposite sides of the peak at a half-maximum pressure level to indicate a FWHM of the axial resolution profile, and an axial resolution determined from a spacing between the half-maximum markers can be approximately 13.28 mm. In some aspects, the half-maximum markers can be positioned at approximately 43 mm and approximately 57 mm along the axial position.

A focal aspect ratio defined as a ratio between the axial resolution and the lateral resolution can characterize an anisotropy of the focal acoustic pressure field produced by the acoustic lens. In some aspects, the lateral resolution of approximately 2.12 mm and the axial resolution of approximately 13.28 mm can correspond to a focal aspect ratio of approximately 6.3 between the axial resolution and the lateral resolution, indicating an elongated cigar-shaped focus that exhibits tight lateral confinement combined with an extended axial depth of field. In some aspects, the elongated cigar-shaped focus characterized by FIGS. 21A-21B can be tailored to targeting elongated anatomical structures distal to the heterogeneous propagation medium, such as a hypothalamus, a dentate-rubro-thalamic tract, or an anterior limb of an internal capsule, that span an axial extent comparable to the axial resolution of the focal acoustic pressure field.

In some aspects, the lateral resolution profile of FIG. 21A and the axial resolution profile of FIG. 21B can be extracted from the simulated acoustic pressure field distributions illustrated in FIGS. 20A-20C by sampling the normalized pressure along a lateral line passing through a focal peak at the target plane and along an axial line passing through the focal peak along an acoustic propagation direction. The lateral resolution and the axial resolution determined from the FWHM of the lateral resolution profile and the axial resolution profile can quantify focal confinement of the acoustic lens designed for the elongated focal volume.

In some aspects, the volumetric optimization mode of the HASA-ADAM framework described above with reference to FIGS. 20A-20C can be configured to produce a target focal aspect ratio between the axial resolution and the lateral resolution by selecting a ratio between an axial standard deviation and a lateral standard deviation of an anisotropic three-dimensional Gaussian distribution used as the target three-dimensional pressure distribution. By increasing the ratio between the axial standard deviation and the lateral standard deviation of the anisotropic three-dimensional Gaussian distribution, the volumetric optimization mode can produce a converged thickness distribution that yields a focal acoustic pressure field having a larger focal aspect ratio between the axial resolution and the lateral resolution, and by decreasing the ratio between the axial standard deviation and the lateral standard deviation, the volumetric optimization mode can produce a converged thickness distribution that yields a focal acoustic pressure field having a smaller focal aspect ratio between the axial resolution and the lateral resolution.

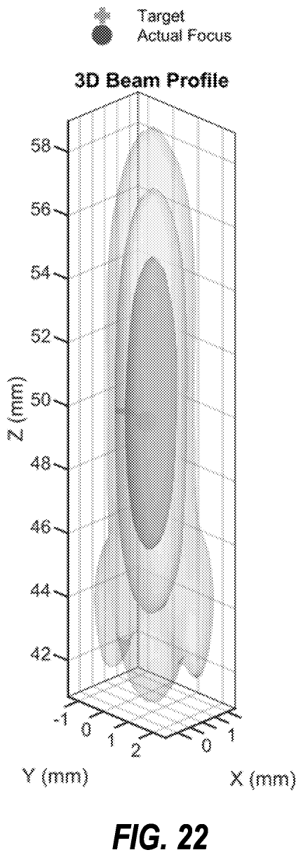

FIG. 22 illustrates a three-dimensional beam profile of an acoustic focal field generated through an optimized acoustic lens having a converged thickness distribution output by the topology optimization path described above with reference to FIG. 5. The three-dimensional beam profile illustrated in FIG. 22 can correspond to the elongated focal volume described above with reference to FIGS. 20A-20C and to the lateral and axial resolution characteristics described above with reference to FIGS. 21A-21B, such that the three-dimensional beam profile visualizes a volumetric morphology of an acoustic focal field that exhibits tight lateral confinement and an extended axial depth of field.

In some aspects, the three-dimensional beam profile of FIG. 22 can be rendered within a rectangular volumetric grid defined by a lateral X axis, a lateral Y axis, and an axial Z axis. The lateral X axis can span a range from approximately −1 mm to approximately +1 mm, the lateral Y axis can span a range from approximately −1 mm to approximately +2 mm, and the axial Z axis can span a range from approximately 42 mm to approximately 58 mm, with the axial Z axis corresponding to an acoustic propagation direction.

The three-dimensional beam profile of FIG. 22 can include a cross-shaped marker representing an intended target position at the target plane and a filled circular marker representing an actual focus achieved by the acoustic focal field generated through the optimized acoustic lens. In some aspects, the cross-shaped marker representing the intended target position and the filled circular marker representing the actual focus can be positioned in close proximity to one another near an axial coordinate of approximately 50 mm along the axial Z axis and near an origin of the lateral X axis and the lateral Y axis. A spatial separation between the cross-shaped marker and the filled circular marker can characterize a targeting error of the optimized acoustic lens, and proximity of the filled circular marker to the cross-shaped marker can indicate substantial alignment between the intended target position and the actual focus realized through the heterogeneous propagation medium.

In some aspects, the three-dimensional beam profile of FIG. 22 can further include a plurality of nested isosurfaces surrounding the cross-shaped marker and the filled circular marker, with each nested isosurface representing a contour of constant acoustic intensity. An innermost isosurface can represent a higher acoustic intensity contour level and can be rendered as an ellipsoidal region surrounding the actual focus. An intermediate isosurface can represent a lower acoustic intensity contour level and can surround the innermost isosurface. An outermost isosurface can represent a still lower acoustic intensity contour level and can surround the intermediate isosurface. In some aspects, the nested isosurfaces can be rendered as semi-transparent ellipsoidal shells such that the innermost isosurface, the intermediate isosurface, and the outermost isosurface can be visualized together within the rectangular volumetric grid.

In some aspects, the nested isosurfaces of FIG. 22 can be elongated along the axial Z axis relative to the lateral X axis and the lateral Y axis, producing a cigar-shaped or elongated ellipsoidal beam morphology that exhibits a narrow lateral extent and an extended axial depth of field. The cigar-shaped beam morphology illustrated by FIG. 22 can correspond to the focal aspect ratio between the axial resolution and the lateral resolution described above with reference to FIGS. 21A-21B.

In some aspects, the three-dimensional beam profile of FIG. 22 can further include one or more secondary lobes positioned outside a principal focal volume defined by the nested isosurfaces. For example, secondary lobes of reduced acoustic intensity can extend axially below the principal focal volume in a region between approximately 42 mm and approximately 46 mm along the axial Z axis, corresponding to pre-focal side lobes flanking the principal focal volume. The pre-focal side lobes can represent residual energy deposited along the acoustic propagation path through the heterogeneous propagation medium prior to convergence of the acoustic focal field at the actual focus.

In some aspects, the cigar-shaped focal volume illustrated by FIG. 22 can be produced by the volumetric optimization mode of the HASA-ADAM framework described above with reference to FIGS. 20A-20C, in which a target three-dimensional pressure distribution is defined as an anisotropic three-dimensional Gaussian distribution having a lateral standard deviation smaller than an axial standard deviation. The anisotropic three-dimensional Gaussian distribution can serve as the target three-dimensional pressure distribution against which the simulated three-dimensional pressure distribution recorded across the plurality of axial slices is compared during the iterative optimization 340, such that the converged thickness distribution output by the volumetric optimization mode yields the cigar-shaped focal volume visualized by the nested isosurfaces of FIG. 22.

In some aspects, the lateral standard deviation and the axial standard deviation of the anisotropic three-dimensional Gaussian distribution can be selected based on dimensions of an elongated anatomical structure within tissue distal to the heterogeneous propagation medium, such as a hypothalamus, a dentate-rubro-thalamic tract, or an anterior limb of an internal capsule. By matching the lateral standard deviation and the axial standard deviation of the anisotropic three-dimensional Gaussian distribution to the dimensions of the elongated anatomical structure, the volumetric optimization mode can produce a converged thickness distribution of the acoustic lens that synthesizes a cigar-shaped focal volume conformed to the elongated anatomical structure, such that the elongated anatomical structure can be sonicated in a single exposure without mechanical raster scanning of a focal spot across the elongated anatomical structure.

In some aspects, the three-dimensional beam profile of FIG. 22 can be evaluated to assess targeting accuracy and focal morphology of the optimized acoustic lens prior to fabrication by three-dimensional printing of a polymer based on the converged thickness distribution. A targeting error metric can be computed as a spatial separation between the cross-shaped marker representing the intended target position and the filled circular marker representing the actual focus, and a focal morphology metric can be computed from extents of the nested isosurfaces along the lateral X axis, the lateral Y axis, and the axial Z axis. Together, the targeting error metric and the focal morphology metric can quantify performance of the converged thickness distribution in producing a cigar-shaped focal volume aligned with the intended target position through the heterogeneous propagation medium.

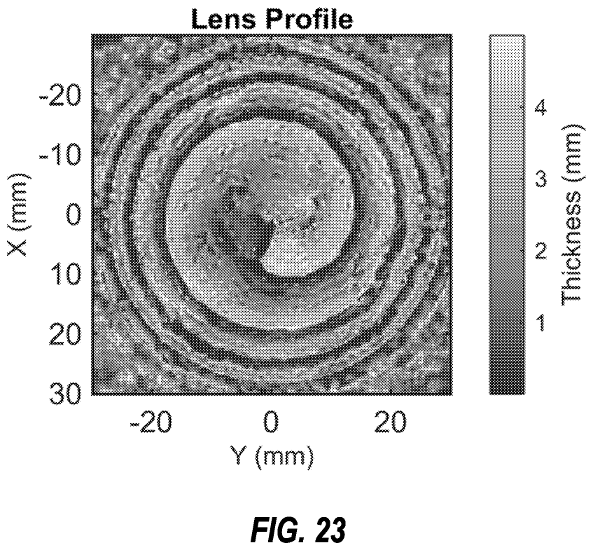

FIG. 23 illustrates a grayscale thickness map of a lens profile generated by the acoustic lens topology optimization framework, according to examples of the disclosed technology. The grayscale thickness map illustrated in FIG. 23 can correspond to a converged thickness distribution output by the topology optimization path described above with reference to FIG. 5 when the iterative optimization 340 is configured to synthesize an acoustic vortex beam through the heterogeneous propagation medium.

FIG. 23 illustrates a grayscale thickness map of a lens profile generated by the topology optimization path, according to examples of the disclosed technology. The grayscale thickness map illustrated in FIG. 23 can correspond to a converged thickness distribution output by the topology optimization path described above with reference to FIG. 5 when the iterative optimization 340 is configured to synthesize an acoustic vortex beam through the heterogeneous propagation medium.

In some aspects, the grayscale thickness map of FIG. 23 can exhibit a series of concentric ring-like features radiating outward from a central region of the acoustic lens, with alternating bands of higher and lower thickness values forming a Fresnel-like topology. A central region of the grayscale thickness map can display variations in thickness, and the concentric bands can extend outward toward a peripheral region of the acoustic lens. The Fresnel-like topology of the grayscale thickness map can produce a toroidal acoustic intensity distribution at the target plane when acoustic waves emitted by a transducer propagate through the acoustic lens defined by the converged thickness distribution and through the heterogeneous propagation medium.

In some aspects, the toroidal acoustic intensity distribution produced by the acoustic lens defined by the grayscale thickness map of FIG. 23 can correspond to an acoustic vortex beam having a topological charge l=1. The acoustic vortex beam can exhibit an azimuthal phase variation of 2πl around an axis of acoustic propagation, such that the acoustic vortex beam carries an orbital angular momentum and exhibits a central null along the axis of acoustic propagation. The central null can correspond to a region of suppressed acoustic intensity at a center of the toroidal acoustic intensity distribution at the target plane.

In some aspects, the converged thickness distribution output by the topology optimization path to synthesize the acoustic vortex beam can be produced by the volumetric optimization mode of the HASA-ADAM framework described above with reference to FIGS. 20A-20C, with a target three-dimensional pressure distribution defined to encode the toroidal acoustic intensity distribution corresponding to the acoustic vortex beam having the topological charge l=1. The volumetric optimization mode can refine the thickness distribution of the acoustic lens by minimizing a volumetric loss between a simulated three-dimensional pressure distribution recorded across a plurality of axial slices and the target three-dimensional pressure distribution encoding the toroidal acoustic intensity distribution.

In some aspects, the iterative optimization 340 used to produce the converged thickness distribution illustrated in FIG. 23 can be initialized with a Spiral Fresnel warm start that defines an initial thickness distribution exhibiting an azimuthal phase ramp consistent with the topological charge l=1. The Spiral Fresnel warm start can include an azimuthal phase variation that wraps by 2π around the axis of acoustic propagation combined with radial Fresnel zone features, such that the initial thickness distribution provides a starting point that preserves a central null along the axis of acoustic propagation during early iterations of the iterative optimization 340. The Spiral Fresnel warm start can be supplied as an initial value of the unconstrained optimization variable at the step 330, and the iterative optimization 340 can then refine the unconstrained optimization variable to compensate for skull-induced aberrations and volumetric wave propagation effects while preserving the central null of the acoustic vortex beam.

In some aspects, the central null of the acoustic vortex beam produced by the converged thickness distribution illustrated in FIG. 23 can be used for structure-sparing operations during transcranial focused ultrasound. For example, the central null can be aligned with a structure to be spared from acoustic energy deposition, such as a calcified pineal gland, a major blood vessel, or a ventricular system, while the toroidal acoustic intensity distribution surrounding the central null deposits acoustic energy into tissue surrounding the structure to be spared. By aligning the central null with the structure to be spared, the acoustic vortex beam can sonicate a toroidal region of tissue around the structure to be spared without depositing acoustic energy at a location of the structure to be spared.

In some aspects, a radius of the central null and a radius of the toroidal acoustic intensity distribution at the target plane can be selected based on dimensions of the structure to be spared and on dimensions of a treatment region surrounding the structure to be spared. The radius of the central null can be selected to encompass the structure to be spared, such that the structure to be spared lies within the central null where acoustic intensity is suppressed, and the radius of the toroidal acoustic intensity distribution can be selected to overlap the treatment region surrounding the structure to be spared. The radius of the central null and the radius of the toroidal acoustic intensity distribution can be encoded in the target three-dimensional pressure distribution supplied to the volumetric optimization mode, and the converged thickness distribution illustrated in FIG. 23 can be tailored to the selected dimensions through the iterative optimization 340.

In some aspects, the converged thickness distribution illustrated in FIG. 23 can be transmitted to a three-dimensional printer to fabricate the acoustic lens from a polymer material having the grayscale thickness map illustrated in FIG. 23. The acoustic lens fabricated from the converged thickness distribution can be coupled to a transducer to produce the acoustic vortex beam through the heterogeneous propagation medium when the transducer is driven by an excitation signal at an operating frequency for which the iterative optimization 340 was performed.

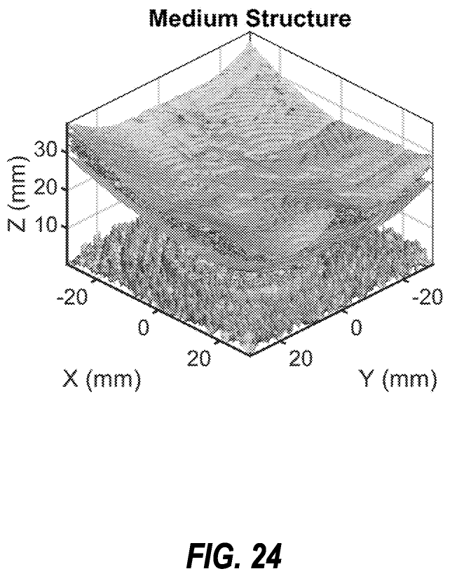

FIG. 24 illustrates a three-dimensional surface visualization of a medium structure used in acoustic wave propagation modeling for the acoustic vortex example described above with reference to FIG. 23, according to examples of the disclosed technology. The three-dimensional surface visualization of FIG. 24 can correspond to a volumetric representation of the heterogeneous propagation medium used by the heterogeneous angular spectrum approach when the iterative optimization 340 is configured to synthesize an acoustic vortex beam through the heterogeneous propagation medium.

In some aspects, the three-dimensional surface visualization of FIG. 24 can be rendered in a Cartesian coordinate system having a lateral X axis, a lateral Y axis, and an axial Z axis. The lateral X axis and the lateral Y axis can each span a range from approximately −20 mm to approximately +20 mm, and the axial Z axis can span a range from approximately 0 mm to approximately 30 mm or greater. The three-dimensional surface visualization can include a lower textured surface positioned near a base of the axial Z axis and an upper curved surface positioned at an elevated range of the axial Z axis, with a gap region separating the lower textured surface from the upper curved surface along the axial Z axis. The lower textured surface and the upper curved surface can represent heterogeneous acoustic regions of the medium structure through which acoustic waves propagate from a source plane to a target plane.

In some aspects, the lower textured surface can be positioned at axial Z coordinates ranging from approximately 0 mm to approximately 10 mm and can exhibit a rough, granular topography across the lateral X-Y plane. The upper curved surface can be positioned at axial Z coordinates ranging from approximately 10 mm to greater than approximately 30 mm and can exhibit a saddle-like geometry with visible striations and contour patterns across an extent of the upper curved surface. The saddle-like geometry can include elevation variations across the lateral X-Y plane, with higher regions appearing toward one corner of the upper curved surface and lower regions appearing toward an opposing corner. The lower textured surface can remain substantially planar in an overall extent of the lower textured surface while exhibiting localized roughness consistent with porous trabecular regions of cranial bone.

In some aspects, voxel-wise speed of sound and density values across the lower textured surface, the upper curved surface, and an intervening propagation region between the lower textured surface and the upper curved surface can be assigned by a porosity-dependent mixture model applied to micro-CT data of a skull, as described above with reference to FIG. 13. The voxel-wise speed of sound and density values can populate the spatially varying speed of sound distribution and the spatially varying density distribution of the three-dimensional acoustic property map ingested by the heterogeneous angular spectrum approach during the iterative optimization 340 that synthesizes the acoustic vortex beam.

In some aspects, the saddle-like geometry of the upper curved surface can introduce asymmetric phase aberrations and refractive steering effects on an acoustic pressure field propagating through the medium structure of FIG. 24 toward the target plane. The asymmetric phase aberrations can perturb an azimuthal phase variation of the acoustic vortex beam around the axis of acoustic propagation and can disrupt a central null of the acoustic vortex beam at the target plane when an acoustic lens is designed without accounting for the spatially varying acoustic properties of the medium structure.

In some aspects, the topology optimization path described above with reference to FIG. 5 can operate on the three-dimensional surface visualization of FIG. 24 by treating the propagation region between the lower textured surface and the upper curved surface as the heterogeneous propagation medium through which the acoustic pressure field is forward-propagated from the source plane to the target plane at each iteration of the iterative optimization 340. The heterogeneous angular spectrum approach can march the acoustic pressure field along the axial Z axis through the propagation region using an axial marching step size, such as an axial marching step size of approximately 150 μm or approximately 250 μm, with the spatially varying speed of sound distribution and the spatially varying density distribution sampled at each axial propagation step to account for local acoustic property variations across the lower textured surface, the upper curved surface, and the intervening propagation region.

In some aspects, the iterative optimization 340 can fine-tune the thickness distribution of the acoustic lens to pre-compensate for the asymmetric phase aberrations and the refractive steering effects introduced by the saddle-like geometry of the upper curved surface, such that the converged thickness distribution illustrated in FIG. 23 produces the acoustic vortex beam with the central null preserved along the axis of acoustic propagation through the medium structure of FIG. 24. By computing the gradient of the volumetric loss with respect to the unconstrained optimization variable through the propagation region by automatic differentiation, the iterative optimization 340 can refine localized features of the thickness distribution to counter the asymmetric phase aberrations imparted by the saddle-like geometry while maintaining the toroidal acoustic intensity distribution surrounding the central null at the target plane.

In some aspects, fine-tuning of the thickness distribution by the iterative optimization 340 can include adjusting localized thickness values across azimuthal sectors of the acoustic lens to counter sector-dependent phase delays imparted by the upper curved surface, and can include adjusting localized thickness values across radial zones of the acoustic lens to counter radial speed-of-sound variations across the lower textured surface and the upper curved surface. The localized adjustments of the thickness distribution can deviate from a Spiral Fresnel warm start supplied to the iterative optimization 340, such that the converged thickness distribution illustrated in FIG. 23 retains an azimuthal phase ramp consistent with a topological charge l=1 while incorporating skull-specific corrections derived from the three-dimensional acoustic property map of the medium structure illustrated in FIG. 24.

In some aspects, the three-dimensional surface visualization of FIG. 24 can represent a patient-specific anatomy of a skull derived from micro-CT data or from MRI scan data, such that the iterative optimization 340 can produce a patient-specific converged thickness distribution of the acoustic lens adapted to focus the acoustic vortex beam through the patient-specific anatomy. The patient-specific converged thickness distribution can be transmitted to a three-dimensional printer to fabricate the acoustic lens from a polymer material, such that the acoustic lens fabricated from the patient-specific converged thickness distribution can synthesize the acoustic vortex beam through the medium structure illustrated in FIG. 24 with the central null aligned along the axis of acoustic propagation to a structure to be spared distal to the upper curved surface.

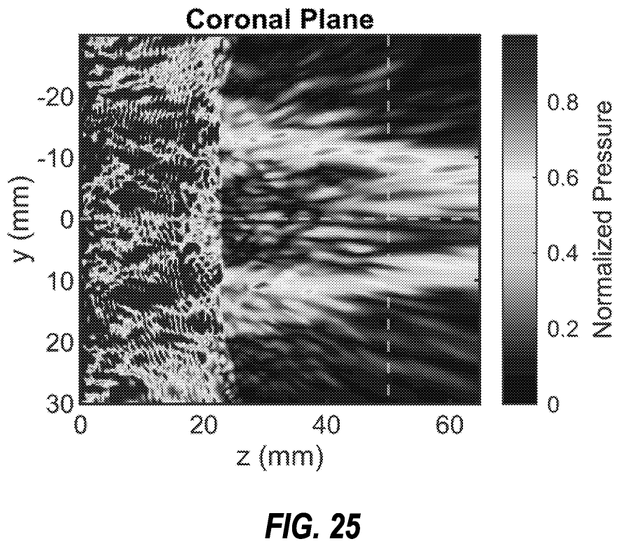

FIG. 25 illustrates a normalized pressure field in a coronal plane resulting from acoustic wave propagation, according to examples of the disclosed technology. The normalized pressure field illustrated in FIG. 25 can correspond to a simulated acoustic pressure field produced by an acoustic lens having a converged thickness distribution output by the topology optimization path described above with reference to FIG. 5, in which the iterative optimization 340 is configured to synthesize an acoustic vortex beam through the heterogeneous propagation medium illustrated in FIG. 24.

In some aspects, the coronal plane illustrated in FIG. 25 can present the normalized pressure field in a y-z coordinate system, with an axial z coordinate extending from approximately 0 mm to approximately 65 mm along an acoustic propagation direction and a lateral y coordinate spanning from approximately −20 mm to approximately +30 mm. The normalized pressure field can be displayed as a grayscale image accompanied by a normalized pressure scale ranging from approximately 0 to approximately 0.8, with darker regions of the grayscale image corresponding to lower normalized pressure values and lighter regions corresponding to higher normalized pressure values.

In some aspects, the normalized pressure field of FIG. 25 can include a near-field region extending from approximately z=0 mm to approximately z=25 mm along the axial z coordinate, in which a region of high spatial-frequency interference patterns can appear across a lateral extent of the coronal plane. The high spatial-frequency interference patterns can comprise densely packed alternating bright and dark fringes that span the lateral extent of the near-field region. The high spatial-frequency interference patterns can arise from acoustic interaction between the acoustic pressure field and the heterogeneous propagation medium positioned along the acoustic propagation path, including interaction with porous trabecular regions and denser cortical layers of a skull through which the acoustic pressure field propagates.

In some aspects, beyond the near-field region, the normalized pressure field can transition into a diverging beam pattern that propagates outward from approximately z=25 mm toward approximately z=65 mm along the axial z coordinate. The diverging beam pattern can include elongated streak-like features that radiate from a central region near a lateral y coordinate of approximately 0 mm and extend laterally and axially toward a far-field boundary of the coronal plane. The diverging beam pattern can exhibit a fan-shaped distribution with a plurality of radial filaments of varying intensity that extend laterally and axially from a reference focal location toward the far-field boundary, illustrating an angular spread of the acoustic vortex beam after propagation through the heterogeneous propagation medium.

In some aspects, a horizontal dashed line can be positioned at the lateral y coordinate of approximately 0 mm extending across the coronal plane along the axial z coordinate, and a vertical dashed line can be positioned at approximately z=50 mm intersecting the horizontal dashed line. Together, the horizontal dashed line and the vertical dashed line can mark the reference focal location within the diverging beam pattern, such that the reference focal location corresponds to an intended axial depth and lateral position of the acoustic vortex beam at the target plane.

In some aspects, the acoustic vortex beam illustrated in FIG. 25 can form a hollow vortex tube having a central null that extends along the axis of acoustic propagation. The central null can persist across a plurality of axial z coordinates along the axial z coordinate, such that a region of suppressed normalized pressure can extend continuously along the lateral y coordinate of approximately 0 mm through the near-field region, through the reference focal location at approximately z=50 mm, and into the diverging beam pattern beyond the reference focal location. The hollow vortex tube can be characterized by a toroidal acoustic intensity distribution surrounding the central null in transverse planes, such that the hollow vortex tube exhibits a finite radial extent in directions transverse to the acoustic propagation direction while exhibiting a region of suppressed acoustic intensity along the axis of acoustic propagation.

In some aspects, persistence of the central null along the acoustic propagation direction through the near-field region and the diverging beam pattern can indicate that the converged thickness distribution output by the iterative optimization 340 can preserve an azimuthal phase variation of the acoustic vortex beam through the heterogeneous propagation medium. The azimuthal phase variation of approximately 2π around the axis of acoustic propagation, consistent with a topological charge l=1, can produce a phase singularity along the axis of acoustic propagation that maintains the central null across the near-field region, the reference focal location, and the diverging beam pattern despite asymmetric phase aberrations and refractive steering effects introduced by the heterogeneous propagation medium.

In some aspects, the persistent central null of the hollow vortex tube illustrated in FIG. 25 can extend a range of axial z coordinates over which a structure to be spared can be aligned with the central null during transcranial focused ultrasound. By aligning the structure to be spared along the axial z coordinate within the hollow vortex tube, acoustic energy deposition into the structure to be spared can be suppressed across an axial extent of the structure to be spared, while tissue surrounding the structure to be spared can be sonicated by the toroidal acoustic intensity distribution forming a wall of the hollow vortex tube.

In some aspects, the normalized pressure field illustrated in FIG. 25 can be computed by the heterogeneous angular spectrum approach using the converged thickness distribution illustrated in FIG. 23 and the three-dimensional acoustic property map illustrated in FIG. 24. The heterogeneous angular spectrum approach can march the acoustic pressure field from the source plane along the axial z coordinate through the heterogeneous propagation medium to a far-field boundary at approximately z=65 mm, with the spatially varying speed of sound distribution and the spatially varying density distribution sampled at each axial propagation step. A coronal slice of the marched acoustic pressure field at the lateral y coordinate can be extracted to produce the normalized pressure field of FIG. 25, and the normalized pressure scale ranging from approximately 0 to approximately 0.8 can encode normalized pressure magnitudes across the coronal slice.

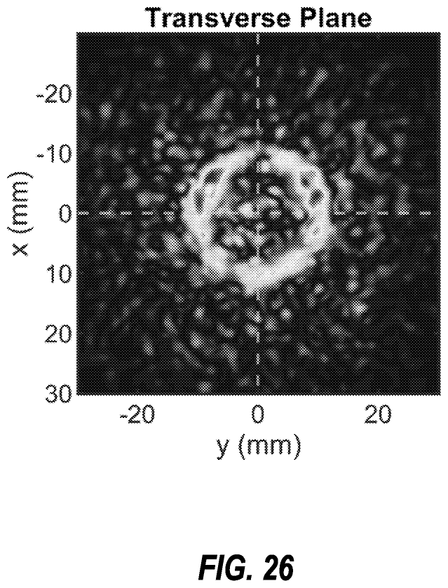

FIG. 26 illustrates a two-dimensional acoustic intensity map of a reconstructed pressure field in a transverse plane, according to examples of the disclosed technology. The two-dimensional acoustic intensity map illustrated in FIG. 26 can correspond to the simulated acoustic pressure field produced by the acoustic lens having the converged thickness distribution illustrated in FIG. 23 and propagated through the heterogeneous propagation medium illustrated in FIG. 24, sampled at the target plane in a transverse plane orthogonal to the acoustic propagation direction.

In some aspects, the two-dimensional acoustic intensity map illustrated in FIG. 26 can be displayed in an x-y coordinate system, with a lateral x coordinate spanning from approximately −30 mm to approximately +30 mm and a lateral y coordinate spanning from approximately −30 mm to approximately +30 mm. Dashed crosshair lines can extend horizontally along the lateral y coordinate at x=0 and vertically along the lateral x coordinate at y=0, intersecting at a center of the two-dimensional acoustic intensity map and marking an axis of acoustic propagation through the transverse plane.

In some aspects, the two-dimensional acoustic intensity map of FIG. 26 can exhibit a substantially ring-shaped intensity distribution centered near an origin of the transverse plane. The ring-shaped intensity distribution can correspond to a transverse cross-section of the hollow vortex tube described above with reference to FIG. 25, such that the ring-shaped intensity distribution forms a wall of the hollow vortex tube at the target plane. A central region of the ring-shaped intensity distribution at the origin of the transverse plane can correspond to a central null of the acoustic vortex beam, at which acoustic intensity can be suppressed along the axis of acoustic propagation.

In some aspects, the ring-shaped intensity distribution illustrated in FIG. 26 can exhibit non-uniform intensity along a circumference of the ring-shaped intensity distribution. A plurality of azimuthal sectors of the ring-shaped intensity distribution can exhibit higher intensity values relative to a plurality of darker azimuthal sectors interspersed within the ring-shaped intensity distribution, such that the ring-shaped intensity distribution can include alternating bright and dark regions distributed along the circumference around the central null. A diffuse background of lower-intensity speckle can surround the ring-shaped intensity distribution, with intensity decreasing toward a periphery of the transverse plane.

In some aspects, the non-uniform intensity along the circumference of the ring-shaped intensity distribution can result from elastic mode conversion at a boundary of the skull through which the acoustic pressure field propagates. Longitudinal pressure waves incident on the boundary of the skull at oblique angles can convert into shear waves within the skull, and the shear waves can attenuate within the skull or can fail to recouple into longitudinal pressure waves at an opposing boundary of the skull. The elastic mode conversion at the boundary of the skull can effectively shadow specific azimuthal sectors of the ring-shaped intensity distribution along the circumference of the ring-shaped intensity distribution, such that acoustic energy that would otherwise contribute to the shadowed azimuthal sectors can be redirected, attenuated, or scattered by the skull.

In some aspects, the azimuthal sectors that are shadowed by the elastic mode conversion at the boundary of the skull can correspond to portions of the ring-shaped intensity distribution at which the acoustic propagation path through the skull traverses regions of the skull having higher angles of incidence or higher cortical bone thickness. The angles of incidence at the boundary of the skull can vary around the circumference of the ring-shaped intensity distribution as a result of asymmetric skull geometry and curvature, such that azimuthal sectors corresponding to acoustic propagation paths at angles of incidence approaching a refractive limit of the skull material can exhibit reduced intensity values relative to azimuthal sectors corresponding to acoustic propagation paths at smaller angles of incidence.

In some aspects, the central null of the ring-shaped intensity distribution can be maintained at the origin of the transverse plane despite the non-uniform intensity along the circumference of the ring-shaped intensity distribution. The converged thickness distribution illustrated in FIG. 23, output by the topology optimization path described above with reference to FIG. 5, can preserve an azimuthal phase variation of approximately 2π around the axis of acoustic propagation through the heterogeneous propagation medium, such that a phase singularity at the axis of acoustic propagation can produce the central null at the origin of the transverse plane. The non-uniform intensity along the circumference of the ring-shaped intensity distribution can therefore coexist with a substantially preserved central null at the origin of the transverse plane.

In some aspects, the substantially preserved central null at the origin of the transverse plane illustrated in FIG. 26 can be suitable for structure-sparing interventions during transcranial focused ultrasound. By aligning a structure to be spared with the central null at the origin of the transverse plane, acoustic energy deposition into the structure to be spared can be suppressed across the transverse plane, while tissue surrounding the structure to be spared can be sonicated by the ring-shaped intensity distribution forming the wall of the hollow vortex tube. The structure to be spared can include a calcified pineal gland, a major blood vessel, a ventricular system, or another anatomical structure for which acoustic energy deposition can be suppressed during a transcranial focused ultrasound exposure.

In some aspects, the iterative optimization 340 can further refine the converged thickness distribution illustrated in FIG. 23 to redistribute acoustic energy along the circumference of the ring-shaped intensity distribution and reduce the non-uniform intensity along the circumference. For example, an elastic wave propagation model that incorporates longitudinal-to-shear mode conversion at the boundary of the skull, as described above with reference to FIG. 10, can be substituted for or combined with the heterogeneous angular spectrum approach during the iterative optimization 340, such that the converged thickness distribution accounts for the elastic mode conversion at the boundary of the skull and can pre-compensate for the shadowing of the azimuthal sectors during design of the acoustic lens. In some aspects, the target three-dimensional pressure distribution supplied to the volumetric optimization mode of the HASA-ADAM framework described above with reference to FIGS. 20A-20C can encode a target ring-shaped intensity distribution at the target plane, such that the iterative optimization 340 minimizes a volumetric loss between a simulated ring-shaped intensity distribution and the target ring-shaped intensity distribution to refine the converged thickness distribution toward a more uniform azimuthal distribution around the central null.

In some aspects, the two-dimensional acoustic intensity map illustrated in FIG. 26 can be computed by extracting a transverse slice of the simulated acoustic pressure field marched by the heterogeneous angular spectrum approach through the heterogeneous propagation medium illustrated in FIG. 24, at an axial coordinate corresponding to the target plane. The transverse slice can be squared to produce the two-dimensional acoustic intensity map, and the two-dimensional acoustic intensity map can be normalized for display across the transverse plane to facilitate visualization of the ring-shaped intensity distribution and the central null at the origin of the transverse plane.

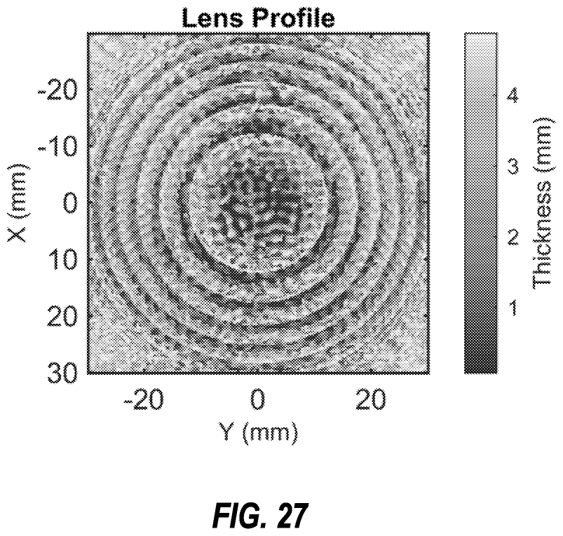

FIG. 27 illustrates a two-dimensional thickness profile of an acoustic lens, according to examples of the disclosed technology. The two-dimensional thickness profile illustrated in FIG. 27 can correspond to a converged thickness distribution output by the topology optimization path described above with reference to FIG. 5 when the iterative optimization 340 is configured to synthesize a diffraction-limited focus at a target coordinate within tissue distal to the heterogeneous propagation medium.

In some aspects, the two-dimensional thickness profile of FIG. 27 can be displayed as a grayscale heatmap of thickness values across a lateral X-Y plane of the acoustic lens. A lateral Y coordinate of the two-dimensional thickness profile can range from approximately −20 mm to approximately +20 mm, and a lateral X coordinate of the two-dimensional thickness profile can range from approximately −20 mm to approximately +30 mm. Thickness values across the two-dimensional thickness profile can range from approximately 0 mm to greater than approximately 4 mm, with darker grayscale intensities corresponding to lower thickness values and lighter grayscale intensities corresponding to higher thickness values.

In some aspects, the two-dimensional thickness profile of FIG. 27 can exhibit a series of concentric ring-like features centered approximately near an origin of the lateral X-Y plane, with alternating bands of lighter and darker shading that correspond to variations in lens thickness across a spatial domain of the acoustic lens. A central region of the two-dimensional thickness profile near the origin of the lateral X-Y plane can display a textured pattern with finer-scale variations in thickness, while surrounding rings of the concentric ring-like features can extend outward toward a periphery of a lens aperture. An outer region of the two-dimensional thickness profile, beyond the concentric ring-like features, can exhibit a lighter shade indicating greater thickness values relative to the concentric ring-like features.

In some aspects, the converged thickness distribution illustrated in FIG. 27 can be produced by the iterative optimization 340 configured with an energy maximization formulation rather than a pattern-matching formulation. Under the energy maximization formulation, the iterative optimization 340 can maximize an integral of acoustic intensity within a sub-wavelength bucket mask M(r) centered at target coordinates within a three-dimensional region of interest Ω. The sub-wavelength bucket mask M(r) can have a radius σ that is smaller than an acoustic wavelength λ in a background medium, such that σ<λ, and can be centered at the target coordinates within the three-dimensional region of interest.

In some aspects, the iterative optimization 340 configured with the energy maximization formulation can compute an energy loss L_{energy} according to the relationship

where P(r) denotes the simulated acoustic pressure field at a spatial coordinate r within the three-dimensional region of interest Ω, |P(r)|² denotes a simulated acoustic intensity at the spatial coordinate r, M(r) denotes the sub-wavelength bucket mask, and dV denotes a volume element of the three-dimensional region of interest. The negative sign in the relationship can convert an energy maximization objective into a loss minimization objective compatible with the ADAM-based optimization stage described above with reference to FIG. 4.

In some aspects, the energy loss L_{energy} can be substituted for the pattern-matching loss described above with reference to FIG. 4 and FIG. 5 at the step 365, such that the iterative optimization 340 refines the unconstrained optimization variable to concentrate acoustic energy within the sub-wavelength bucket mask M(r) rather than to match a prescribed reference intensity image at the target plane. The gradient of the energy loss with respect to the unconstrained optimization variable can be computed by automatic differentiation provided by the machine learning framework, and the ADAM optimizer can update the unconstrained optimization variable based on the gradient of the energy loss and the learning rate at the step 370.

In some aspects, the energy maximization formulation can facilitate diffraction-limited focusing of acoustic waves through the heterogeneous propagation medium without an apodization trap that can be induced by pattern-matching formulations. The apodization trap can arise under a pattern-matching formulation when the iterative optimization 340 attempts to reproduce a prescribed reference intensity image at the target plane by suppressing aperture contributions that produce sidelobes or off-target intensity, such that an effective aperture of the acoustic lens can be apodized and a resulting focal spot can be broadened relative to a diffraction limit set by an aperture geometry. By replacing the pattern-matching loss with the energy loss L_{energy} that integrates acoustic intensity within the sub-wavelength bucket mask M(r), the iterative optimization 340 can preserve aperture contributions across an entirety of the acoustic lens and can concentrate acoustic energy within the sub-wavelength bucket mask at the target coordinates, such that the converged thickness distribution illustrated in FIG. 27 can produce a focal spot approaching a diffraction limit set by the aperture geometry of the acoustic lens.

In some aspects, the radius σ of the sub-wavelength bucket mask M(r) can be selected based on the acoustic wavelength λ in the background medium at an operating frequency of the acoustic lens, such that the radius σ satisfies σ<λ. In some aspects, the sub-wavelength bucket mask M(r) can be implemented as a binary mask having a value of one within a spherical region of radius σ centered at the target coordinates and a value of zero outside the spherical region, or can be implemented as a smoothly tapered mask having a soft boundary at a characteristic radius σ.

In some aspects, the three-dimensional region of interest Ω over which the energy loss L_{energy} is integrated can correspond to a sub-volume of a propagation domain that contains the target coordinates, such that the iterative optimization 340 can constrain energy accumulation to the sub-volume during forward propagation through the acoustic lens and through the heterogeneous propagation medium. In some aspects, the three-dimensional region of interest Ω can be coextensive with a region across which the simulated acoustic pressure field is recorded by the recurrent computational graph described above with reference to FIGS. 20A-20C, such that the energy maximization formulation can be implemented within the volumetric optimization mode of the HASA-ADAM framework.

In some aspects, the converged thickness distribution illustrated in FIG. 27 can be transmitted to a three-dimensional printer to fabricate the acoustic lens from a polymer material having the two-dimensional thickness profile illustrated in FIG. 27. The acoustic lens fabricated from the converged thickness distribution can be coupled to a transducer to produce a diffraction-limited focus at the target coordinates through the heterogeneous propagation medium when the transducer is driven by an excitation signal at an operating frequency for which the iterative optimization 340 was performed.

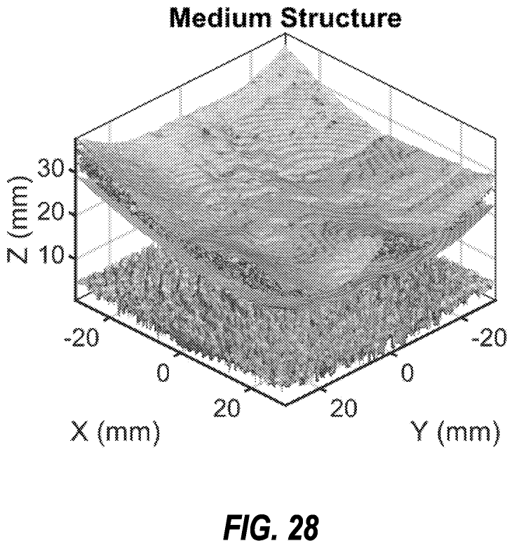

FIG. 28 illustrates a three-dimensional surface rendering of a medium structure characterized along orthogonal axes for the diffraction-limited focusing example, according to examples of the disclosed technology. The three-dimensional surface rendering of FIG. 28 can correspond to a volumetric representation of the heterogeneous propagation medium used by the heterogeneous angular spectrum approach when the iterative optimization 340 is configured with the energy maximization formulation described above with reference to FIG. 27 to synthesize a diffraction-limited focus at a target coordinate within tissue distal to the heterogeneous propagation medium.

In some aspects, the three-dimensional surface rendering of FIG. 28 can be rendered in a Cartesian coordinate system having a lateral X axis, a lateral Y axis, and an axial Z axis. The lateral X axis and the lateral Y axis can each span a range from approximately −20 mm to approximately +20 mm, and the axial Z axis can span a range from approximately 0 mm to greater than approximately 30 mm. The three-dimensional surface rendering can include a lower textured surface and an upper undulating surface that are vertically separated along the axial Z axis. The lower textured surface and the upper undulating surface can represent heterogeneous layers of the medium structure through which acoustic waves propagate from a source plane to a target plane.

In some aspects, the lower textured surface can be positioned near a base of the axial Z axis at axial Z coordinates ranging from approximately 0 mm to approximately 10 mm, and the lower textured surface can exhibit an irregular topography representative of a rough heterogeneous layer of the medium structure. The lower textured surface can remain substantially planar in an overall extent of the lower textured surface across the lateral X-Y plane while exhibiting localized roughness consistent with porous trabecular regions of cranial bone.

In some aspects, the upper undulating surface can be positioned at axial Z coordinates ranging from approximately 10 mm to greater than approximately 30 mm, and the upper undulating surface can exhibit a curved, undulating profile with visible striations and contour variations across the lateral X-Y plane. The upper undulating surface can display elevation variations across the lateral X-Y plane, with higher regions appearing toward one corner of the three-dimensional surface rendering and lower regions appearing toward an opposing region of the three-dimensional surface rendering. The undulating profile of the upper undulating surface can represent a second heterogeneous layer of the medium structure positioned distal to the lower textured surface along the acoustic propagation direction.

In some aspects, voxel-wise speed of sound and density values across the lower textured surface, the upper undulating surface, and an intervening propagation region between the lower textured surface and the upper undulating surface can be assigned by a porosity-dependent mixture model applied to micro-CT data of a skull, as described above with reference to FIG. 13. The voxel-wise speed of sound and density values can populate the spatially varying speed of sound distribution and the spatially varying density distribution of the three-dimensional acoustic property map ingested by the heterogeneous angular spectrum approach during the iterative optimization 340 that synthesizes the diffraction-limited focus.

In some aspects, the topology optimization path described above with reference to FIG. 5 can operate on the three-dimensional surface rendering of FIG. 28 by treating the intervening propagation region between the lower textured surface and the upper undulating surface as the heterogeneous propagation medium through which the acoustic pressure field is forward-propagated from the source plane to the target plane at each iteration of the iterative optimization 340. The heterogeneous angular spectrum approach can march the acoustic pressure field along the axial Z axis through the intervening propagation region using an axial marching step size, such as an axial marching step size of approximately 150 μm or approximately 250 μm, with the spatially varying speed of sound distribution and the spatially varying density distribution sampled at each axial propagation step to account for local acoustic property variations across the lower textured surface, the upper undulating surface, and the intervening propagation region.

In some aspects, the medium structure illustrated in FIG. 28 can be supplied as a propagation environment within which the iterative optimization 340 configured with the energy maximization formulation refines the unconstrained optimization variable to concentrate acoustic energy within the sub-wavelength bucket mask M(r) centered at the target coordinates. Asymmetric phase aberrations and refractive steering effects introduced by the curved, undulating profile of the upper undulating surface can be incorporated into the heterogeneous angular spectrum approach during forward propagation through the intervening propagation region, such that the gradient of the energy loss L_{energy} computed by automatic differentiation accounts for contributions of the asymmetric phase aberrations and the refractive steering effects to acoustic energy concentration at the target coordinates.

In some aspects, the converged thickness distribution illustrated in FIG. 27 can be produced by the iterative optimization 340 operating on the medium structure illustrated in FIG. 28, such that the converged thickness distribution pre-compensates for the asymmetric phase aberrations and the refractive steering effects imparted by the upper undulating surface and the lower textured surface while concentrating acoustic energy within the sub-wavelength bucket mask at the target coordinates distal to the upper undulating surface.

In some aspects, the three-dimensional surface rendering of FIG. 28 can represent a patient-specific anatomy of a skull derived from micro-CT data or from MRI scan data, such that the iterative optimization 340 can produce a patient-specific converged thickness distribution of the acoustic lens adapted to focus acoustic waves through the patient-specific anatomy to a diffraction-limited focus at the target coordinates. The patient-specific converged thickness distribution can be transmitted to a three-dimensional printer to fabricate the acoustic lens from a polymer material, such that the acoustic lens fabricated from the patient-specific converged thickness distribution can produce the diffraction-limited focus through the medium structure illustrated in FIG. 28 when a transducer coupled to the acoustic lens is driven by an excitation signal at an operating frequency for which the iterative optimization 340 was performed.

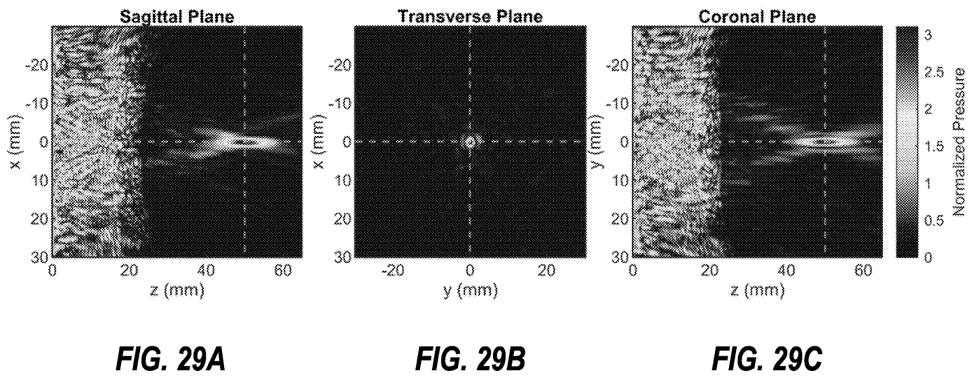

FIGS. 29A-29C illustrate simulated normalized pressure distributions of an acoustic field generated by a holographic lens through a skull, shown across three orthogonal planes, according to examples of the disclosed technology. FIG. 29A illustrates a simulated normalized pressure distribution in a sagittal plane, FIG. 29B illustrates a simulated normalized pressure distribution in a transverse plane, and FIG. 29C illustrates a simulated normalized pressure distribution in a coronal plane. The simulated normalized pressure distributions illustrated in FIGS. 29A-29C can correspond to an acoustic field produced by an acoustic lens having a converged thickness distribution output by the topology optimization path described above with reference to FIG. 5 when the iterative optimization 340 is configured with the energy maximization formulation described above with reference to FIG. 27, such that the acoustic lens synthesizes a diffraction-limited focus through the heterogeneous propagation medium.

In some aspects, each of FIGS. 29A-29C can be displayed as a grayscale intensity map accompanied by a shared normalized pressure scale ranging from approximately 0 to approximately 3, with brighter regions of the grayscale intensity map corresponding to higher normalized pressure values and darker regions of the grayscale intensity map corresponding to lower normalized pressure values.

In some aspects, the sagittal plane illustrated in FIG. 29A can present the simulated normalized pressure distribution as a function of an axial z coordinate ranging from approximately 0 mm to approximately 60 mm along a horizontal axis and a lateral x coordinate ranging from approximately −20 mm to approximately +30 mm along a vertical axis. In some aspects, the sagittal plane of FIG. 29A can exhibit a region of elevated pressure intensity near a source region at lower values of the axial z coordinate, followed by a propagation pathway that converges to a confined focal region located near an axial z coordinate of approximately 50 mm. Dashed reference lines can mark a target focal position within the sagittal plane such that the confined focal region is registered to the target focal position along the axial z coordinate.

In some aspects, the transverse plane illustrated in FIG. 29B can present the simulated normalized pressure distribution as a function of a lateral y coordinate ranging from approximately −20 mm to approximately +20 mm along a horizontal axis and the lateral x coordinate ranging from approximately −20 mm to approximately +30 mm along a vertical axis. In some aspects, the transverse plane of FIG. 29B can reveal a tightly confined focal spot centered at an intersection of dashed reference lines extending along the lateral y coordinate and along the lateral x coordinate. The tightly confined focal spot can exhibit a substantially circularly symmetric pressure distribution at the target plane, illustrating lateral confinement of the simulated acoustic pressure field produced by the acoustic lens through the heterogeneous propagation medium.

In some aspects, the coronal plane illustrated in FIG. 29C can present the simulated normalized pressure distribution as a function of the axial z coordinate ranging from approximately 0 mm to approximately 60 mm along a horizontal axis and the lateral y coordinate ranging from approximately −20 mm to approximately +30 mm along a vertical axis. In some aspects, the coronal plane of FIG. 29C can exhibit a region of elevated pressure intensity near the source region at lower values of the axial z coordinate, followed by a propagation pathway that converges to a confined focal region located near the axial z coordinate of approximately 50 mm. Dashed reference lines can mark the target focal position within the coronal plane such that the confined focal region is registered to the target focal position along the axial z coordinate.

In some aspects, the sagittal plane of FIG. 29A, the transverse plane of FIG. 29B, and the coronal plane of FIG. 29C can collectively illustrate an elongated focal beam that exhibits tight lateral and elevational confinement combined with an extended depth of field along the axial z coordinate. The elongated focal beam can be characteristic of a volumetric cigar-shaped focus produced through the heterogeneous propagation medium when the acoustic lens having the converged thickness distribution is driven by a transducer at an operating frequency for which the iterative optimization 340 was performed.

In some aspects, the simulated normalized pressure distributions illustrated in FIGS. 29A-29C can be computed by the heterogeneous angular spectrum approach using the converged thickness distribution illustrated in FIG. 27 and the three-dimensional acoustic property map of the heterogeneous propagation medium illustrated in FIG. 28. The heterogeneous angular spectrum approach can march the acoustic pressure field from the source plane along the axial z coordinate through the heterogeneous propagation medium to a far-field boundary at approximately z=60 mm, with the spatially varying speed of sound distribution and the spatially varying density distribution sampled at each axial propagation step. A sagittal slice, a transverse slice, and a coronal slice of the marched acoustic pressure field can be extracted to produce the simulated normalized pressure distributions illustrated in FIG. 29A, FIG. 29B, and FIG. 29C, respectively.

In some aspects, convergence of the simulated normalized pressure distribution to the confined focal region near the axial z coordinate of approximately 50 mm can indicate that the converged thickness distribution output by the iterative optimization 340 pre-compensates for asymmetric phase aberrations and refractive steering effects introduced by the heterogeneous propagation medium. By accounting for the spatially varying speed of sound distribution and the spatially varying density distribution during forward propagation, the converged thickness distribution can concentrate acoustic energy within the confined focal region at the target focal position despite skull-induced aberrations along the acoustic propagation path.

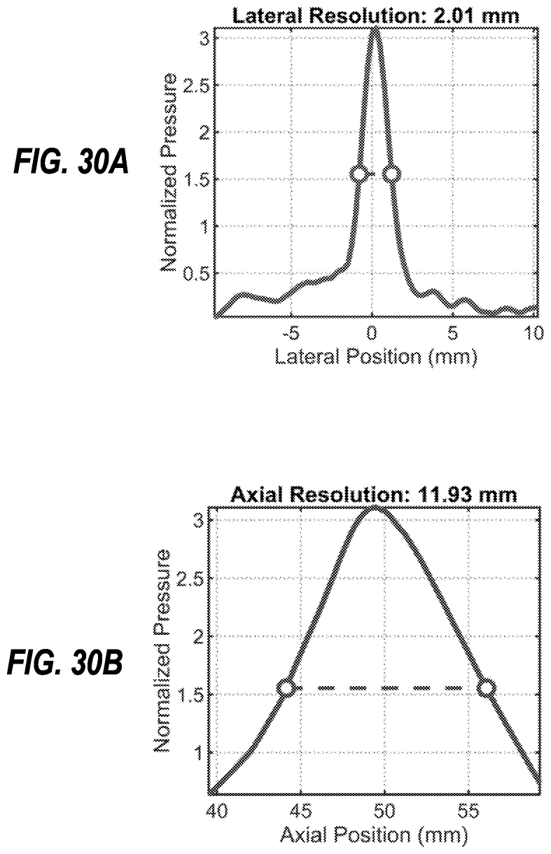

FIGS. 30A-30B illustrate lateral and axial focal performance characteristics of a diffraction-limited acoustic focus generated by an acoustic lens having a converged thickness distribution output by the topology optimization path described above with reference to FIG. 5, evaluated in terms of normalized pressure along a lateral dimension and an axial dimension. The focal performance characteristics illustrated in FIGS. 30A-30B can correspond to the simulated acoustic pressure field described above with reference to FIGS. 29A-29C, such that the lateral and axial normalized pressure profiles can quantify focal confinement of the diffraction-limited focus produced by the acoustic lens through the heterogeneous propagation medium.

FIG. 30A illustrates a lateral focal performance characteristic of the diffraction-limited acoustic focus. In some aspects, the lateral focal performance characteristic can be displayed as a plot of normalized pressure as a function of lateral position expressed in millimeters, with the lateral position ranging from approximately −10 mm to approximately +10 mm. In some aspects, the lateral focal performance characteristic can exhibit a sharply peaked curve centered near a lateral position of approximately 0 mm, with a peak normalized pressure reaching approximately 3.1. Half-maximum markers can be positioned on opposite sides of the peak at a half-maximum amplitude level of approximately 1.55 to define a full width at half maximum (FWHM) of the lateral focal performance characteristic, and a lateral resolution determined from a spacing between the half-maximum markers can be approximately 2.01 mm. In some aspects, the lateral focal performance characteristic can descend rapidly from the peak on both sides of the lateral position of approximately 0 mm, and can include a minor shoulder on a negative lateral side of the peak and low-amplitude oscillations extending toward lateral extents of the lateral position range.

In some aspects, the lateral resolution of approximately 2.01 mm can correspond to approximately 1.34λ at an operating frequency of approximately 1 MHz in a background medium having a speed of sound of approximately 1480 m/s, where λ denotes an acoustic wavelength in the background medium at the operating frequency. The lateral resolution expressed in terms of the acoustic wavelength can characterize the lateral focal performance characteristic as approaching a fundamental diffraction limit set by an aperture geometry of the acoustic lens at the operating frequency.

FIG. 30B illustrates an axial focal performance characteristic of the diffraction-limited acoustic focus. In some aspects, the axial focal performance characteristic can be displayed as a plot of normalized pressure as a function of axial position expressed in millimeters, with the axial position ranging from approximately 40 mm to approximately 60 mm along an acoustic propagation direction. In some aspects, the axial focal performance characteristic can exhibit a broader peaked curve relative to the lateral focal performance characteristic of FIG. 30A, with a peak normalized pressure reaching approximately 3.1 at an axial position of approximately 50 mm. Half-maximum markers can be positioned on opposite sides of the peak at a half-maximum amplitude level of approximately 1.55 and can be connected by a dashed horizontal line indicating an axial extent of the diffraction-limited acoustic focus at the half-maximum amplitude level, and an axial resolution corresponding to a depth-of-field measured between the half-maximum markers can be approximately 11.93 mm.

In some aspects, the axial focal performance characteristic of FIG. 30B can be substantially more elongated than the lateral focal performance characteristic of FIG. 30A, illustrating an anisotropy of a focal volume produced by the acoustic lens through the heterogeneous propagation medium. A focal aspect ratio defined as a ratio between the axial resolution and the lateral resolution can characterize the anisotropy of the focal volume. In some aspects, the lateral resolution of approximately 2.01 mm and the axial resolution of approximately 11.93 mm can correspond to a focal aspect ratio of approximately 5.9 between the axial resolution and the lateral resolution, characteristic of a high-gain focused ultrasound beam operating near a fundamental diffraction limit of the acoustic lens at the operating frequency.

In some aspects, the lateral focal performance characteristic of FIG. 30A and the axial focal performance characteristic of FIG. 30B can be extracted from the simulated acoustic pressure field described above with reference to FIGS. 29A-29C by sampling the normalized pressure along a lateral line passing through a focal peak at the target plane and along an axial line passing through the focal peak along the acoustic propagation direction. The lateral resolution and the axial resolution determined from the FWHM of the lateral focal performance characteristic and the axial focal performance characteristic can quantify focal confinement of the diffraction-limited acoustic focus produced by the acoustic lens designed by the iterative optimization 340 configured with the energy maximization formulation described above with reference to FIG. 27.

In some aspects, the lateral resolution and the axial resolution illustrated by FIGS. 30A-30B can be evaluated prior to fabrication of the acoustic lens by three-dimensional printing of a polymer based on the converged thickness distribution, such that the focal aspect ratio between the axial resolution and the lateral resolution can be characterized as a function of an operating frequency, an aperture geometry of the acoustic lens, and the spatially varying speed of sound distribution and the spatially varying density distribution of the heterogeneous propagation medium. In some aspects, the energy maximization formulation can be tuned by adjusting a radius σ of a sub-wavelength bucket mask M(r) centered at target coordinates such that the lateral focal performance characteristic and the axial focal performance characteristic approach the fundamental diffraction limit of the acoustic lens at the operating frequency without apodization of an effective aperture of the acoustic lens.

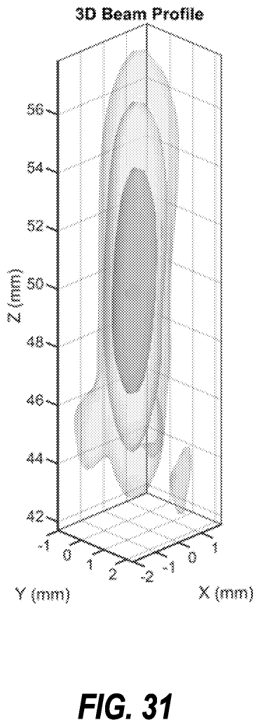

FIG. 31 illustrates a three-dimensional beam profile showing acoustic intensity isosurfaces generated by an acoustic lens having a converged thickness distribution output by the topology optimization path described above with reference to FIG. 5 when the iterative optimization 340 is configured with the energy maximization formulation described above with reference to FIG. 27. The three-dimensional beam profile illustrated in FIG. 31 can correspond to the diffraction-limited acoustic focus characterized above with reference to FIGS. 30A-30B, such that the three-dimensional beam profile visualizes a volumetric morphology of the diffraction-limited acoustic focus produced through the heterogeneous propagation medium.

In some aspects, the three-dimensional beam profile of FIG. 31 can be rendered within a volumetric region defined in a Cartesian coordinate system having a lateral X axis, a lateral Y axis, and an axial Z axis, with the axial Z axis corresponding to an acoustic propagation direction. In some aspects, the lateral X axis can span a range from approximately −2 mm to approximately +1 mm, the lateral Y axis can span a range from approximately −1 mm to approximately +2 mm, and the axial Z axis can span a range from approximately 42 mm to approximately 56 mm.

In some aspects, the three-dimensional beam profile of FIG. 31 can include a plurality of nested isosurfaces, with each nested isosurface representing a contour of constant acoustic intensity within the volumetric region. An innermost isosurface can represent a higher acoustic intensity contour level and can be positioned centrally along the axial Z axis at approximately Z=50 mm. The innermost isosurface can exhibit a compact, substantially ellipsoidal geometry that is laterally confined within a lateral X-Y plane. An intermediate isosurface can represent a lower acoustic intensity contour level and can surround the innermost isosurface. The intermediate isosurface can extend along the axial Z axis from approximately Z=46 mm to approximately Z=54 mm, forming an elongated cigar-shaped envelope around the innermost isosurface. An outermost isosurface can represent a still lower acoustic intensity contour level and can surround the intermediate isosurface. The outermost isosurface can extend along the axial Z axis over a greater range, from approximately Z=44 mm to approximately Z=56 mm.

In some aspects, the innermost isosurface, the intermediate isosurface, and the outermost isosurface can collectively define a principal focal region of the diffraction-limited acoustic focus. The principal focal region can be elongated along the axial Z axis relative to the lateral X axis and the lateral Y axis, such that the principal focal region exhibits an anisotropic focal volume having tight lateral confinement within the lateral X-Y plane and an extended depth of field along the axial Z axis. The anisotropic focal volume illustrated in FIG. 31 can correspond to the focal aspect ratio between the axial resolution and the lateral resolution described above with reference to FIGS. 30A-30B.

In some aspects, the three-dimensional beam profile of FIG. 31 can further include a plurality of discrete isosurface lobes positioned outside the principal focal region. A first discrete lobe can be located near a lower portion of the volumetric region at approximately Z=44 mm to approximately Z=46 mm along the axial Z axis, offset laterally from a central axis of the principal focal region. A second discrete lobe can be positioned at approximately Z=43 mm to approximately Z=45 mm along the axial Z axis on an opposing lateral side of the central axis relative to the first discrete lobe. An additional discrete lobe can be positioned adjacent to the principal focal region at approximately Z=50 mm to approximately Z=52 mm along the axial Z axis. The discrete isosurface lobes can represent localized regions of constructive interference flanking the principal focal region along the acoustic propagation direction and along lateral directions transverse to the acoustic propagation direction.

In some aspects, the discrete isosurface lobes positioned outside the principal focal region can arise from constructive interference of acoustic energy across an entirety of an aperture of the acoustic lens. The energy maximization formulation described above with reference to FIG. 27 can integrate acoustic intensity within the sub-wavelength bucket mask M(r) centered at target coordinates within the three-dimensional region of interest Ω rather than penalize aperture contributions that produce side lobes outside the sub-wavelength bucket mask. By integrating acoustic intensity within the sub-wavelength bucket mask rather than matching a prescribed reference intensity image across the target plane, the iterative optimization 340 configured with the energy maximization formulation can permit constructive interference side lobes to utilize a full aperture of the acoustic lens during forward propagation through the heterogeneous propagation medium.

In some aspects, utilization of the full aperture of the acoustic lens by the constructive interference side lobes can concentrate acoustic energy within the principal focal region while permitting localized regions of acoustic intensity outside the principal focal region. The constructive interference side lobes can correspond to peripheral contributions of the acoustic lens aperture that converge at the target coordinates along acoustic propagation paths that contribute to focal gain at the principal focal region. By preserving the peripheral contributions of the acoustic lens aperture rather than apodizing the peripheral contributions to suppress side lobes, the energy maximization formulation can drive the acoustic focal field toward a fundamental diffraction limit of the acoustic lens at an operating frequency for which the iterative optimization 340 was performed.

In some aspects, the three-dimensional beam profile of FIG. 31 can be computed from the simulated acoustic pressure field described above with reference to FIGS. 29A-29C by extracting isosurfaces of constant acoustic intensity at selected normalized pressure levels and rendering the isosurfaces within the volumetric region defined by the lateral X axis, the lateral Y axis, and the axial Z axis. In some aspects, the selected normalized pressure levels for the innermost isosurface, the intermediate isosurface, and the outermost isosurface can be chosen to span a range of acoustic intensity contour levels that characterize the principal focal region and the discrete isosurface lobes flanking the principal focal region.

In some aspects, a focal morphology metric can be computed from extents of the innermost isosurface, the intermediate isosurface, and the outermost isosurface along the lateral X axis, the lateral Y axis, and the axial Z axis to quantify the anisotropy of the focal volume produced by the acoustic lens having the converged thickness distribution. In some aspects, a side lobe metric can be computed from a number, a position, and a magnitude of the discrete isosurface lobes positioned outside the principal focal region to characterize aperture utilization by the energy maximization formulation. Together, the focal morphology metric and the side lobe metric can quantify performance of the converged thickness distribution in producing the diffraction-limited acoustic focus through the heterogeneous propagation medium prior to fabrication of the acoustic lens by three-dimensional printing of a polymer based on the converged thickness distribution.

The disclosed technology can further be implemented as a system embodiment for designing and producing the acoustic lens. The system can include a memory and a processor in communication with the memory. The memory can store a three-dimensional acoustic property map of the heterogeneous propagation medium. The three-dimensional acoustic property map can include a spatially varying speed of sound distribution and a spatially varying density distribution of the heterogeneous propagation medium. The memory can further store a target acoustic intensity distribution at a target plane. In some aspects, the memory can include volatile memory, non-volatile memory, or a combination thereof, and can include random-access memory, read-only memory, solid-state storage, magnetic storage, or optical storage.

The processor in communication with the memory can be configured to initialize a thickness distribution of the acoustic lens. The thickness distribution can be parameterized by an unconstrained optimization variable transformed by a softplus function bounded by a maximum thickness, as described above with reference to the topology optimization path. The processor can be configured to iteratively update the thickness distribution by, for each of a plurality of iterations, simulating forward propagation of an acoustic pressure field from a source plane, through the acoustic lens defined by the thickness distribution, and through the heterogeneous propagation medium to the target plane using the heterogeneous angular spectrum approach that accounts for the spatially varying speed of sound distribution and the spatially varying density distribution.

The processor can be further configured to compute a simulated intensity distribution at the target plane based on the simulated forward propagation, to compute a loss based on a difference between the simulated intensity distribution and the target acoustic intensity distribution, to compute, by automatic differentiation, a gradient of the loss with respect to the unconstrained optimization variable, and to update the unconstrained optimization variable based on the gradient and a learning rate. The processor can be configured to output a converged thickness distribution of the acoustic lens upon satisfaction of a convergence criterion.

In some aspects, the system can further include a three-dimensional printer in communication with the processor. The three-dimensional printer can be configured to fabricate the acoustic lens from a polymer material based on the converged thickness distribution output by the processor. In some aspects, the three-dimensional printer can include a stereolithography three-dimensional printer, such as a Formlabs Form 3B printer, and the polymer material can include a photopolymer resin, such as Formlabs Clear V4 resin. The converged thickness distribution output by the processor can be transmitted from the processor to the three-dimensional printer over a wired or wireless communication interface, such that the three-dimensional printer can fabricate the acoustic lens having a physical thickness profile corresponding to the converged thickness distribution.

In some aspects, the processor can include a graphics processing unit. The heterogeneous angular spectrum approach and the automatic differentiation can be implemented using a machine learning framework executed on the graphics processing unit. In some aspects, the machine learning framework can include TensorFlow, PyTorch, JAX, or another machine learning framework that provides automatic differentiation and hardware acceleration. The graphics processing unit can include, for example, a 24 GB NVIDIA RTX 3090 graphics processing unit or another graphics processing unit configured to execute the machine learning framework. In some aspects, the processor can include a central processing unit in addition to the graphics processing unit, such that operations associated with data input and output, control flow, and storage can be executed on the central processing unit while operations associated with the heterogeneous angular spectrum approach and the automatic differentiation can be executed on the graphics processing unit.

In some aspects, the heterogeneous propagation medium can include a skull, and the three-dimensional acoustic property map stored in the memory can be derived from micro-computed tomography data of the skull. As described above, the micro-computed tomography data of the skull can be processed by the processor or by a separate computing system to generate the spatially varying speed of sound distribution and the spatially varying density distribution, for example using a porosity-dependent mixture model that assigns voxel-wise speed of sound and density values based on Hounsfield units derived from the micro-computed tomography data.

In some aspects, the processor can be configured to simulate the forward propagation by, at each of a plurality of axial propagation steps, transforming the acoustic pressure field to a frequency domain by a two-dimensional fast Fourier transform, multiplying the transformed acoustic pressure field by an exponential phase term encoding axial propagation, and applying a correction based on a refractive index mismatch between materials at the axial propagation step. The two-dimensional fast Fourier transform, the multiplication by the exponential phase term, and the correction based on the refractive index mismatch can be executed by the machine learning framework on the graphics processing unit, such that the gradient of the loss with respect to the unconstrained optimization variable can be computed by automatic differentiation through each of the plurality of axial propagation steps.

In some aspects, the processor can be configured to update the unconstrained optimization variable using an Adam optimizer, and the loss computed by the processor can further include a regularization term weighted by a regularization weight. The regularization term can include a total variation regularizer that encourages smooth thickness variations across the acoustic lens, an L1 regularizer applied to the thickness distribution, or another regularizer suitable for stabilizing the iterative update of the thickness distribution.

The disclosed technology can further be implemented as a non-transitory computer-readable medium storing instructions that, when executed by a processor, cause the processor to perform operations for designing the acoustic lens. The operations can include receiving the three-dimensional acoustic property map of the heterogeneous propagation medium, the three-dimensional acoustic property map including the spatially varying speed of sound distribution and the spatially varying density distribution. The operations can include receiving the target acoustic intensity distribution at the target plane. The operations can include initializing the thickness distribution of the acoustic lens, the thickness distribution being parameterized by the unconstrained optimization variable transformed by the softplus function bounded by the maximum thickness.

The operations performed by the processor in response to execution of the instructions stored on the non-transitory computer-readable medium can further include iteratively updating the thickness distribution by, for each of a plurality of iterations, simulating forward propagation of the acoustic pressure field from the source plane, through the acoustic lens defined by the thickness distribution, and through the heterogeneous propagation medium to the target plane using the heterogeneous angular spectrum approach that accounts for the spatially varying speed of sound distribution and the spatially varying density distribution. The operations can further include computing the simulated intensity distribution at the target plane based on the simulated forward propagation, computing the loss based on a difference between the simulated intensity distribution and the target acoustic intensity distribution, computing, by automatic differentiation, the gradient of the loss with respect to the unconstrained optimization variable, and updating the unconstrained optimization variable based on the gradient and the learning rate.

The operations can further include outputting a converged thickness distribution of the acoustic lens upon satisfaction of the convergence criterion. In some aspects, the operations can further include transmitting the converged thickness distribution to a three-dimensional printer to fabricate the acoustic lens from a polymer material. In some aspects, the operations can include updating the unconstrained optimization variable using an Adam optimizer, and the convergence criterion can include at least one of the loss being less than or equal to a tolerance, or an iteration count reaching a maximum number of iterations.

In some aspects, the non-transitory computer-readable medium can include a hard disk drive, a solid-state drive, a flash memory device, an optical disc, a magnetic tape, or another tangible storage medium that retains the instructions in a form readable by the processor. The instructions stored on the non-transitory computer-readable medium can be encoded in a machine-executable format, an interpreted script format, or a combination thereof, such that execution of the instructions by the processor causes the processor to perform the operations described above.

In some aspects, the disclosed technology can be extended from a single-element transducer paired with the acoustic lens to dense or sparse phased array systems for transcranial applications. Under the extension to phased array systems, each array element of a phased array can be treated similarly to a lens pixel of the acoustic lens, such that an excitation phase, an excitation amplitude, or both, applied to each array element can be parameterized as an optimization variable that is iteratively updated by the heterogeneous angular spectrum approach and the gradient-based optimizer described above. A dense phased array can include array elements distributed across an aperture with a pixel pitch comparable to or smaller than an acoustic wavelength in a background medium, while a sparse phased array can include array elements distributed across the aperture with a pixel pitch larger than the acoustic wavelength. In some aspects, the heterogeneous angular spectrum approach can simulate forward propagation of the acoustic pressure field emitted by the array elements through the heterogeneous propagation medium to the target plane, and the gradient of the loss with respect to the excitation phase or the excitation amplitude can be computed by automatic differentiation, such that the iterative optimization can refine the excitation parameters of the phased array to produce the target acoustic intensity distribution at the target plane.

In some aspects, the acoustic lens designed by the disclosed technology can be configured to produce a multi-focal pressure field targeting a plurality of brain regions simultaneously rather than a single focus. The target acoustic intensity distribution received by the iterative optimization can encode a plurality of focal spots distributed across the target plane or distributed across a three-dimensional region of interest, such that the converged thickness distribution can produce the multi-focal pressure field when acoustic waves emitted by the transducer propagate through the acoustic lens and through the heterogeneous propagation medium. In some aspects, the plurality of focal spots can be co-planar at the target plane, or can be distributed across a plurality of axial depths along an acoustic propagation direction. The multi-focal pressure field can be applied to simultaneous sonication of multiple deep-brain structures, such as bilateral structures or distributed networks of brain regions, during a single transcranial focused ultrasound exposure.

In some aspects, the disclosed technology can produce holographic patterns at the target plane that include arbitrarily complex two-dimensional images. The target acoustic intensity distribution received by the iterative optimization can encode a logo pattern, a vortex pattern, a single focus, a multi-point target, or another two-dimensional image, and the converged thickness distribution output by the iterative optimization can produce a reconstructed acoustic intensity field at the target plane corresponding to the encoded two-dimensional image. The logo pattern can include a graphical feature such as a text glyph or a geometric design, the vortex pattern can include the toroidal acoustic intensity distribution described above with reference to FIG. 23 and FIG. 26, the single focus can include a diffraction-limited focal spot described above with reference to FIG. 27, and the multi-point target can include a plurality of focal spots distributed across the target plane. The disclosed technology can therefore support a range of transcranial focused ultrasound applications, including single-target sonication, multi-target sonication, structure-sparing sonication using vortex patterns, and synthesis of holographic acoustic patterns matched to anatomical constraints of the heterogeneous propagation medium.

In some aspects, the disclosed technology can be implemented as a cloud-based service in which the memory, the processor, and the graphics processing unit are hosted on a remote computing system accessible over a network. A user can transmit the three-dimensional acoustic property map of the heterogeneous propagation medium and the target acoustic intensity distribution to the remote computing system over the network, and the remote computing system can execute the iterative optimization to produce the converged thickness distribution. The converged thickness distribution can be returned to the user over the network or can be transmitted directly from the remote computing system to a three-dimensional printer associated with the user to fabricate the acoustic lens.

The disclosed technology can be further understood according to the following clauses:

Clause 1. A method for designing an acoustic lens for focusing acoustic waves through a heterogeneous propagation medium, the method comprising: receiving a three-dimensional acoustic property map of the heterogeneous propagation medium, the acoustic property map including a spatially varying speed of sound distribution and a spatially varying density distribution; receiving a target acoustic intensity distribution at a target plane; initializing a thickness distribution of the acoustic lens, the thickness distribution being parameterized by an unconstrained optimization variable transformed by a softplus function bounded by a maximum thickness; iteratively updating the thickness distribution by, for each of a plurality of iterations: simulating forward propagation of an acoustic pressure field from a source plane, through the acoustic lens defined by the thickness distribution, and through the heterogeneous propagation medium to the target plane using a heterogeneous angular spectrum approach that accounts for the spatially varying speed of sound distribution and the spatially varying density distribution; computing a simulated intensity distribution at the target plane based on the simulated forward propagation; computing a loss based on a difference between the simulated intensity distribution and the target acoustic intensity distribution; computing, by automatic differentiation, a gradient of the loss with respect to the unconstrained optimization variable; and updating the unconstrained optimization variable based on the gradient and a learning rate; and outputting a converged thickness distribution of the acoustic lens upon satisfaction of a convergence criterion.

Clause 2. The method of clause 1, wherein the heterogeneous propagation medium comprises a skull, and wherein receiving the three-dimensional acoustic property map comprises deriving the spatially varying speed of sound distribution and the spatially varying density distribution from micro-computed tomography data of the skull.

Clause 3. The method of clause 1, wherein simulating the forward propagation comprises, at each of a plurality of axial propagation steps: transforming the acoustic pressure field to a frequency domain by a two-dimensional fast Fourier transform; multiplying the transformed acoustic pressure field by an exponential phase term encoding axial propagation; and applying a correction based on a refractive index mismatch between materials at the axial propagation step.

Clause 4. The method of clause 3, further comprising attenuating spatial-frequency components above a cutoff and applying a tapering mask at spatial edges of the acoustic pressure field.

Clause 5. The method of clause 1, wherein updating the unconstrained optimization variable is performed using an Adam optimizer.

Clause 6. The method of clause 1, wherein the loss further includes a regularization term weighted by a regularization weight.

Clause 7. The method of clause 1, wherein the convergence criterion comprises at least one of the loss being less than or equal to a tolerance, or an iteration count reaching a maximum number of iterations.

Clause 8. The method of clause 1, wherein the softplus function bounds the thickness distribution to a range of zero to a maximum thickness of 5 mm or less.

Clause 9. The method of clause 1, further comprising fabricating the acoustic lens by three-dimensional printing of a polymer based on the converged thickness distribution.

Clause 10. The method of clause 1, further comprising: applying an aperture mask to the thickness distribution to constrain the acoustic lens to a defined aperture shape; and applying a region-of-interest mask to the simulated intensity distribution to weight the loss within a defined region of the target plane.

Clause 11. The method of clause 1, wherein the heterogeneous angular spectrum approach is implemented using a machine learning framework that provides automatic differentiation and graphics processing unit acceleration.

Clause 12. A system for designing and producing an acoustic lens for focusing acoustic waves through a heterogeneous propagation medium, the system comprising: a memory storing a three-dimensional acoustic property map of the heterogeneous propagation medium, the acoustic property map including a spatially varying speed of sound distribution and a spatially varying density distribution, and storing a target acoustic intensity distribution at a target plane; a processor in communication with the memory, the processor configured to: initialize a thickness distribution of the acoustic lens, the thickness distribution being parameterized by an unconstrained optimization variable transformed by a softplus function bounded by a maximum thickness; iteratively update the thickness distribution by, for each of a plurality of iterations: simulating forward propagation of an acoustic pressure field from a source plane, through the acoustic lens defined by the thickness distribution, and through the heterogeneous propagation medium to the target plane using a heterogeneous angular spectrum approach that accounts for the spatially varying speed of sound distribution and the spatially varying density distribution; computing a simulated intensity distribution at the target plane based on the simulated forward propagation; computing a loss based on a difference between the simulated intensity distribution and the target acoustic intensity distribution; computing, by automatic differentiation, a gradient of the loss with respect to the unconstrained optimization variable; and updating the unconstrained optimization variable based on the gradient and a learning rate; and output a converged thickness distribution of the acoustic lens upon satisfaction of a convergence criterion.

Clause 13. The system of clause 12, further comprising a three-dimensional printer in communication with the processor and configured to fabricate the acoustic lens from a polymer material based on the converged thickness distribution.

Clause 14. The system of clause 12, wherein the processor comprises a graphics processing unit, and wherein the heterogeneous angular spectrum approach and the automatic differentiation are implemented using a machine learning framework executed on the graphics processing unit.

Clause 15. The system of clause 12, wherein the heterogeneous propagation medium comprises a skull, and wherein the three-dimensional acoustic property map is derived from micro-computed tomography data of the skull.

Clause 16. The system of clause 12, wherein the processor is configured to simulate the forward propagation by, at each of a plurality of axial propagation steps: transforming the acoustic pressure field to a frequency domain by a two-dimensional fast Fourier transform; multiplying the transformed acoustic pressure field by an exponential phase term encoding axial propagation; and applying a correction based on a refractive index mismatch between materials at the axial propagation step.

Clause 17. The system of clause 12, wherein the processor is configured to update the unconstrained optimization variable using an Adam optimizer, and wherein the loss further includes a regularization term weighted by a regularization weight.

Clause 18. A non-transitory computer-readable medium storing instructions that, when executed by a processor, cause the processor to perform operations for designing an acoustic lens for focusing acoustic waves through a heterogeneous propagation medium, the operations comprising: receiving a three-dimensional acoustic property map of the heterogeneous propagation medium, the acoustic property map including a spatially varying speed of sound distribution and a spatially varying density distribution; receiving a target acoustic intensity distribution at a target plane; initializing a thickness distribution of the acoustic lens, the thickness distribution being parameterized by an unconstrained optimization variable transformed by a softplus function bounded by a maximum thickness; iteratively updating the thickness distribution by, for each of a plurality of iterations: simulating forward propagation of an acoustic pressure field from a source plane, through the acoustic lens defined by the thickness distribution, and through the heterogeneous propagation medium to the target plane using a heterogeneous angular spectrum approach that accounts for the spatially varying speed of sound distribution and the spatially varying density distribution; computing a simulated intensity distribution at the target plane based on the simulated forward propagation; computing a loss based on a difference between the simulated intensity distribution and the target acoustic intensity distribution; computing, by automatic differentiation, a gradient of the loss with respect to the unconstrained optimization variable; and updating the unconstrained optimization variable based on the gradient and a learning rate; and outputting a converged thickness distribution of the acoustic lens upon satisfaction of a convergence criterion.

Clause 19. The non-transitory computer-readable medium of clause 18, wherein the operations further comprise transmitting the converged thickness distribution to a three-dimensional printer to fabricate the acoustic lens from a polymer material.

Clause 20. The non-transitory computer-readable medium of clause 18, wherein updating the unconstrained optimization variable is performed using an Adam optimizer, and wherein the convergence criterion comprises at least one of the loss being less than or equal to a tolerance, or an iteration count reaching a maximum number of iterations.

A number of implementations have been described. Nevertheless, it will be understood that various modifications may be made without departing from the spirit and scope of the disclosure. Accordingly, other implementations are within the scope of the following claims.

1. A method for designing an acoustic lens for focusing acoustic waves through a heterogeneous propagation medium, the method comprising:
receiving a three-dimensional acoustic property map of the heterogeneous propagation medium, the acoustic property map including a spatially varying speed of sound distribution and a spatially varying density distribution;
receiving a target acoustic intensity distribution at a target plane;
initializing a thickness distribution of the acoustic lens, the thickness distribution being parameterized by an unconstrained optimization variable transformed by a softplus function bounded by a maximum thickness;
iteratively updating the thickness distribution by, for each of a plurality of iterations:
simulating forward propagation of an acoustic pressure field from a source plane, through the acoustic lens defined by the thickness distribution, and through the heterogeneous propagation medium to the target plane using a heterogeneous angular spectrum approach that accounts for the spatially varying speed of sound distribution and the spatially varying density distribution;
computing a simulated intensity distribution at the target plane based on the simulated forward propagation;
computing a loss based on a difference between the simulated intensity distribution and the target acoustic intensity distribution;
computing, by automatic differentiation, a gradient of the loss with respect to the unconstrained optimization variable; and
updating the unconstrained optimization variable based on the gradient and a learning rate; and
outputting a converged thickness distribution of the acoustic lens upon satisfaction of a convergence criterion.

2. The method of claim 1, wherein the heterogeneous propagation medium comprises a skull, and wherein receiving the three-dimensional acoustic property map comprises deriving the spatially varying speed of sound distribution and the spatially varying density distribution from micro-computed tomography (micro-CT) data of the skull.

3. The method of claim 1, wherein simulating the forward propagation comprises, at each of a plurality of axial propagation steps:
transforming the acoustic pressure field to a frequency domain by a two-dimensional fast Fourier transform;
multiplying the transformed acoustic pressure field by an exponential phase term encoding axial propagation; and
applying a correction based on a refractive index mismatch between materials at the axial propagation step.

4. The method of claim 3, further comprising attenuating spatial-frequency components above a cutoff and applying a tapering mask at spatial edges of the acoustic pressure field.

5. The method of claim 1, wherein updating the unconstrained optimization variable is performed using an Adam optimizer.

6. The method of claim 1, wherein the loss further includes a regularization term weighted by a regularization weight.

7. The method of claim 1, wherein the convergence criterion comprises at least one of the loss being less than or equal to a tolerance, or an iteration count reaching a maximum number of iterations.

8. The method of claim 1, wherein the softplus function bounds the thickness distribution to a range of zero to a maximum thickness of 5 mm or less.

9. The method of claim 1, further comprising fabricating the acoustic lens by three-dimensional printing of a polymer based on the converged thickness distribution.

10. The method of claim 1, further comprising:
applying an aperture mask to the thickness distribution to constrain the acoustic lens to a defined aperture shape; and
applying a region-of-interest mask to the simulated intensity distribution to weight the loss within a defined region of the target plane.

11. The method of claim 1, wherein the heterogeneous angular spectrum approach is implemented using a machine learning framework that provides automatic differentiation and graphics processing unit acceleration.

12. A system for designing and producing an acoustic lens for focusing acoustic waves through a heterogeneous propagation medium, the system comprising:
a memory storing a three-dimensional acoustic property map of the heterogeneous propagation medium, the acoustic property map including a spatially varying speed of sound distribution and a spatially varying density distribution, and storing a target acoustic intensity distribution at a target plane;
a processor in communication with the memory, the processor configured to:
initialize a thickness distribution of the acoustic lens, the thickness distribution being parameterized by an unconstrained optimization variable transformed by a softplus function bounded by a maximum thickness;
iteratively update the thickness distribution by, for each of a plurality of iterations:
simulating forward propagation of an acoustic pressure field from a source plane, through the acoustic lens defined by the thickness distribution, and through the heterogeneous propagation medium to the target plane using a heterogeneous angular spectrum approach that accounts for the spatially varying speed of sound distribution and the spatially varying density distribution;
computing a simulated intensity distribution at the target plane based on the simulated forward propagation;
computing a loss based on a difference between the simulated intensity distribution and the target acoustic intensity distribution;
computing, by automatic differentiation, a gradient of the loss with respect to the unconstrained optimization variable; and
updating the unconstrained optimization variable based on the gradient and a learning rate; and
output a converged thickness distribution of the acoustic lens upon satisfaction of a convergence criterion.

13. The system of claim 12, further comprising a three-dimensional printer in communication with the processor and configured to fabricate the acoustic lens from a polymer material based on the converged thickness distribution.

14. The system of claim 12, wherein the processor comprises a graphics processing unit, and wherein the heterogeneous angular spectrum approach and the automatic differentiation are implemented using a machine learning framework executed on the graphics processing unit.

15. The system of claim 12, wherein the heterogeneous propagation medium comprises a skull, and wherein the three-dimensional acoustic property map is derived from micro-computed tomography (micro-CT) data of the skull.

16. The system of claim 12, wherein the processor is configured to simulate the forward propagation by, at each of a plurality of axial propagation steps:
transforming the acoustic pressure field to a frequency domain by a two-dimensional fast Fourier transform;
multiplying the transformed acoustic pressure field by an exponential phase term encoding axial propagation; and
applying a correction based on a refractive index mismatch between materials at the axial propagation step.

17. The system of claim 12, wherein the processor is configured to update the unconstrained optimization variable using an Adam optimizer, and wherein the loss further includes a regularization term weighted by a regularization weight.

18. A non-transitory computer-readable medium storing instructions that, when executed by a processor, cause the processor to perform operations for designing an acoustic lens for focusing acoustic waves through a heterogeneous propagation medium, the operations comprising:
receiving a three-dimensional acoustic property map of the heterogeneous propagation medium, the acoustic property map including a spatially varying speed of sound distribution and a spatially varying density distribution;
receiving a target acoustic intensity distribution at a target plane;
initializing a thickness distribution of the acoustic lens, the thickness distribution being parameterized by an unconstrained optimization variable transformed by a softplus function bounded by a maximum thickness;
iteratively updating the thickness distribution by, for each of a plurality of iterations:
simulating forward propagation of an acoustic pressure field from a source plane, through the acoustic lens defined by the thickness distribution, and through the heterogeneous propagation medium to the target plane using a heterogeneous angular spectrum approach that accounts for the spatially varying speed of sound distribution and the spatially varying density distribution;
computing a simulated intensity distribution at the target plane based on the simulated forward propagation;
computing a loss based on a difference between the simulated intensity distribution and the target acoustic intensity distribution;
computing, by automatic differentiation, a gradient of the loss with respect to the unconstrained optimization variable; and
updating the unconstrained optimization variable based on the gradient and a learning rate; and
outputting a converged thickness distribution of the acoustic lens upon satisfaction of a convergence criterion.

19. The non-transitory computer-readable medium of claim 18, wherein the operations further comprise transmitting the converged thickness distribution to a three-dimensional printer to fabricate the acoustic lens from a polymer material.

20. The non-transitory computer-readable medium of claim 18, wherein updating the unconstrained optimization variable is performed using an Adam optimizer, and wherein the convergence criterion comprises at least one of the loss being less than or equal to a tolerance, or an iteration count reaching a maximum number of iterations.
